(19) United States
(12) Patent Application Publication
(10) Pub. No.: US 2024/0284723 A1
(43) Pub. Date: Aug. 22, 2024

(54) DISPLAY DEVICE

(71) Applicant: Samsung Display Co., LTD., Yongin-si (KR)

(72) Inventors: DONGHYUN LEE, Yongin-si (KR); YOUN-WOONG KANG, Yongin-si (KR); SEOKHYUN NAM, Yongin-si (KR); SI JOON SONG, Yongin-si (KR); JAEHAK LEE, Yongin-si (KR)

(21) Appl. No.: 18/531,076

(22) Filed: Dec. 6, 2023

(30) Foreign Application Priority Data
Feb. 20, 2023 (KR) 10-2023-0022224

(51) Int. Cl. H10K 59/124; H10K 50/805; H10K 59/121

(52) U.S. Cl. CPC H10K 59/124; H10K 50/805; H10K 59/1213

(57) ABSTRACT

A display device includes a display panel. The display panel includes a pixel, an encapsulation layer, and a connection electrode connecting a signal line and a pad electrode. The connection electrode is connected to the pad electrode via a first contact area positioned in a non-display area. A first contact hole is defined penetrating the second synthetic resin layer in the first contact area, a plurality of insulating layers is disposed in the first contact hole, and a second contact hole is defined inside the first contact hole in a plan view, penetrates the insulating layers, and exposes the pad electrode. The first contact hole has a width greater than a width of the second contact hole in the plan view.

This application claims priority to Korean Patent Application No. 10-2023-0022224, filed on Feb. 20, 2023, and all the benefits accruing therefrom under 35 U.S.C. § 119, the content of which in its entirety is herein incorporated by reference.

### BACKGROUND

### 1. Field of disclosure

The present disclosure relates to a display device. More particularly, the present disclosure relates to a display device in which a flexible circuit board is bonded to a rear surface of a display panel.

### 2. Description of the Related Art

Electronic devices, such as smartphones, tablet computers, notebook computers, car navigation units, and smart televisions, are being developed. The electronic devices include a display device to provide information.

Various types of display devices are being developed to satisfy the user experience UX and the user interface UI. Researches to provide a display device with a wide display area and a narrow non-display area are being conducted.

### SUMMARY

The present disclosure provides a display device with reduced non-display area.

Embodiments of the invention provide a display device including: a display panel including a display area and a non-display area The display panel includes a first synthetic resin layer overlapping the display area and the non-display area, a second synthetic resin layer disposed on the first synthetic resin layer, a pad electrode disposed between the first synthetic resin layer and the second synthetic resin layer, overlapping the non-display area, and exposed to an outside via an opening defined through the first synthetic resin layer, a plurality of insulating layers disposed on an upper surface of the second synthetic resin layer, a pixel disposed on the upper surface of the second synthetic resin layer and including a light emitting element overlapping the display area and a transistor electrically connected to the light emitting element, a signal line disposed on the upper surface of the second synthetic resin layer and overlapping at least the non-display area, and a connection electrode disposed on the insulating layers in the non-display area and configured to electrically connect the signal line to the pad electrode. The connection electrode is connected to the pad electrode via a first contact area defined in the non-display area, a first contact hole is defined penetrating the second synthetic resin layer in the first contact area, portions of the insulating layers are disposed in the first contact hole, a second contact hole is defined inside the first contact hole in a plan view, penetrates the insulating layers, and exposes the pad electrode, and the first contact hole has a width greater than a width of the second contact hole in the plan view.

Embodiments of the invention provide a display device including a display panel including a display area and a non-display area and a flexible circuit board electrically connected to the display panel. The display panel includes a first synthetic resin layer overlapping the display area and the non-display area, a second synthetic resin layer disposed on the first synthetic resin layer, a base insulating layer disposed between the first synthetic resin layer and the second synthetic resin layer, a plurality of insulating layers disposed on an upper surface of the second synthetic resin layer, a pixel disposed on the upper surface of the second synthetic resin layer and including a light emitting element overlapping the display area and a transistor electrically connected to the light emitting element, a signal line disposed on the upper surface of the second synthetic resin layer and overlapping at least the non-display area, and a connection electrode disposed on the insulating layers in the non-display area, configured to electrically connect the signal line to the flexible circuit board, and including a pad portion exposed to an outside through an opening defined through the first synthetic resin layer. The connection electrode is connected to the flexible circuit board via a contact area defined in the non-display area, a first contact hole is defined penetrating the second synthetic resin layer and the base insulating layer in the contact area, portions of the insulating layers are disposed in the first contact hole, a second contact hole is defined inside the first contact hole in a plan view and penetrates the insulating layers, and the pad portion is disposed in the second contact hole.

Embodiments of the invention provide a display device including a display panel including a display area and a non-display area The display panel includes a first synthetic resin layer overlapping the display area and the non-display area, a second synthetic resin layer disposed on the first synthetic resin layer, a pad electrode disposed between the first synthetic resin layer and the second synthetic resin layer, overlapping the non-display area, and exposed to an outside via an opening defined through the first synthetic resin layer, a plurality of insulating layers disposed on an upper surface of the second synthetic resin layer, a pixel disposed on the upper surface of the second synthetic resin layer and including a light emitting element overlapping the display area and a transistor electrically connected to the light emitting element, and a signal line disposed on a first group of insulating layers among the insulating layers in the non-display area and electrically connected to the pad electrode. The signal line is connected to the pad electrode via a contact area defined in the non-display area, a first contact hole is defined penetrating the second synthetic resin layer in the contact area, portions of the first group of the insulating layers are disposed in the first contact hole, a second contact hole is defined inside the first contact hole in a plan view, penetrates the first group of the insulating layers, and exposes the pad electrode, the signal line is connected to the pad electrode through the second contact hole, and the first contact hole has a width greater than a width of the second contact hole in the plan view.

According to the above, the flexible circuit board is connected to a rear surface of the display panel, e.g., a rear surface bonding. Thus, the non-display area of the display panel is not bent, and defects occurring when the non-display area of the display panel is bent are effectively prevented. Accordingly, a bezel area of a window covering the non-display area of the display panel is reduced.

According to the above, the flexible circuit board and the pad electrode are electrically connected to each other by a metal pattern formed by curing a metal ink and patterning the cured metal ink. The metal pattern is able to be formed in a low temperature condition, and thus, the flexible circuit board and the display panel are bonded with each other without pressing the flexible circuit board and the display panel under a high temperature condition.

According to the above, the first contact hole and the second contact hole, which are formed in the contact area and overlap each other in the plan view, are arranged discontinuously and have different widths, and thus, defects occurring the insulating layers are effectively reduced.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a perspective view of an electronic device according to an embodiment of the present disclosure:

FIG. 2 is an exploded perspective view of an electronic device according to an embodiment of the present disclosure;

FIG. 3 is a cross-sectional view of a display device taken along line I-I′ of FIG. 2;

FIG. 4 is a cross-sectional view of a display module according to an embodiment of the present disclosure;

FIG. 5 is a plan view of a display panel according to an embodiment of the present disclosure;

FIG. 6 is a cross-sectional view of a display module according to an embodiment of the present disclosure;

FIG. 7A is a plan view of an input sensor according to an embodiment of the present disclosure;

FIG. 7B is a cross-sectional view of the input sensor taken along line II-II′ of FIG. 7A;

FIG. 8 is an enlarged plan view of a non-display area of a display module according to an embodiment of the present disclosure;

FIG. 9A is a cross-sectional view of the display module taken along line III-III′ of FIG. 8;

FIG. 9B is a cross-sectional view of a deposition process according to an embodiment of the present disclosure;

FIG. 9C is an enlarged cross-sectional view of a portion of FIG. 9B;

FIG. 10A is an enlarged plan view of a non-display area of a display module according to an embodiment of the present disclosure;

FIG. 10B is a cross-sectional view of the display module taken along line IV-IV′ of FIG. 10A;

FIG. 10C is a cross-sectional view of the display module taken along line V-V′ of FIG. 10A:

FIGS. 10D and 10E are enlarged views of a portion of FIG. 10B:

FIG. 10F is a photographed image of a first contact area of FIG. 10A:

FIGS. 11A to 11L are cross-sectional views of a method of manufacturing a display module according to an embodiment of the present disclosure:

FIGS. 12A to 12I are cross-sectional views of a method of manufacturing a display module according to an embodiment of the present disclosure;

FIGS. 13 to 17 are enlarged cross-sectional views of a portion of a display module according to embodiments of the present disclosure;

FIG. 18 is a cross-sectional view of a display module according to an embodiment of the present disclosure;

FIGS. 19A to 19F are cross-sectional views of a method of manufacturing a display module according to an embodiment of the present disclosure:

FIGS. 20, 21A, and 21B are cross-sectional views of a display module according to embodiments of the present disclosure:

FIG. 22 is a cross-sectional view of a display module according to an embodiment of the present disclosure:

FIGS. 23A to 23I are cross-sectional views of a method of manufacturing a display module according to an embodiment of the present disclosure:

FIG. 24 is a cross-sectional view of a display module according to an embodiment of the present disclosure;

FIG. 25A is a cross-sectional view of a display module according to an embodiment of the present disclosure:

FIGS. 25B and 25C are cross-sectional views of a method of manufacturing a display module according to an embodiment of the present disclosure:

FIG. 26A is an enlarged plan view of a non-display area of a display module according to an embodiment of the present disclosure; and

FIG. 26B is a cross-sectional view of the display module taken along line VI-VI′ of FIG. 26A.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms “first”, “second”, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

For example, “about” can mean within one or more standard deviations, or within ±30%, 20%, 10% or 5% of the stated value. Hereinafter, embodiments of the present disclosure will be described with reference to accompanying drawings.

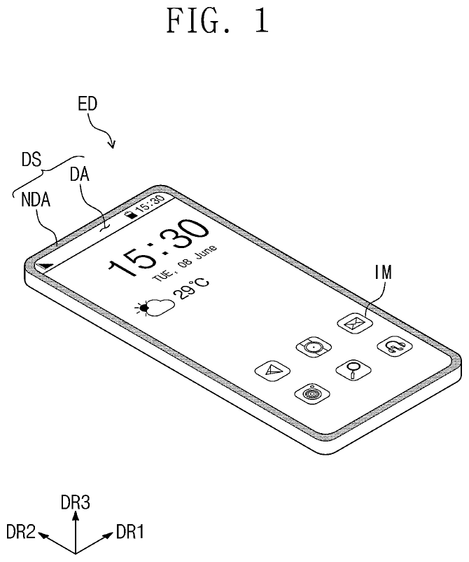

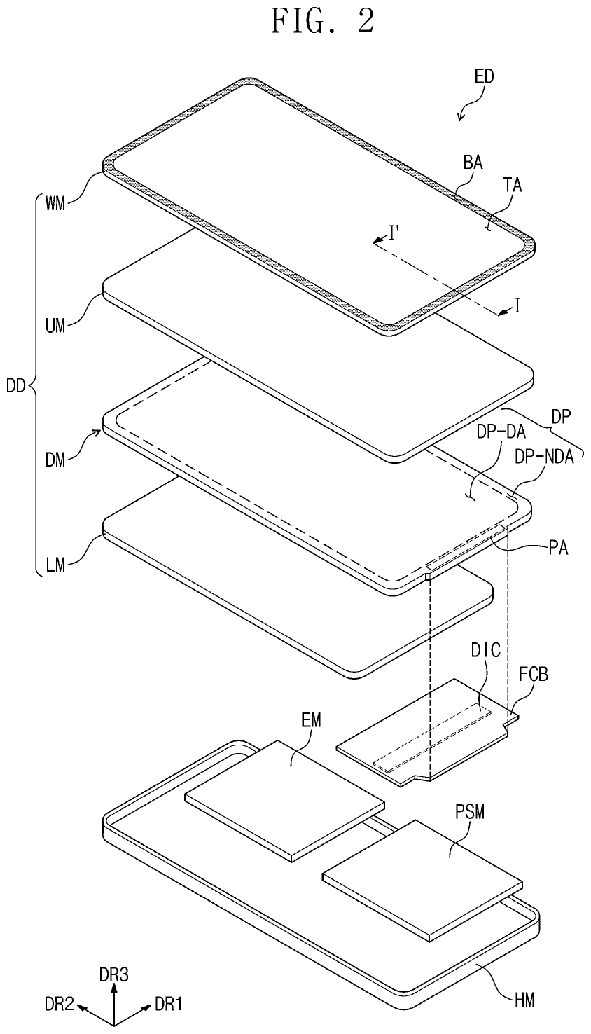

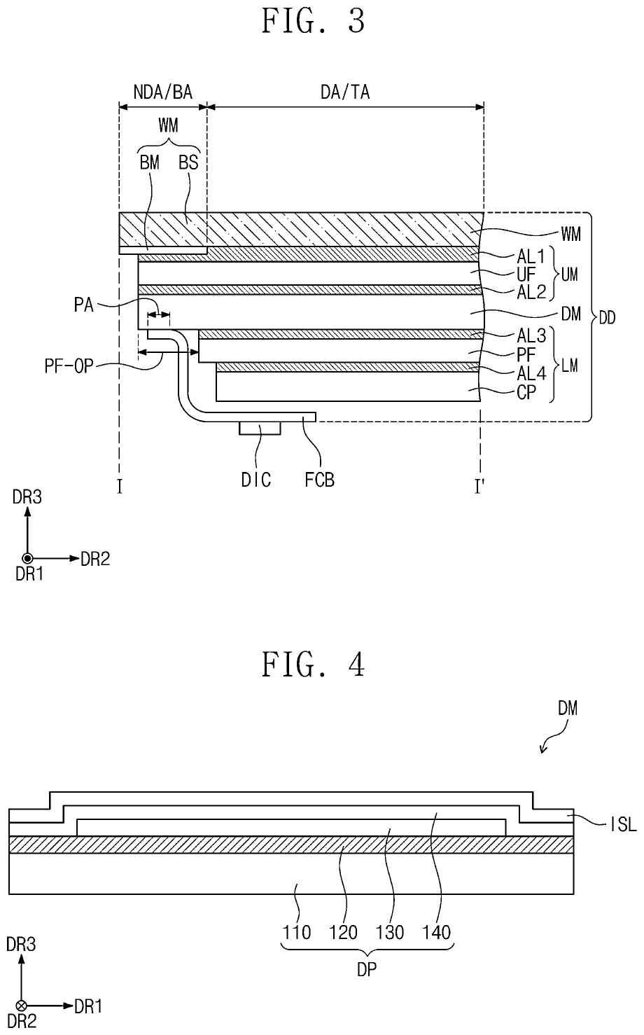

FIG. 1 is a perspective view of an electronic device ED according to an embodiment of the present disclosure. FIG. 2 is an exploded perspective view of the electronic device ED according to an embodiment of the present disclosure. FIG. 3 is a cross-sectional view of a display device DD according to an embodiment of the present disclosure.

Referring to FIG. 1, the electronic device ED may include a display surface DS defined by a first direction DRI and a second direction DR2 intersecting the first direction DR1. The electronic device ED may provide an image IM to a user through the display surface DS.

The display surface DS may include a display area DA and a non-display area NDA around the display area DA. The display area DA may display the image IM, and the non-display area NDA may not display the image IM. The non-display area NDA may surround the display area DA, however, it should not be limited thereto or thereby, and the shape of the display area DA and the shape of the non-display area NDA may be changed.

Hereinafter, a direction substantially perpendicular to the plane defined by the first direction DRI and the second direction DR2 may be referred to as a third direction DR3. Front and rear surfaces of each member of the electronic device ED may be distinguished from each other with respect to the third direction DR3. In the present disclosure, the expression “in a plan view” may mean a state of being viewed in the third direction DR3.

The electronic device ED may be a foldable electronic device folded with respect to a folding axis. The folding axis FX may be substantially parallel to the first direction DRI or the second direction DR2, and a folding area may be defined in a portion of the display area DA. The electronic device ED may be inwardly folded (inner-folding) to allow a portion of the display area DA to face the other portion of the display area DA or may be outwardly folded (outer-folding) to allow the portion of the display area DA not to face the other portion of the display area DA.

Referring to FIG. 2, the electronic device ED may include the display device DD, an electronic module EM, a power source module PSM, and a housing HM. Although schematically shown in FIG. 2, the electronic device ED may further include a mechanical structure (e.g., a hinge) to control an operation, for example, a folding or rolling operation, of the display device DD.

The display device DD may generate an image and may sense an external input. The display device DD may include a window WM, an upper member UM, a display module DM, a lower member LM, a flexible circuit board FCB, and a driving chip DIC. The upper member UM may include components disposed above the display module DM, and the lower member LM may include components disposed under the display module DM.

The window WM may provide a front surface of the electronic device ED. The window WM may include a transmission area TA and a bezel area BA. The display area DA and the non-display area NDA of the display surface DS shown in FIG. 1 may be defined by the transmission area TA and the bezel area BA. The transmission area TA may be an area through which the image passes, and the bezel area BA may be an area which covers structures/members disposed under the window WM.

The display module DM may include at least a display panel DP. FIG. 2 shows only the display panel DP among components of the display module DM, which are stacked one on another. However, the display module DM may further include a plurality of components disposed above the display panel DP in addition to the display panel DP. Detailed descriptions on the stack structure of the display module DM will be described later.

The display panel DP should not be particularly limited, and the display panel DP may be an organic light emitting display panel or an inorganic light emitting display panel. The display panel DP may include a display area DP-DA and a non-display area DP-NDA, which respectively correspond to the display area DA (refer to FIG. 1A) and the non-display area NDA (refer to FIG. 1A) of the electronic device ED. In the present disclosure, the expression “An area/portion corresponds to another area/portion.” means that “An area/portion overlaps another area/portion.”, however, they should not be limited to having the same size as each other.

A pad area PA of the display panel DP may be defined at one side of the non-display area DP-NDA. The pad area PA may be electrically bonded or connected to the flexible circuit board FCB described later. In the present embodiment, the pad area PA may be defined in a rear surface of the display panel DP.

The display panel DP may have a substantially quadrangular shape. The expression “a substantially quadrangular shape” used herein may mean not only the mathematical meaning of a rectangular shape, but also shapes that are similar to rectangles and perceived by the user as rectangles. For instance, the substantially quadrangular shape may include a quadrangular shape with a rounded corner. In addition, in the substantially rectangular shape, an edge of the display panel DP may have a curved area, and the edge should not be limited to a straight line.

The upper member UM may include a protective film or an optical film. The optical film may include a polarizer or a retarder to reduce a reflection of an external light. The lower member LM may include a protective film protecting the display panel DP, a support member supporting the display panel DP, and a digitizer. The upper member UM and the lower member LM will be described in detail later.

The flexible circuit board FCB shown in FIG. 2 may be disposed under the display panel DP. The flexible circuit board FCB may be bonded to the rear surface of the display panel DP and may electrically connect the display panel DP to a main circuit board. The flexible circuit board FCB may include at least one insulating layer and at least one conductive layer. The conductive layer may include a plurality of signal lines.

The driving chip DIC may be mounted on the flexible circuit board FCB. The driving chip DIC may include a driving circuit, e.g., a data driving circuit, to drive pixels of the display panel DP. FIG. 2 shows a structure in which the driving chip DIC is mounted on the flexible circuit board FCB, however, the present disclosure should not be limited thereto or thereby. As an example, the driving chip DIC may be mounted on the display panel DP or the main circuit board.

The electronic module EM may include a control module, a wireless communication module, an image input module, an audio input module, an audio output module, a memory, and an external interface module. The electronic module EM may include the main circuit board, and the modules may be mounted on the main circuit board or may be electrically connected to the main circuit board via a flexible circuit board. The electronic module EM may be electrically connected to the power source module PSM.

Although not shown in figures, the electronic device ED may further include an electro-optical module. The electro-optical module may be an electronic component that outputs or receives an optical signal. The electro-optical module may include a camera module and/or a proximity sensor. The camera module may take a picture of an external object via an area of the display panel DP.

The housing HM shown in FIG. 2 may be coupled to the display device DD, particularly, the window WM to accommodate the above-mentioned modules. The housing HM is shown as having an integral shape, however, it should not be limited thereto or thereby. The housing HM may include a plurality of portions, for instance, a side surface edge portion and a bottom portion, coupled to each other.

FIG. 3 additionally shows adhesive layers ALI to AL4 that are not illustrated in FIG. 2. The window WM may include a base substrate BS and a bezel pattern BP disposed on a lower surface of the base substrate BS. In the present embodiment, the base substrate BS may include a synthetic resin film or a glass substrate. The base substrate BS may have a multi-layer structure. The base substrate BS may include a thin glass substrate, a protective film disposed on the thin glass substrate, and an adhesive layer that attaches the thin glass substrate and the protective film.

The bezel pattern BP may be a colored light blocking layer and may be formed by a coating process. The bezel pattern BP may include a base material and a pigment or dye mixed with the base material. The bezel pattern BM may overlap the non-display area NDA shown in FIG. 1 and the bezel area BA shown in FIG. 2. The bezel pattern BM may be disposed on the lower surface of the base substrate BS. When the base substrate BS has a multi-layer structure, the bezel pattern BM may be disposed at an interface defined by plural layers. For instance, the bezel pattern BM may be disposed between the thin glass substrate and the protective film. Although not shown in figures, the window WM may include at least one of a hard coating layer, an anti-fingerprint layer, and an anti-reflective layer disposed on an upper surface of the base substrate BS.

The upper member UM may include an upper film UF. The upper film UF may include a synthetic resin film. The synthetic resin film may include polyimide, polycarbonate, polyamide, triacetyl cellulose, polymethylmethacrylate, or polyethylene terephthalate.

The upper film UF may absorb an external impact applied to a front surface of the display device DD. According to an embodiment, the display module DM may include a color filter as an anti-reflective member to replace a polarizing film, and in this case, an impact resistance of the display device DD with respect to external impacts applied to the front surface thereof may be reduced. The upper film UF may compensate for the reduction of the impact resistance to the external impacts, which is caused by applying the color filter to the display module DM.

The upper film UF may overlap the bezel area BA and the transmission area TA. The upper film UF may overlap only a portion of the bezel area BA. A portion of the bezel pattern BM may be exposed without being covered by the upper film UF. According to an embodiment, the upper film UF may be omitted. According to an embodiment, the upper film UF may be replaced with the optical film including the polarizer and the retarder.

The upper member UM may further include a first adhesive layer AL1 attaching the upper film UF and the window WM and a second adhesive layer AL2 attaching the upper film UF and the display module DM. The first adhesive layer AL1 and the second adhesive layer AL2 may be a pressure sensitive adhesive (“PSA”) film or an optically clear adhesive (“OCA”). Adhesive layers described hereinafter may include the same adhesive as the first adhesive layer AL1.

The display module DM may be disposed under the upper film UF. The display module DM may overlap the bezel area BA and the transmission area TA. The display module DM may completely overlap the upper film UF in the bezel area BA. A side surface of the display module DM may be aligned with a side surface of the upper film UF, and a corner of the display module DM may be aligned with a corner of the upper film UF in the plan view.

In the bezel area BA, the pad area PA may overlap the upper film UF. A portion of the display module DM, which corresponds to the pad area PA, may be coupled with a lower surface of the upper film UF by the second adhesive layer AL2. As the pad area PA overlaps the upper film UF and the portion of the display module DM overlapping the pad area PA is coupled with the upper film UF, the upper film UF may sufficiently support the pad area PA when the flexible circuit board FCB is bonded to the pad area PA.

The lower member LM may include a lower film PF, a cover panel CP, a third adhesive layer AL3, and a fourth adhesive layer AL4. The lower member LM may further include a support plate and a digitizer.

The lower film PF may be disposed under the display module DM and may be coupled with a lower surface of the display module DM by the third adhesive layer AL3. The lower film PF may protect a lower portion of the display module DM. The lower film PF may include a flexible synthetic resin film. As an example, the lower film PF may include polyethylene terephthalate or polyimide, however, it should not be limited thereto or thereby.

The lower film PF may expose at least the pad area PA. The lower film PF may have an area smaller than that of the display module DM. For instance, the lower film PF may overlap only the display area DA.

The lower film PF may have substantially the same area as the display module DM. The lower film PF may include an opening area PF-OP defined therein to correspond to the pad area PA (refer to FIG. 3). Even though the lower film PF entirely protects the lower surface of the display module DM, the opening area PF-OP may be defined to allow the flexible circuit board FCB to be adjacent to the pad area PA.

As shown in FIG. 3, the fourth adhesive layer AL4 may attach the lower film PF and the cover panel CP. The cover panel CP may increase a resistance against a compressive force caused by external pressure force. Accordingly, the cover panel CP may prevent the display panel DP from being deformed. The cover panel CP may include a flexible plastic material, such as polyimide or polyethylene terephthalate. In addition, the cover panel CP may be a colored film with low light transmittance. The cover panel CP may absorb a light incident thereto from the outside. As an example, the cover panel CP may be a black synthetic resin film. When looking at the display device DD from an upper side of the window WM, components disposed under the cover panel CP may not be viewed by the user.

The support plate may be further disposed under the cover panel CP. The support plate may include a high-strength metal material. The support plate may include a reinforced fiber composite material. The support plate may include a reinforced fiber disposed in a matrix portion. The reinforced fiber may be a carbon fiber or a glass fiber. The matrix portion may include a polymer resin. The matrix portion may include a thermoplastic resin. As an example, the matrix portion may include a polyamide-based resin or a polypropylene-based resin. For example, the reinforced fiber composite material may be a carbon fiber reinforced plastic (“CFRP”) or a glass fiber reinforced plastic (“GFRP”).

FIG. 4 is a cross-sectional view of the display module DM according to an embodiment of the present disclosure.

Referring to FIG. 4, the display module DM may include the display panel DP and an input sensor ISL. The display panel DP may include a base layer 110, a driving element layer 120, a light emitting element layer 130, and an encapsulation layer 140.

The driving element layer 120 may be disposed on the base layer 110. The base layer 110 may be a flexible substrate that is bendable, foldable, or rollable. The base layer 110 may be a glass substrate, a metal substrate, or a polymer substrate, however, it should not be limited thereto or thereby. According to an embodiment, the base layer 110 may be an inorganic layer, an organic layer, or a composite material layer. The base layer 110 may have substantially the same shape as the display panel DP.

The base layer 110 may have a multi-layer structure. For instance, the base layer 110 may include a first synthetic resin layer, a second synthetic resin layer, and inorganic layers disposed between the first synthetic resin layer and the second synthetic resin layer. Each of the first and second synthetic resin layers may include a polyimide-based resin, however, it should not be particularly limited.

The driving element layer 120 may be disposed on the base layer 110. The driving element layer 120 may include a plurality of insulating layers, a plurality of semiconductor patterns, a plurality of conductive patterns, and a plurality of signal lines. The driving element layer 120 may include a pixel driving circuit. Hereinafter, unless otherwise specified, the expression “Components A and B are disposed on the same layer.” means that components A and B are formed through the same process and contain the same material or have the same stack structure. The conductive patterns or semiconductor patterns disposed on the same layer may be understood as described above.

The light emitting element layer 130 may be disposed on the driving element layer 120. The light emitting element layer 130 may include a light emitting element. For example, the light emitting element may include an organic light emitting material, an inorganic light emitting material, an organic-inorganic light emitting material, a quantum dot, a quantum rod, a micro-LED, or a nano-LED.

The encapsulation layer 140 may be disposed on the light emitting element layer 130. The encapsulation layer 140 may protect the light emitting element layer 130 from moisture, oxygen, and a foreign substance such as dust particles. The encapsulation layer 140 may include at least one encapsulation inorganic layer. The encapsulation layer 140 may include a stack structure in which a first encapsulation inorganic layer, an encapsulation organic layer, and a second encapsulation inorganic layer are sequentially stacked.

The input sensor ISL may be disposed directly on the display panel DP. The input sensor ISL may sense a user's input by an electromagnetic induction method or a capacitive method. The input sensor ISL and the display panel DP may be formed through successive processes. The expression “being directly disposed on” as used herein may mean that no intervening elements are disposed between the input sensor ISL and the display panel DP. That is, a separate adhesive layer may not be disposed between the input sensor ISL and the display panel DP.

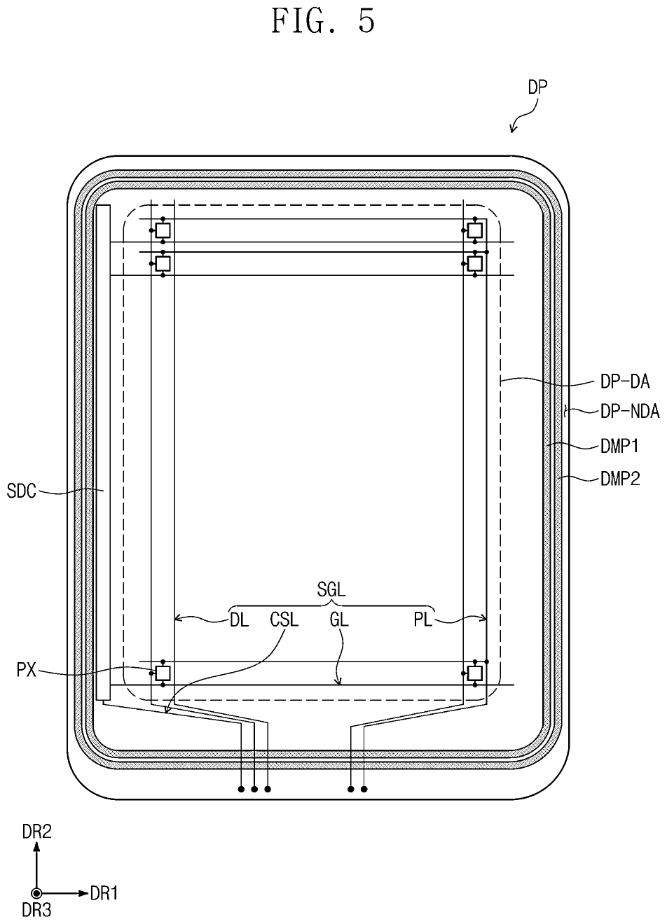

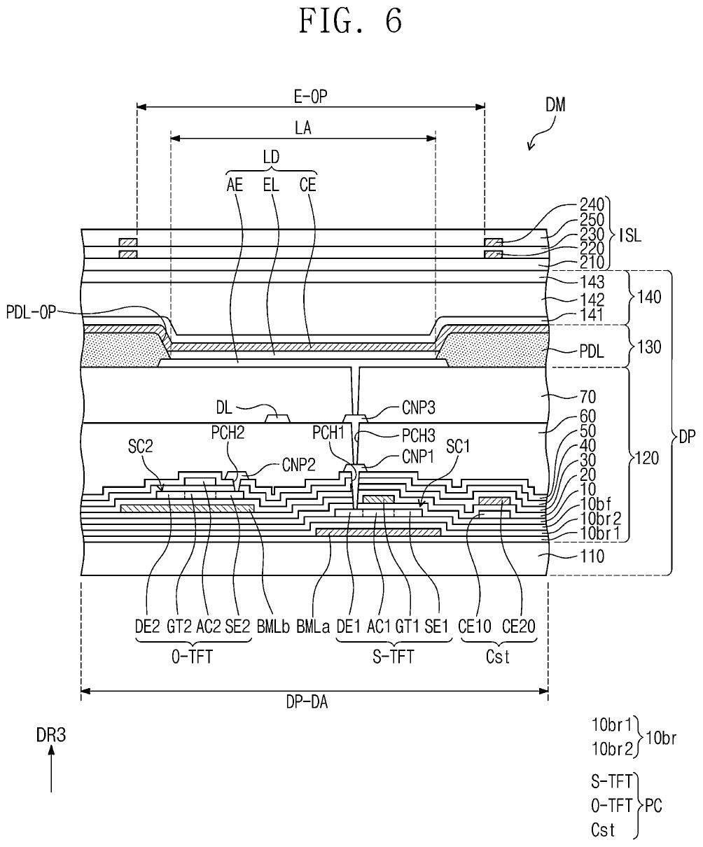

FIG. 5 is a plan view of the display panel DP according to an embodiment of the present disclosure. FIG. 6 is a cross-sectional view of the display module DM according to an embodiment of the present disclosure.

Referring to FIG. 5, the display panel DP may include a scan driving circuit SDC, a plurality of signal lines SGL, and a plurality of pixels PX. The pixels PX may be arranged in the display area DP-DA. Each of the pixels PX may include the light emitting element and the pixel driving circuit connected to the light emitting element. The scan driving circuit SDC, the signal lines SGL, and the pixel driving circuit may be included in the driving element layer 120 shown in FIG. 4.

The scan driving circuit SDC may include a gate driving circuit. The gate driving circuit may generate a plurality of scan signals and may sequentially output the scan signals to a plurality of scan lines GL described later. The scan driving circuit SDC may further include a light emission driving circuit distinguished from the gate driving circuit. The light emission driving circuit may further output scan signals to another group of scan lines.

The scan driving circuit SDC may include a plurality of thin film transistors formed through the same processes, e.g., a low temperature polycrystalline silicon (“LTPS”) process or a low temperature polycrystalline oxide (“LTPO”) process, as the pixel driving circuit.

The signal lines SGL may include the scan lines GL, data lines DL, a power line PL, and a control signal line CSL. Each of the scan lines GL may be connected to a corresponding pixel PX among the pixels PX, and each of the data lines DL may be connected to a corresponding pixel PX among the pixels PX. The power line PL may be connected to the pixels PX. The data lines DL may provide data signals to the pixels PX. The control signal line CSL may provide control signals to the scan driving circuit SDC.

As shown in FIG. 8, the power line PL may include a first power line PL1 receiving a first power supply voltage and a second power line PL2 receiving a second power supply voltage having a level higher than the first power supply voltage. The first power supply voltage may be provided to the pixel PX via the first power line PL1, and the second power supply voltage may be provided to the pixel PX via the second power line PL2. One control signal line CSL is shown as a representative example, however, the control signal line CSL may be provided in plural.

The scan lines GL, the data lines DL, and the power line PL may overlap the display area DP-DA and the non-display area DP-NDA, and the control signal line CSL may overlap the non-display area DP-NDA. Ends of the signal lines SGL may be aligned with one side of the non-display area DP-NDA. Each of the signal lines SGL may have an integral shape, but may include a plurality of portions disposed on different layers. The different portions distinguished from each other by the insulating layer may be connected to each other via a contact hole defined through the insulating layer. For instance, the data lines DL may include a first portion disposed in the display area DP-DA and a second portion disposed in the non-display area DP-NDA and disposed on a different layer from the first portion. The first portion and the second portion may include different materials from each other and may have different stack structures from each other.

The display panel DP may include insulating patterns DMP1 and DMP2. FIG. 5 shows first and second insulating patterns DMPI and DMP2 as a representative example. The first and second insulating patterns DMP1 and DMP2 may be disposed in the non-display area DP-NDA and may surround the display area DP-DA. Each of the first and second insulating patterns DMP1 and DMP2 may have a closed-line shape. The first and second insulating patterns DMP1 and DMP2 may serve as a dam to prevent a liquid organic material from overflowing in an inkjet process of the display panel DP. Details on the insulating patterns will be described later.

FIG. 6 shows a cross-section of the display module DM corresponding to the pixel PX of FIG. 5.

The pixel driving circuit PC that drives the light emitting element LD may include a plurality of pixel driving elements. The pixel driving circuit PC may include a plurality of transistors and a capacitor Cst. FIG. 6 shows a silicon transistor S-TFT and an oxide transistor O-TFT as a representative example of the transistor. The pixel driving circuit PC of FIG. 6 is merely an example, and components of the pixel driving circuit PC should not be limited thereto or thereby. The pixel driving circuit PC may include only one type of transistor between the silicon transistor S-TFT and the oxide transistor O-TFT.

Referring to FIG. 6, the base layer 110 has a single-layer structure. The base layer 110 may include a synthetic resin such as polyimide. The base layer 110 may be formed by coating a synthetic resin layer on a work substrate (or a carrier substrate). When the display module DM is completed through subsequent processes, the work substrate may be removed.

Referring to FIG. 6, a barrier layer 10br may be disposed on the base layer 110. The barrier layer 10br may prevent a foreign substance from entering thereinto from the outside. The barrier layer 10br may include at least one inorganic layer. The barrier layer 10br may include a silicon oxide layer and a silicon nitride layer. Each of the silicon oxide layer and the silicon nitride layer may be provided in plural, and the silicon oxide layers may be alternately stacked with the silicon nitride layers.

The barrier layer 10br may include a lower barrier layer 10br1 and an upper barrier layer 10br2. A first shielding electrode BMLa may be disposed between the lower barrier layer 10br1 and the upper barrier layer 10br2. The first shielding electrode BMLa may be disposed to correspond to the silicon transistor S-TFT. The first shielding electrode BMLa may include a metal material, e.g., molybdenum.

The first shielding electrode BMLa may receive a bias voltage. The first shielding electrode BMLa may receive the first power supply voltage. The first shielding electrode BMLa may prevent an electric potential caused by a polarization phenomenon from exerting influence on the silicon transistor S-TFT. The first shielding electrode BMLa may prevent an external light from reaching the silicon transistor S-TFT. According to an embodiment, the first shielding electrode BMLa may be a floating electrode isolated from other electrodes or lines.

A buffer layer 10bf may be disposed on the barrier layer 10br. The buffer layer 10bf may prevent metal atoms or impurities from being diffused to a first semiconductor pattern SC1 disposed thereon from the base layer 110. The buffer layer 10bf may include at least one inorganic layer. The buffer layer 10bf may include a silicon oxide layer and a silicon nitride layer.

The first semiconductor pattern SC1 may be disposed on the buffer layer 10bf. The first semiconductor pattern SC1 may include a silicon semiconductor. As an example, the silicon semiconductor may include amorphous silicon or polycrystalline silicon. For example, the first semiconductor pattern SC1 may include low temperature polycrystalline silicon.

The first semiconductor pattern SC1 may have different electrical properties depending on whether it is doped or not or whether it is doped with an N-type dopant or a P-type dopant. The first semiconductor pattern SC1 may include a first region having a relatively high conductivity and a second region having a relatively low conductivity. The first region may be doped with the N-type dopant or the P-type dopant. A P-type transistor may include a doped region doped with the P-type dopant, and an N-type transistor may include a doped region doped with the N-type dopant. The second region may be a non-doped region or a region doped at a concentration lower than that of the first region. In the present embodiment, the first semiconductor pattern SC1 may be the N-type transistor.

The first region may have a conductivity greater than that of the second region and may substantially serve as an electrode or signal line. The second region may substantially correspond to a channel area (or an active area) of the transistor. In other words, a portion of the first semiconductor pattern SC1 may be a channel of the transistor, another portion of the first semiconductor pattern SC1 may be a source or a drain of the transistor, and the other portion of the first semiconductor pattern SC1 may be a connection electrode or a connection signal line.

A source area SE1, a channel area AC1 (or an active area), and a drain area DE1 of the silicon transistor S-TFT may be formed from the first semiconductor pattern SC1. The source area SE1 and the drain area DE1 may extend in opposite directions to each other from the channel area AC1.

A first insulating layer 10 may be disposed on the buffer layer 10bf. The first insulating layer 10 may cover the first semiconductor pattern SC1. The first insulating layer 10 may be an inorganic layer. The first insulating layer 10 may have a single-layer structure of a silicon oxide layer, however, it should not be limited thereto or thereby. Not only the first insulating layer 10, but also an inorganic layer of the driving element layer 120 described later may have a single-layer or multi-layer structure and may include at least one of a silicon nitride, a silicon oxynitride, and a silicon oxide, however, it should not be limited thereto or thereby.

A gate GT1 of the silicon transistor S-TFT may be disposed on the first insulating layer 10. The gate GT1 may be a portion of a metal pattern. The gate GT1 may overlap the channel area AC1. The gate GT1 may be used as a mask in a process of doping the first semiconductor pattern SC1. A first electrode CE10 of the capacitor Cst may be disposed on the first insulating layer 10. Different from those shown in FIG. 6, the gate GT1 and the first electrode CE10 may be provided integrally with each other.

A second insulating layer 20 may be disposed on the first insulating layer 10 and may cover the gate GT1. An upper electrode may be further disposed on the second insulating layer 20 to overlap the gate GT1. A second electrode CE20 may be disposed on the second insulating layer 20 to overlap the first electrode CE10. The upper electrode may be provided integrally with the second electrode CE20 in a plan view.

A second shielding electrode BMLb may be disposed on the second insulating layer 20. The second shielding electrode BMLb may be disposed to correspond to the oxide transistor O-TFT. According to an embodiment, the second shielding electrode BMLb may be omitted. According to an embodiment, the first shielding electrode BMLa may extend to a lower portion of the oxide transistor O-TFT and may replace the second shielding electrode BMLb.

A third insulating layer 30 may be disposed on the second insulating layer 20. A second semiconductor pattern SC2 may be disposed on the third insulating layer 30. The second semiconductor pattern SC2 may include a channel area AC2 of the oxide transistor O-TFT. The second semiconductor pattern SC2 may include a metal oxide semiconductor. The second semiconductor pattern SC2 may include a transparent conductive oxide (“TCO”), such as indium tin oxide (“ITO”), indium zinc oxide (“IZO”), indium gallium zinc oxide (“IGZO”), zinc oxide (ZnOx), or indium oxide (In₂O₃).

The metal oxide semiconductor may include a plurality of areas SE2, AC2, and DE2 distinguished from each other depending on whether a transparent conductive oxide is reduced or not. The area (hereinafter, referred to as a “reduced area”) in which the transparent conductive oxide is reduced has a conductivity greater than that of the area (hereinafter, referred to as a “non-reduced area”) in which the transparent conductive oxide is not reduced. The reduced area may substantially act as the source/drain of the transistor or the signal line. The non-reduced area may substantially correspond to a semiconductor area (or the channel) of the transistor. In other words, a portion of the second semiconductor pattern SC2 may be the semiconductor area of the transistor, another portion of the second semiconductor pattern SC2 may be a source area SE2/a drain area DE2 of the transistor, and the other portion of the second semiconductor pattern SC2 may be a signal transmission area.

A fourth insulating layer 40 may be disposed on the third insulating layer 30. As shown in FIG. 6, the fourth insulating layer 40 may cover the second semiconductor pattern SC2. According to an embodiment, the fourth insulating layer 40 may be an insulating pattern that overlaps a gate GT2 of the oxide transistor O-TFT and exposes the source area SE2 and the drain area DE2.

The gate GT2 of the oxide transistor O-TFT may be disposed on the fourth insulating layer 40. The gate GT2 of the oxide transistor O-TFT may be a portion of a metal pattern. The gate GT2 of the oxide transistor O-TFT may overlap the channel area AC2.

A fifth insulating layer 50 may be disposed on the fourth insulating layer 40 and may cover the gate GT2. Each of the first to fifth insulating layers 10 to 50 may be an inorganic layer.

A first connection pattern CNP1 and a second connection pattern CNP2 may be disposed on the fifth insulating layer 50. The first connection pattern CNP1 and the second connection pattern CNP2 may be formed through the same process, and thus, the first connection pattern CNP1 and the second connection pattern CNP2 may include the same material and the same stack structure. The first connection pattern CNP1 may be connected to the drain area DE1 of the silicon transistor S-TFT via a first pixel contact hole PCH1 defined through the first, second, third, fourth, and fifth insulating layers 10, 20, 30, 40, and 50. The second connection pattern CNP2 may be connected to the source area SE2 of the oxide transistor O-TFT via a second pixel contact hole PCH2 defined through the fourth and fifth insulating layers 40 and 50. The connection relationship of the first connection pattern CNP1 and the second connection pattern CNP2 with respect to the silicon transistor S-TFT and the oxide transistor O-TFT should not be limited thereto or thereby.

A sixth insulating layer 60 may be disposed on the fifth insulating layer 50. A third connection pattern CNP3 may be disposed on the sixth insulating layer 60. The third connection pattern CNP3 may be connected to the first connection pattern CNPI via a third pixel contact hole PCH3 defined through the sixth insulating layer 60. The data line DL may be disposed on the sixth insulating layer 60. A seventh insulating layer 70 may be disposed on the sixth insulating layer 60 and may cover the third connection pattern CNP3 and the data line DL. The third connection pattern CNP3 and the data line DL may be formed through the same process, and thus, the third connection pattern CNP3 and the data line DL may include the same material and the same stack structure. Each of the sixth insulating layer 60 and the seventh insulating layer 70 may be an organic layer.

The first shielding electrode BMLa, the gate GT1 of the silicon transistor S-TFT, the second electrode CE20, and the gate GT2 of the oxide transistor O-TFT may include molybdenum (Mo), an alloy including molybdenum (Mo), titanium (Ti), or an alloy including titanium (Ti), which has a good heat resistance. The first connection pattern CNP1 and the second connection pattern CNP2 may include aluminum with high electrical conductivity. The first connection pattern CNP1 and the second connection pattern CNP2 may have a three-layer structure of titanium/aluminum/titanium.

The light emitting element LD may include an anode (or a first electrode) AE, a light emitting layer EL, and a cathode (or a second electrode) CE. The anode AE of the light emitting element LD may be disposed on the seventh insulating layer 70. The anode AE may be a (semi-)transmissive electrode or a reflective electrode. The anode AE may have a stack structure of ITO/Ag/ITO sequentially stacked. Positions of the anode AE and the cathode CE may be interchanged.

A pixel definition layer PDL may be disposed on the seventh insulating layer 70. The pixel definition layer PDL may be an organic layer. The pixel definition layer PDL may have a light absorbing property and may have a black color. As an example, the pixel definition layer PDL may include a black coloring agent. The black coloring agent may include a black dye or a black pigment. The black coloring agent may include a metal material, such as carbon black, chromium, or an oxide thereof. The pixel definition layer PDL may correspond to a light blocking pattern having a light blocking property.

The pixel definition layer PDL may cover a portion of the anode AE. As an example, an opening PDL-OP may be defined through the pixel definition layer PDL to expose a portion of the anode AE. A light emitting area LA may be defined to correspond to the opening PDL-OP. In the present disclosure, a hole control layer may be disposed between the anode AE and the light emitting layer EL. The hole control layer may include a hole transport layer and may further include a hole injection layer. An electron control layer may be disposed between the light emitting layer EL and the cathode CE. The electron control layer may include an electron transport layer and may further include an electron injection layer.

The encapsulation layer 140 may cover the light emitting element LD. The encapsulation layer 140 may include an encapsulation inorganic layer 141, an encapsulation organic layer 142, and an encapsulation inorganic layer 143, which are sequentially stacked, however, layers forming the encapsulation layer 140 should not be limited thereto or thereby. The encapsulation inorganic layers 141 and 143 may include a silicon nitride layer, a silicon oxynitride layer, a silicon oxide layer, a titanium oxide layer, or an aluminum oxide layer. Each of the encapsulation inorganic layers 141 and 143 may have a multi-layer structure. The encapsulation organic layer 142 may include an acrylic-based organic layer, however, it should not be particularly limited.

The input sensor ISL may include at least one conductive layer (or at least one sensor conductive layer) and at least one insulating layer (or at least one sensor insulation layer). In the present embodiment, the input sensor ISL may include a first insulating layer 210 (or a first sensor insulation layer), a first conductive layer 220, a second insulating layer 230 (or a second sensor insulation layer), a second conductive layer 240, and a third insulating layer 250 (or a third sensor insulation layer). FIG. 6 schematically shows a conductive line of the first conductive layer 220 and a conductive line of the second conductive layer 240.

The first insulating layer 210 may be disposed directly on the display panel DP. The first insulating layer 210 may be an inorganic layer including at least one of silicon nitride, silicon oxynitride, and silicon oxide. Each of the first conductive layer 220 and the second conductive layer 240 may have a single-layer structure or a multi-layer structure of layers stacked in the third direction DR3. The first conductive layer 220 and the second conductive layer 240 may include conductive lines that define an electrode of a mesh shape. The conductive line of the first conductive layer 220 and the conductive line of the second conductive layer 240 may be connected to each other via a contact hole defined through the second insulating layer 230 or may not be connected to each other depending on their positions. The connection relationship between the conductive line of the first conductive layer 220 and the conductive line of the second conductive layer 240 may be determined according to the type of sensor for the input sensor ISL.

The first conductive layer 220 and the second conductive layer 240, which have the single-layer structure, may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnO), indium zinc tin oxide (ITZO), or the like. In addition, the transparent conductive layer may include conductive polymer such as PEDOT, metal nanowire, graphene, or the like.

The first conductive layer 220 and the second conductive layer 240, which have the multi-layer structure, may include metal layers. The metal layers may have a three-layer structure of titanium/aluminum/titanium. The first conductive layer 220 and the second conductive layer 240, which have the multi-layer structure, may include at least one metal layer and at least one transparent conductive layer. The second insulating layer 230 may be disposed between the first conductive layer 220 and the second conductive layer 240. The third insulating layer 250 may cover the second conductive layer 240. According to an embodiment, the third insulating layer 250 may be omitted. The second insulating layer 230 and the third insulating layer 250 may include an inorganic layer or an organic layer.

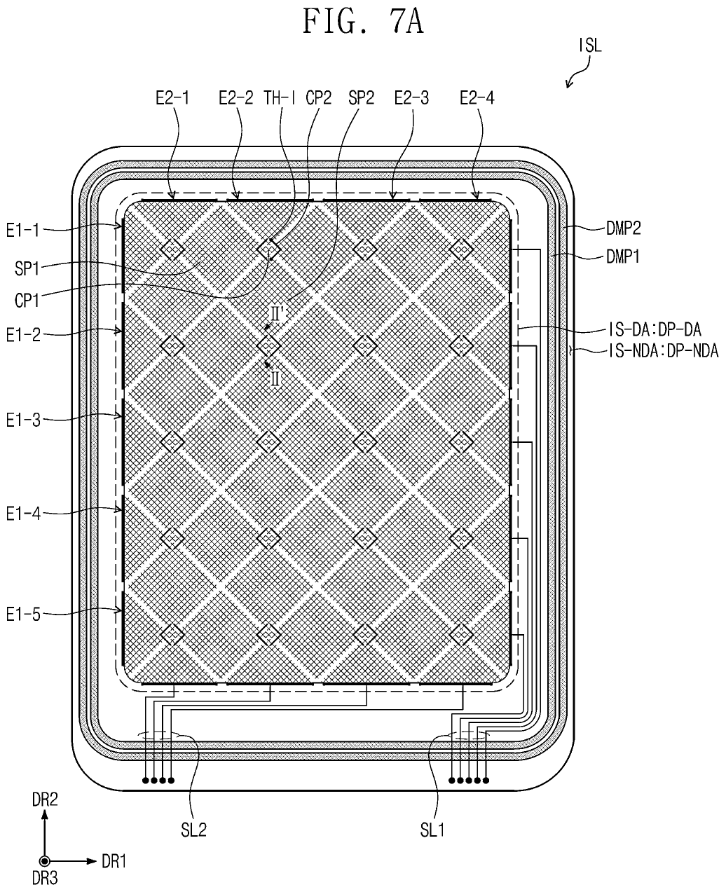

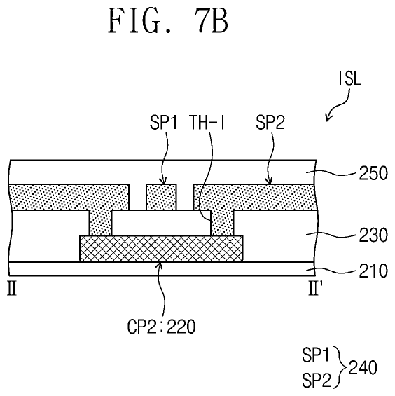

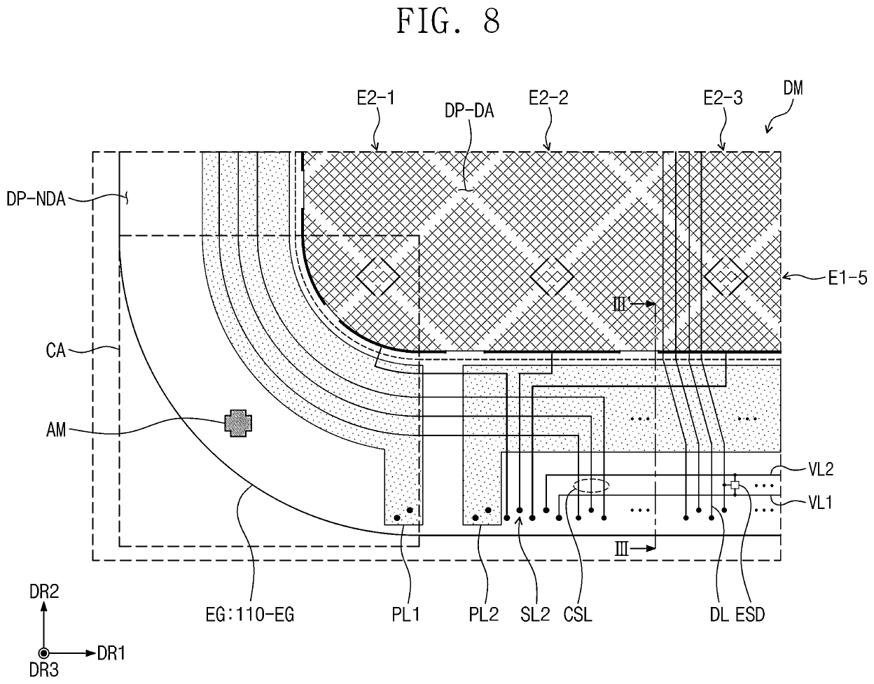

FIG. 7A is a plan view of the input sensor ISL according to an embodiment of the present disclosure, and FIG. 7B is a cross-sectional view of the input sensor ISL taken along line II-II′ of FIG. 7A.

Referring to FIG. 7A, the input sensor ISL may include a sensing area IS-DA and a non-sensing area IS-NDA adjacent to the sensing area IS-DA. The sensing area IS-DA and the non-sensing area IS-NDA may respectively correspond to the display area DP-DA and the non-display area DP-NDA shown in FIG. 5. The input sensor ISL may include first electrodes (or first sensing electrodes) E1-1 to E1-5, second electrodes (or second sensing electrodes) E2-1 to E2-4, first signal lines (or first sensor signal lines) SL1, and second signal lines (or second sensor signal lines) SL2. The first and second insulating patterns DMP1 and DMP2 are additionally illustrated in FIG. 7A to show a relative position of the first and second insulating patterns DMP1 and DMP2 with respect to the input sensor ISL.

The first electrodes E1-1 to E1-5 and the second electrodes E2-1 to E2-4 insulated from the first electrodes E1-1 to E1-5 while intersecting the first electrodes E1-1 to E1-5 may be arranged in the sensing area IS-DA. The first signal lines SL1 connected to the first electrodes E1-1 to E1-5 and the second signal lines SL2 electrically connected to the second electrodes E2-1 to E2-4 may be arranged in the non-sensing area IS-NDA. One of the first signal lines SL1 and the second signal lines SL2 may apply a driving signal from an external circuit to corresponding electrodes to sense an external input, and the other of the first signal lines SL1 and the second signal lines SL2 may output a sensing signal. A variation in capacitance between the first electrodes E1-1 to E1-5 and the second electrodes E2-1 to E2-4 may be measured based on the sensing signal. In the present embodiment, an input sensor operated in a mutual capacitance mode is shown as a representative example, however, the present disclosure should not be limited thereto or thereby. According to an embodiment, an input sensor operated in a self-capacitance mode may be used. The input sensor operated in the self-capacitance mode may include one type of sensing electrodes.

Each of the first electrodes E1-1 to E1-5 and the second electrodes E2-1 to E2-4 may have a mesh shape defining a plurality of openings. The openings may be defined to correspond to the light emitting area LA (refer to FIG. 6) of the display panel DP. FIG. 6 shows an opening E-OP corresponding to one light emitting area. The second electrodes E2-1 to E2-4 may be insulated from the first electrodes E1-1 to E1-5 while intersecting the first electrodes E1-1 to E1-5. One of the first electrodes E1-1 to E1-5 and the second electrodes E2-1 to E2-4 may be provided integrally with each other. In the present embodiment, the first electrodes E1-1 to E1-5 provided integrally with each other are shown as a representative example. The first electrodes E1-1 to E1-5 may include sensing portions SP1 and intermediate portions CP1.

Each of the second electrodes E2-1 to E2-4 may include sensing patterns SP2 and bridge patterns (or connection patterns) CP2. Two sensing patterns SP2 adjacent to each other may be connected by two bridge patterns CP2, however, the number of the bridge patterns should not be limited thereto or thereby.

Referring to FIGS. 6 to 7B, the bridge patterns CP2 may be formed from the first conductive layer 220, and the first electrodes E1-1 to E1-5 and the sensing patterns SP2 may be formed from the second conductive layer 240. The bridge pattern CP2 may be connected to the sensing patterns SP2 via a contact hole TH-I defined through the second insulating layer 230.

In the present embodiment, each of the first signal lines SL1 and the second signal lines SL2 of FIG. 7A may be formed from the first conductive layer 220 of FIG. 6. Accordingly, each of the first signal lines SL1 and the second signal lines SL2 of FIG. 7A may be disposed on the same layer as the bridge pattern CP2 of FIG. 7B, however, the present disclosure should not be limited thereto or thereby. According to an embodiment, each of the first signal lines SL1 and the second signal lines SL2 may be formed from the second conductive layer 240. Each of the first signal lines SL1 and the second signal lines SL2 may include a line formed from the first conductive layer 220 and a line formed from the second conductive layer 240.

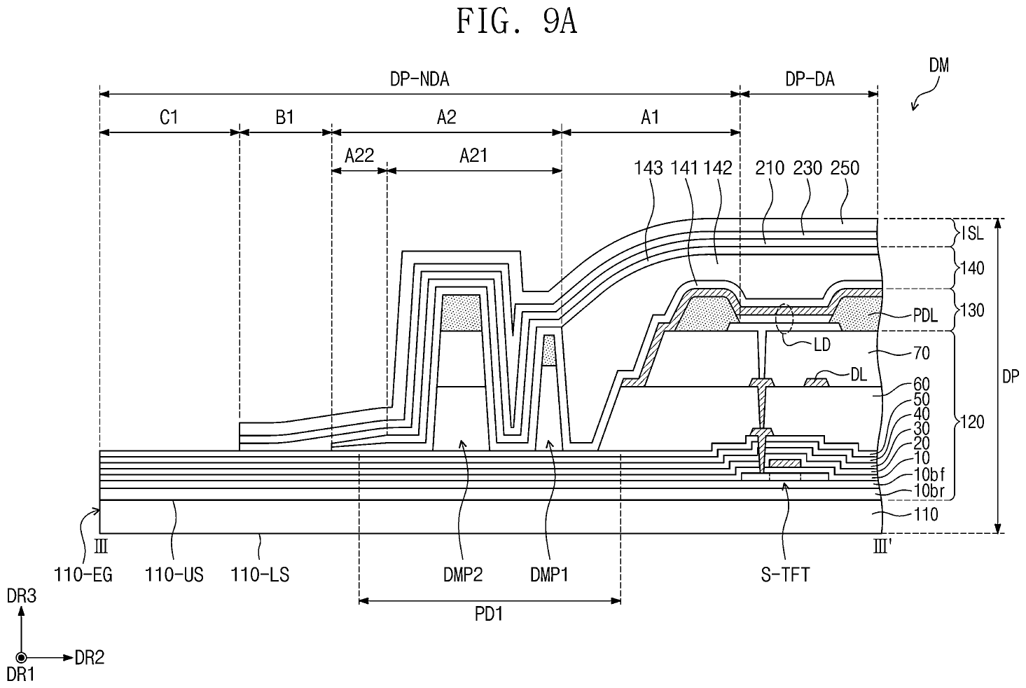

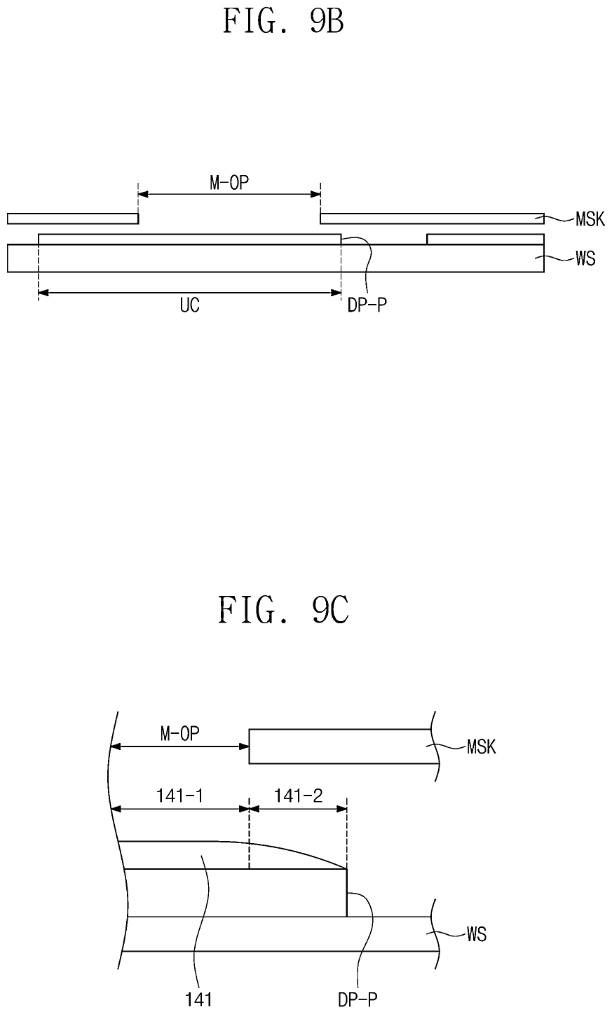

FIG. 8 is an enlarged plan view of the non-display area of the display module DM according to an embodiment of the present disclosure. FIG. 9A is a cross-sectional view of the display module DM taken along line III-III′ of FIG. 8, FIG. 9B is a cross-sectional view of a deposition process according to an embodiment of the present disclosure, and FIG. 9C is an enlarged cross-sectional view of a portion of FIG. 9B.

Referring to FIGS. 8 and 9A, the display area DP-DA and the non-display area DP-NDA of the display module DM are assigned with the same reference numerals as those of the display area DP-DA and the non-display area DP-NDA of the display panel DP of FIG. 5. In addition, the display area DP-DA and the non-display area DP-NDA may respectively correspond to the sensing area IS-DA and the non-sensing area IS-NDA of FIG. 7A. In FIG. 8, the electrode E1-5 of the first electrodes E1-1 to E1-5 and the electrodes E2-1 to E2-3 of the second electrodes E2-1 to E2-4 of FIG. 7A are shown in the display area DP-DA, and components of the display panel DP are not shown in the display area DP-DA.

FIG. 8 shows an enlarged view of one corner area (or a vertex area) CA and the non-display area DP-NDA disposed at a lower side of the display area DP-DA in the plan view with respect to FIGS. 5 and 7A. Among components shown in FIG. 8, components overlapping each other are disposed on different layers from each other.

The first power line PL1 and the second power line PL2 may be disposed in the non-display area DP-NDA. The first power line PL1 may extend to the non-display area DP-NDA at a left side shown in FIG. 5 through the corner area CA. In the corner area CA, a boundary line between the display area DP-DA and the non-display area DP-NDA may be a curved line in the plan view. In FIG. 8, the boundary line between the display area DP-DA and the non-display area DP-NDA is represented by a dotted line.

The first power line PL1 may extend to the non-display area DP-NDA at an upper side and the non-display area DP-NDA at a right side after passing through the non-display area DP-NDA at the left side shown in FIG. 5. The second power line PL2 may be disposed in the non-display area DP-NDA disposed at the lower side of the display area DP-DA in the plan view and may extend in the first direction DR1. The first power line PL1 and the second power line PL2 may be disposed on the same layer as the third connection pattern CNP3 shown in FIG. 6.

A first voltage line VL1 and a second voltage line VL2 may be disposed in the non-display area DP-NDA. In the present embodiment, one first voltage line VL1 and one second voltage line VL2 are shown, however, the present disclosure should not be limited thereto or thereby, and each of the first voltage line VL1 and the second voltage line VL2 may be provided in plural. The first voltage line VL1 may receive a first voltage, and the second voltage line VL2 may receive a second voltage higher than the first voltage. According to an embodiment, the first voltage may be the first power supply voltage, and the second voltage may be the second power supply voltage.

The first voltage line VL1 and the second voltage line VL2 may not overlap the second power line PL2 and may be disposed lower than the second power line PL2 in the plan view. The first voltage line VL1 and the second voltage line VL2 may be disposed closer to an edge EG of the display module DM than the second power line PL2 is in the plan view. The edge EG of the display module DM may be an edge 110-EG of the base layer 110 shown in FIG. 9A. The edge 110-EG of the base layer 110 may indicate a side surface of the base layer in the plan view. The first power line PL1 and the second power line PL2 may be disposed on the same layer as the third connection pattern CNP3 shown in FIG. 6 or may be disposed on the same layer as the first connection pattern CNP1.

At least one control signal line CSL may be disposed in the non-display area DP-NDA. The control signal line CSL may be connected to the scan driving circuit SDC shown in FIG. 5 via the corner area CA. The control signal line CSL may overlap the first power line PL1 and the second power line PL2. The control signal line CSL may be disposed on the same layer as one of the first shielding electrode BMLa, the gate GT1 of the silicon transistor S-TFT, the second electrode CE20, and the gate GT2 of the oxide transistor O-TFT shown in FIG. 6.

The data lines DL may be disposed in the display area DP-DA and the non-display area DP-NDA. A portion of the data lines DL, which overlaps the display area DP-DA, may be disposed on the same layer as one of the first connection pattern CNP1 and the third connection pattern CNP3 shown in FIG. 6. A portion of the data lines DL, which overlaps the non-display area DP-NDA, may be disposed on the same layer as one of the first shielding electrode BMLa, the gate GT1 of the silicon transistor S-TFT, the second electrode CE20, and the gate GT2 of the oxide transistor O-TFT shown in FIG. 6. The portion of the data lines DL, which overlaps the display area DP-DA, and the portion of the data lines DL, which overlaps the non-display area DP-NDA, may be connected to each other via a contact hole defined through a corresponding insulating layer among the insulating layers 10br to 70 shown in FIG. 6. A connection point at which the portion of the data lines DL, which overlaps the display area DP-DA, and the portion of the data lines DL, which overlaps the non-display area DP-NDA, are connected to each other may be disposed in the non-display area DP-NDA adjacent to the boundary line between the display area DP-DA and the non-display area DP-NDA.

The data lines DL may intersect the first voltage line VL1, the second voltage line VL2, and the second power line PL2. An electrostatic protection circuit ESD connected to the data line DL, the first voltage line VL1, and the second voltage line VL2 may be disposed in the non-display area DP-NDA. The electrostatic protection circuit ESD may be disposed between the first voltage line VL1 and the second voltage line VL2. FIG. 8 shows one electrostatic protection circuit ESD as a representative example, however, the present disclosure should not be limited thereto or thereby. According to an embodiment, each of the data lines DL may be connected to a corresponding electrostatic protection circuit ESD. According to an embodiment, a plurality of static electricity protection circuits ESD may be connected to each of the data lines DL.

The second signal lines SL2 may be disposed in the non-display area DP-NDA. The second signal lines SL2 may overlap the control signal line CSL and may overlap the first power line PL1 or the second power line PL2. Each of the second signal lines SL2 may be connected to a corresponding electrode among the second electrodes E2-1 to E2-3 disposed in the display area DP-DA.

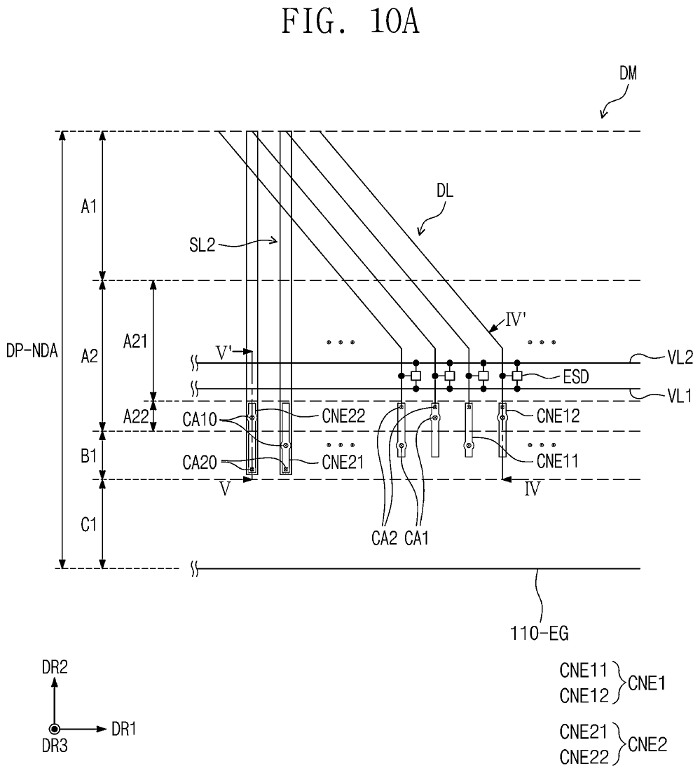

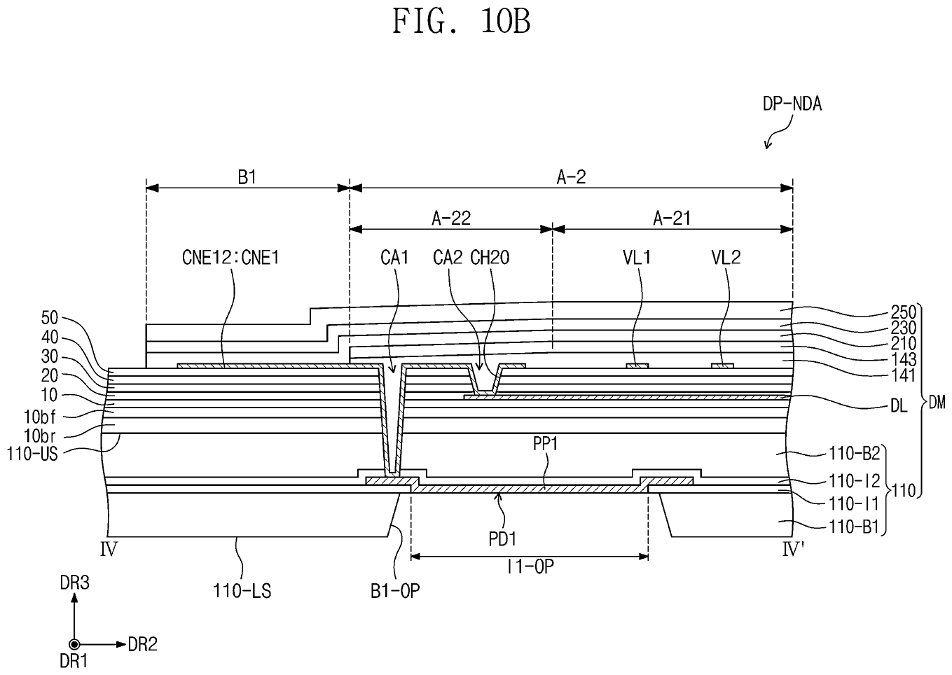

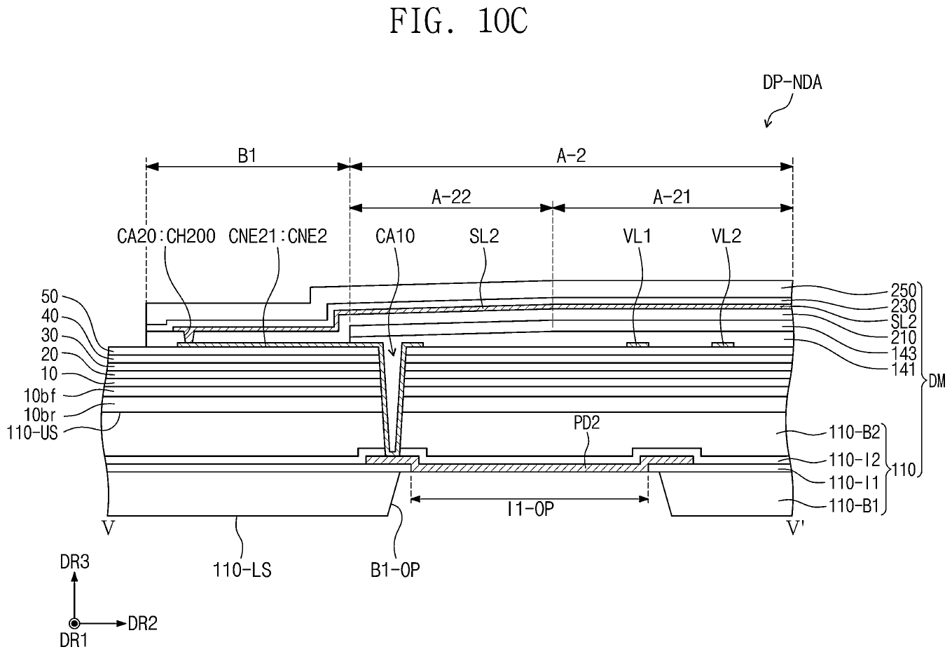

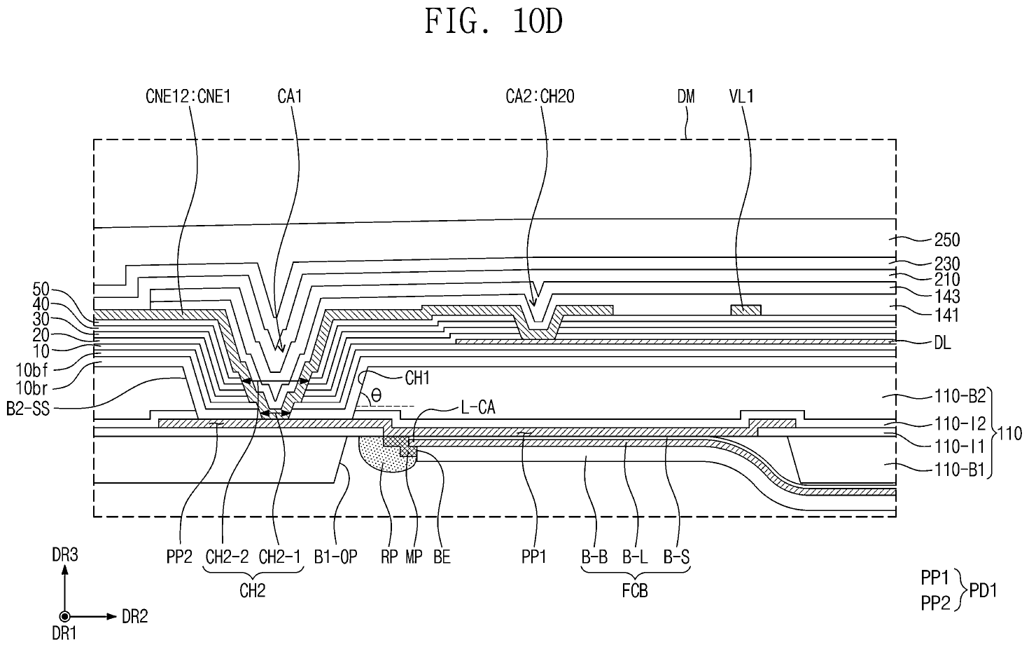

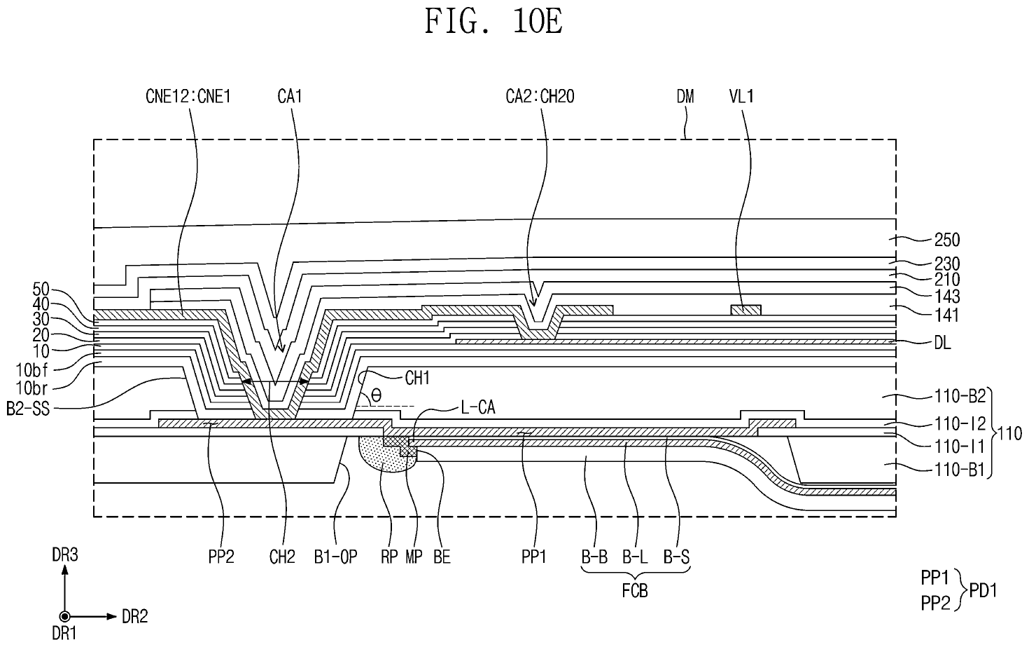

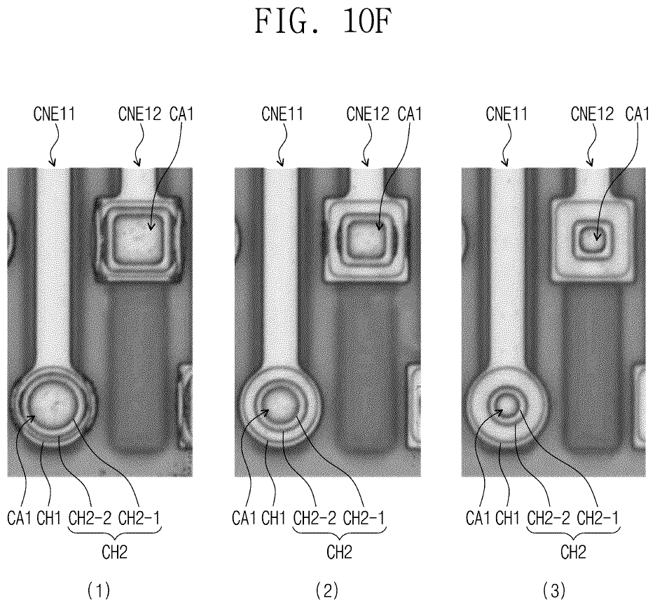

FIG. 8 shows an alignment mark AM disposed in the corner area CA as a representative example. The alignment mark AM may be used as a reference point for an alignment of the display module DM and a mask MSK (refer to FIG. 9B) in the deposition process. The alignment mark AM may be disposed on the same layer as a first pad electrode PD1 described later with reference to FIG. 10B and may be formed through the same process as the first pad electrode PD1.

FIG. 9A shows a cross-sectional structure of the non-display area DP-NDA taken along the line III-III′ of FIG. 8.

The structure of the base layer 110, the driving element layer 120, the light emitting element layer 130, the encapsulation layer 140, and the input sensor ISL, which are disposed in the display area DP-DA, is the same as the structure described with reference to FIG. 6, and thus, details thereof will be omitted. FIG. 9A schematically shows the silicon transistor S-TFT of the pixel driving circuit PC of FIG. 6. The insulating layers 10br to 70 and the pixel definition layer PDL, which are described with reference to FIG. 6, may extend from the display area DP-DA to the non-display area DP-NDA. The extended shapes of the insulating layers 10br to 70 and the pixel definition layer PDL may be different from each other.

The first insulating pattern DMP1 and the second insulating pattern DMP2, which are spaced apart from the sixth insulating layer 60, the seventh insulating layer 70, and the pixel definition layer PDL, may be disposed in the non-display area DP-NDA. The second insulating pattern DMP2 may be placed farther from the pixel definition layer PDL than the first insulating pattern DMP1 is. The first insulating pattern DMP1 and the second insulating pattern DMP2 may have a multi-layer structure. The first insulating pattern DMP1 may have a two-layer structure, and the second insulating pattern DMP2 may have a three-layer structure, however, they should not be limited thereto or thereby. The first insulating pattern DMP1 may include a first layer that is the same layer as the seventh insulating layer 70 and a second layer that is the same layer as the pixel definition layer PDL. The second insulating pattern DMP2 may include a first layer that is the same layer as the sixth insulating layer 60, a second layer that is the same layer as the seventh insulating layer 70, and a third layer that is the same layer as the pixel definition layer PDL. The first insulating pattern DMP1 may serve as a dam to prevent a liquid organic material from overflowing in a process of forming the encapsulation organic layer 142. The second insulating pattern DMP2 may be an auxiliary dam to supplement the first insulating pattern DMP1.

In the plan view, the non-display area DP-NDA disposed at the lower side or an outer side of the display area DP-DA shown in FIG. 8 may be divided into a plurality of areas distinguished from each other based on the cross-sectional structure shown in FIG. 9A. The non-display area DP-NDA overlapping the encapsulation organic layer 142 may be defined as an inner area A1. The inner area A1 may be defined as an area between the display area DP-DA and the first insulating pattern DMP1.

An outer area A2 may be defined in a direction from the inner area A1 toward the edge 110-EG of the base layer 110. The outer area A2 may be an area where the first encapsulation inorganic layer 141 is in contact with the second encapsulation inorganic layer 143. When the first encapsulation inorganic layer 141 is not accurately aligned with the second encapsulation inorganic layer 143 and only one of a portion of the first encapsulation inorganic layer 141 and a portion of the second encapsulation inorganic layer 143 extends farther toward the edge 110-EG of the base layer 110, the extended portion may also be included in the outer area A2.

The outer area A2 may include a first outer area A21 and a second outer area A22. The first outer area A21 may be disposed between the second outer area A22 and the inner area A1. In the second outer area A22, a thickness of the first encapsulation inorganic layer 141 and the second encapsulation inorganic layer 143 may be thinner than that in the first outer area A21, and a density of the first and second encapsulation inorganic layers 141 and 143 is low. The first outer area A21 and the second outer area A22 may correspond to a result of the deposition process described later.

The arrangement of the mask MSK and the work substrate WS in the deposition process is schematically shown in FIGS. 9B and 9C. As shown in FIGS. 9B and 9C, the mask MSK may be aligned with the work substrate WS. An opening M-OP may correspond to the display area DP-DA shown in FIG. 5. The opening M-OP may have a size equal to or greater than that of the display area DP-DA shown in FIG. 5. After the work substrate WS aligned with the mask MSK is loaded into a deposition chamber, an inorganic material may be deposited.

A preliminary display panel DP-P shown in FIGS. 9B and 9C may have a stack structure that includes layers from the base layer 110 to the light emitting element layer 130 of FIG. 6. Since the mask MSK is slightly spaced apart from the preliminary display panel DP-P, the inorganic material may be deposited in an area greater than the opening M-OP. Accordingly, the inorganic material may be deposited not only in the display area DP-DA, but also in the non-display area DP-NDA of FIG. 9A. Accordingly, the inner area Al and the outer area A2 described with reference to FIG. 9A may be formed.

As shown in FIG. 9C, since a first area 141-1 of the first encapsulation inorganic layer 141 overlaps the opening M-OP, the first encapsulation inorganic layer 141 may have a substantially uniform thickness in the first area 141-1. Since a second area 141-2 of the first encapsulation inorganic layer 141 overlaps the mask MSK, an amount of the inorganic material deposited in the second area 141-2 may be relatively small, and thus, the first encapsulation inorganic layer 141 in the second area 141-2 may have a thickness smaller than that of the first encapsulation inorganic layer 141 in the first area 141-1. The thickness of the second area 141-2 may decrease as a distance from the first area 141-1 increases. In addition, the second area 141-2 may have a density smaller than that of the first area 141-1. This is because an ashing gas, e.g., N₂O, used to remove residues existing in the mask MSK before depositing the encapsulation inorganic layer, and the ashing gas existing around the mask MSK disturbs the deposition of the inorganic material.

The first area 141-1 of FIG. 9C may correspond to an area of the first encapsulation inorganic layer 141 overlapping the display area DP-DA, the inner area A1, and the first outer area A2, which are described with reference to FIG. 9A. The second area 141-2 of FIG. 9C may correspond to the second outer area A22 described with reference to FIG. 9A.

The second encapsulation inorganic layer 143 of FIG. 9A may be formed in the method described with reference to FIGS. 9B and 9C. The first encapsulation inorganic layer 141 and the second encapsulation inorganic layer 143, which are formed using the same mask, may be aligned with each other, and each of the first encapsulation inorganic layer 141 and the second encapsulation inorganic layer 143 may include the second outer area A22 in FIG. 9A.

Referring to FIG. 9A again, an auxiliary area B1 may be defined outside the outer area A2 and may extend from the outer area A2 toward the edge 110-EG of the base layer 110. Hereinafter, in explaining the arrangement relationship between one area and another area, the expression “the another area is disposed outside of the one area. ” used herein may mean that the another area is disposed closer to the edge 110-EG of the base layer 110 than the one area is.

The encapsulation layer 140 may not be disposed in the auxiliary area B1, and at least one insulating layer among the first insulating layer 210, the second insulating layer 230, and the third insulating layer 250 of the input sensor ISL may be disposed in the auxiliary area B1. As shown in FIG. 9A, the edges of the first insulating layer 210, the second insulating layer 230, and the third insulating layer 250 may be aligned with each other, and an area between the outer area A2 and the edges of the first insulating layer 210, the second insulating layer 230, and the third insulating layer 250 may correspond to the auxiliary area B1. According to an embodiment, the third insulating layer 250 may be not disposed, or the edge of the third insulating layer 250 may be disposed closer to the edge of the base layer 110 than the edges of the first insulating layer 210 and the second insulating layer 230 of the input sensor ISL are.

Referring to FIG. 9A, a margin area CI may be defined outside the auxiliary area B1 and may extend from the auxiliary area B1 to the edge 110-EG of the base layer 110. The margin area CI may be defined between the auxiliary area B1 and the edge 110-EG of the base layer 110. The first insulating layer 210, the second insulating layer 230, and the third insulating layer 250 of the input sensor ISL may not be disposed in the margin area C1. An upper surface of the fifth insulating layer 50 of the driving element layer 120 may be exposed without being covered by the insulating layers 210, 230, and 250 of the input sensor ISL.

A deposition process, which is the same as the deposition process shown in FIGS. 9B and 9C, may be commonly performed for a plurality of unit cells in a manufacturing process of the display device. After the manufacturing process of the display device is completed, each of the unit cells may be separated from the work substrate and may be formed as the display module DM of FIG. 9A. The separation process may be performed by a cutting process, and the margin area CI may be secured in consideration of a tolerance error of the cutting process. FIGS. 9B and 9C show one unit cell UC among the unit cells.

FIG. 10A is an enlarged plan view of the non-display area DP-NDA of the display module DM according to an embodiment of the present disclosure. FIG. 10B is a cross-sectional view of the display module DM taken along line IV-IV′ of FIG. 10A. FIG. 10C is a cross-sectional view of the display module DM taken along line V-V′ of FIG. 10A. FIGS. 10D and 10E are enlarged views of a portion of FIG. 10B. FIG. 10F is a photographed image of a first contact area CA1 of FIG. 10A.

FIG. 10A shows a further enlarged display area DP-DA shown in FIG. 8, and the inner area A1, the outer area A2, the auxiliary area B1, and the margin area C1 of FIG. 9A are shown in FIG. 10A. Although not shown in FIG. 10A, the second power line PL2 may be disposed in the inner area A1. FIG. 10A shows a portion of the data lines DL and a portion of the second signal lines SL2.

The first voltage line VL1 and the second voltage line VL2 may be disposed in the first outer area A21. The electrostatic protection circuit ESD may be disposed in the first outer area A21. The electrostatic protection circuit ESD may include a first transistor diode-connected to the data line DL from the first voltage line VL1 and a second transistor diode connected to the second voltage line VL2 from the data line DL.

The first connection electrodes CNE1 and the second connection electrodes CNE2 may be disposed outside the first outer area A21. The first connection electrodes CNE1 may be disposed to correspond to the data lines DL in a one-to-one correspondence, and the second connection electrodes CNE2 may be disposed to correspond to the second signal lines SL2 in a one-to-one correspondence.

In the present embodiment, a portion of the first connection electrodes CNE1 and a portion of the second connection electrodes CNE2 may overlap the outer area A2. According to an embodiment, the first connection electrodes CNEI and the second connection electrodes CNE2 may entirely overlap the outer area A2. Positions of the first connection electrodes CNE1 and the second connection electrodes CNE2 are merely an example, and the positions of the first connection electrodes CNE1 and the second connection electrodes CNE2 may be changed.

A portion of each of the first connection electrodes CNE1 and the second connection electrodes CNE2 may overlap the second outer area A22. The first connection electrodes CNE1 and the second connection electrodes CNE2 may be disposed inside the second outer area A22 and the auxiliary area B1. As the portion of the first connection electrodes CNE1 and the portion of the second connection electrodes CNE2 overlap the second outer area A22, an additional area to dispose the first connection electrodes CNE1 and the second connection electrodes CNE2 may be reduced or omitted. In the case where the first connection electrodes CNE1 and the second connection electrodes CNE2 are disposed closer to the lower side, a size of the auxiliary area B1 increases. However, according to the present embodiment, the auxiliary area B1 may decrease, and thus, a size of the non-display area DP-NDA may be reduced.

A connection relationship between the first connection electrode CNE1 and the first pad electrode PDI will be described in detail with reference to FIG. 10B. According to the present embodiment, the first connection electrode CNE1 may be disposed on the same layer as the first connection pattern CNP1 of FIG. 6, and a portion of the data line DL, which overlaps the non-display area DP-NDA, may be disposed on the same layer as the gate GT1 of the silicon transistor S-TFT of FIG. 6.

The first pad electrode PDI may be exposed without being covered by a lower surface 110-LS of the base layer 110 for a rear surface bonding with the flexible circuit board FCB (refer to FIG. 2). The lower surface 110-LS of the base layer 110 may face an upper surface 110-US of the base layer 110 in the third direction DR3. The lower surface 110-LS of the base layer 110 may correspond to the rear surface of the display panel DP (refer to FIG. 9A).

FIG. 10B shows an arrangement relationship between the base layer 110 and the first pad electrode PD1. In the present embodiment, the first pad electrode PDI may be embedded into the base layer 110, however, the present disclosure should not be limited thereto or thereby. According to an embodiment, the first pad electrode PDI may be disposed on the lower surface 110-LS of the base layer 110. A first opening B1-OP and a second opening I1-OP, which are described later, may not be defined through the base layer 110 in a case where the base layer 110 includes a single-layer structure of a synthetic resin layer or even in a case where the base layer 110 includes a multi-layer structure. The first pad electrode PDI disposed on the lower surface 110-LS of the base layer 110 may be connected to a conductive pattern disposed on the upper surface 110-US of the base layer 110 via a contact hole defined through the base layer 110.

As shown in FIG. 10B, the base layer 110 may include a first synthetic resin layer 110-B1, a first base insulating layer 110-11, a second base insulating layer 110-12, and a second synthetic resin layer 110-B2. The first synthetic resin layer 110-B1 and the second synthetic resin layer 110-B2 may include a synthetic resin material, e.g., polyimide. The first base insulating layer 110-11 and the second base insulating layer 110-12 may include an inorganic material, e.g., silicon nitride, silicon oxynitride, or silicon oxide.

The first synthetic resin layer 110-B1 may provide the lower surface 110-LS of the base layer 110, and the first opening B1-OP may be defined through the first synthetic resin layer 110-B1 to expose the first pad electrode PDI to the outside of the display module DM (refer to FIG. 10A). The first base insulating layer 110-11 may be disposed on the first synthetic resin layer 110-B1, and the second opening 11-OP that exposes a portion PPI (hereinafter, referred to as a “first contact portion”) of the first pad electrode PDI and corresponds to the first opening B1-OP may be defined through the first base insulating layer 110-11. A portion of the first base insulating layer 110-11 may be exposed to the outside through the first opening B1-OP.

The first pad electrode PDI of FIG. 10B may be disposed in every first connection electrode CNE1 of FIG. 10A. The first pad electrodes PDI may be arranged spaced apart from each other in the first direction DRI to correspond to the arrangement of the first connection electrodes CNE1 of FIG. 10A. FIG. 10B shows the first pad electrode PD1 overlapping the first outer area A21 and the second outer area A22 as a representative example, however, the first pad electrode PD1 may further extend to the inner area A1 of FIG. 10A. Accordingly, the first opening B1-OP and the second opening 11-OP may further extend to the inner area A1. FIG. 9A schematically shows an area in which the first pad electrode PD1 that further extends is disposed.

The first opening B1-OP may commonly expose the first pad electrodes PD1. The first pad electrodes PD1 and areas between the first pad electrodes PD1 may be exposed through the first opening B1-OP. In contrast, the second opening 11-OP may be separately formed for each of the first pad electrodes PD1.

Referring to FIG. 10B, the second base insulating layer 110-I2 may be disposed on the first base insulating layer 110-I1 and may cover the first pad electrode PD1. The second synthetic resin layer 110-B2 may be disposed on the second base insulating layer 110-I2. The first connection electrode CNE1 may be connected to the first pad electrode PD1 via the first contact area CA1 and may be connected to the data line DL via a second contact area CA2. The first contact area CA1 and the second contact area CA2, which are disposed in the second outer area A22, are shown as a representative example, however, the position of the first and second contact areas CA1 and CA2 should not be particularly limited as long as the first and second contact areas CA1 and CA2 are disposed in the non-display area DP-NDA.

Detailed descriptions on the structure of the first contact area CA1 will be described with reference to FIG. 10D. A contact hole CH20 (hereinafter, referred to as a “third contact hole”) penetrating from the second insulating layer 20 to the fifth insulating layer 50 may be defined in the second contact area CA2. The first connection electrode CNE1 may be connected to the data line DL via the third contact hole CH20.

The structure in which the first connection electrode CNE1 connects the data line DL to the first pad electrode PD1 is described with reference to FIGS. 10A and 10B as a representative example. The arrangement relationship between the first connection electrode CNE1 and the first pad electrode PD1 with respect to the data line DL may be equally applicable to other signal lines shown in FIG. 8. For instance, the first connection electrode CNE1 and the first pad electrode PD1 may be disposed to correspond to the control signal line CSL, the first voltage line VL1, the second voltage line VL2, the first power line PL1, and the second power line PL2 of FIG. 8. The first pad electrode PD1 may be placed at each of the signal lines, and the plural first pad electrodes PD1 corresponding to the signal lines may be arranged in the first direction DR1 in FIG. 10A. The plural first pad electrodes PD1 may be arranged in some signal lines, for instance, the first power line PL1 and the second power line PL2.

Referring to FIG. 10A, a position of the first contact area CA1 may be different according to the first connection electrodes CNE1. The first contact areas CA1 adjacent to each other may be disposed staggered with respect to each other in a zigzag pattern along the first direction DR1. As the first contact areas CAI are disposed staggered with respect to each other or misaligned with respect to each other, a short-circuit defect between the first connection electrodes CNE1 adjacent to each other may be reduced in the process of forming contact holes of the first contact areas CA1.

The first connection electrode CNE1 may include a first-first connection electrode CNE11 and a first-second connection electrode CNE12, which are distinguished from each other according to the position of the first contact area CA1. The first-first connection electrode CNE11 may be alternately arranged with the first-second connection electrode CNE12 in the first direction DR1. The first-first connection electrode CNE11 may connect a first data line (or one data line) to a first-first pad electrode, and the first-second connection electrode CNE12 may connect a second data line (or another data line) adjacent to the first data line to a first-second pad electrode.

The second contact areas CA2 may be disposed in the second outer area A22. The first contact area CA1 corresponding to the first-first connection electrode CNE11 may be disposed in the auxiliary area B1, and the first contact area CA1 corresponding to the first-second connection electrode CNE12 may be disposed in the second outer area A22.

The second connection electrodes CNE2 may be disposed closer to an end of the auxiliary area B1 (or a boundary between the auxiliary area B1 and the margin area C1) than the first connection electrodes CNE1 are. This is because fourth contact areas CA20 corresponding to the second connection electrodes CNE2 are disposed outer than a third contact area CA10, which is aligned with the first contact area CA1, is. Hereinafter, a connection relationship between the second connection electrode CNE2 and a second pad electrode PD2 will be described in detail with reference to FIG. 10C.

Referring to FIG. 10C, the second pad electrode PD2 may be substantially the same as the first pad electrode PD1 described with reference to FIG. 10B. The second pad electrode PD2 may include the same material as the first pad electrode PD1 and may have the same stack structure as the first pad electrode PD1. The second pad electrode PD2 may be exposed without being covered by the lower surface 110-LS of the base layer 110 for the rear surface bonding of the flexible circuit board FCB (refer to FIG. 2). The second pad electrode PD2 may be embedded into the base layer 110 like the first pad electrode PD1. However, the second pad electrode PD2 may have a length greater than that of the first pad electrode PD1.

The second connection electrode CNE2 may be electrically connected to the second pad electrode PD2. The second connection electrode CNE2 may be connected to the second pad electrode PD2 through the third contact area CA10. The third contact area CA10 may have substantially the same structure as the first contact area CA1. Thus, details of the third contact area CA10 will be omitted here, and details of the first contact area CA1, which will be described with reference to FIG. 10D, may be equally applicable to the third contact area CA10 of FIG. 10C.

The second signal line SL2 may be electrically connected to the second connection electrode CNE2 via the fourth contact area CA20. A contact hole CH200 formed in the fourth contact area CA20 is shown as a representative example. In the present embodiment, since the second connection electrode CNE2 is disposed on the fifth insulating layer 50 and the sixth insulating layer 60 (refer to FIGS. 6 and 9A) and the seventh insulating layer 70 (refer to FIGS. 6 and 9A) are not disposed on the second connection electrode CNE2, the contact hole CH200 may not penetrate the insulating layers 10br to 70. The contact hole CH200 penetrating the first insulating layer 210 of the input sensor ISL is shown as a representative example. When a position of the fourth contact area CA20 is changed, the contact hole CH200 may further penetrate the sixth insulating layer 60 or the seventh insulating layer 70.

Referring to FIG. 10A, positions of the third contact areas CA10 may be different according to the second connection electrodes CNE2. The third contact areas CA10 may be arranged continuously from the first contact areas CA while maintaining the arrangement of the first contact areas CA1. The third contact area CA10 corresponding to a second-first connection electrode CNE21 may be disposed in the second outer area A22, and the third contact area CA10 corresponding to a second-second connection electrode CNE22 may be disposed in the auxiliary area B1.

Positions of the fourth contact areas CA20 may be the same as each other regardless of the second connection electrodes CNE2. The fourth contact areas CA20 may be arranged in the first direction DR1, and the fourth contact areas CA20 may not overlap the outer area A2. The fourth contact areas CA20 may overlap the auxiliary area B1 disposed outside the outer area A2.

Referring to FIG. 10D, a first contact hole CH1 may be defined through the second synthetic resin layer 110-B2 in the first contact area CA1. In the present embodiment, the first contact hole CH1 may further penetrate the second base insulating layer 110-I2. A portion PP2 (hereinafter, referred to as a “second contact portion”) of the first pad electrode PD1 may be exposed through the first contact hole CH1. The second contact portion PP2 may extend from the first contact portion PPI and may be disposed on the first base insulating layer 110-I1.

Plural insulating layers 10br to 50 may be disposed inside the first contact hole CH1. The insulating layers 10br to 50 may be in contact with an inner side surface B2-SS of the second synthetic resin layer 110-B2, which defines the first contact hole CH1. The barrier layer 10br disposed at the lowermost position among the insulating layers 10br to 50 may be in contact with the inner side surface B2-SS. The inner side surface B2-SS may be formed to have a predetermined inclination angle with respect to an upper surface of the first synthetic resin layer 110-B1 so that the insulating layers 10br to 50 are formed with a uniform thickness in the deposition process. An angle θ defined by the inner side surface B2-SS and the upper surface of the first synthetic resin layer 110-B1 may be within a range of about 45° to about 80°. In FIG. 10D, a dotted line substantially parallel to the upper surface of the first synthetic resin layer 110-B1 is illustrated.

A second contact hole CH2 may be defined through the insulating layers 10br to 50. The second contact hole CH2 may be defined inside the first contact hole CH1 in the plan view. The second contact hole CH2 may expose a portion of the second contact portion PP2. The first connection electrode CNE1 may be in contact with the portion of the second contact portion PP2 via the second contact hole CH2.

An area of the first pad electrode PD1 exposed through the first contact hole CH1 may be greater than an area of the first pad electrode PD1 exposed through the second contact hole CH2. This is because the second contact hole CH2 has a width smaller than a width of the first contact hole CH1. The width of the first contact hole CH1 and the width of the second contact hole CH2 may mean a diameter of a contact hole having a circular shape. The width of the first contact hole CH1 and the width of the second contact hole CH2 may mean a length in the first direction DR1 of a contact hole having a square shape. The width of the first contact hole CH1 may be measured on an upper surface of the second synthetic resin layer 110-B2, and the width of the second contact hole CH2 may be measured on the upper surface of the fifth insulating layer 50.

The width of the first contact hole CH1 in FIG. 10D is preferably about 20% larger than the width of the second contact hole CH2. According to an embodiment of the present disclosure, the width of the first contact hole CH1 is preferably about 40% larger than the width of the second contact hole CH2. This will be described later with reference to FIG. 10F.

The width of the first contact hole CH1 may be within a range of about 20 μm to about 24 μm, and the width of the second contact hole CH2 may be within a range of about 8 μm to about 14 μm. The width of the second contact hole CH2 may mean a width of a second area CH2-2, and a width of a first area CH2-1 of the second contact hole CH2 may be within a range of about 6 μm to about 10 μm.

A lower surface of the first contact portion PPI may be coplanar with a lower surface of the first base insulating layer 110-I1 or the upper surface of the first synthetic resin layer 110-B1. The lower surface of the first contact portion PPI may be electrically connected to the flexible circuit board FCB. Referring to FIG. 10D, the flexible circuit board FCB may include a base film B-B and a signal transmission line B-L disposed on the base film B-B and including a contact area L-CA exposed without being covered by an edge BE of the base film B-B. The flexible circuit board FCB may further include a solder resist layer B-S protecting the signal transmission line B-L. The signal transmission line B-L may be disposed between the base film B-B and the solder resist layer B-S.

A metal pattern MP may be in contact with the lower surface of the first contact portion PPI and the contact area L-CA and may electrically connect the first connection electrode CNE1 to the signal transmission line B-L. The metal pattern MP may be obtained by curing a metal ink. The metal pattern MP may include a solder paste. The metal pattern MP may be formed of the meal ink containing silver or copper.

A synthetic resin pattern RP may cover the metal pattern MP to prevent the metal pattern MP from being corroded. The metal pattern MP and the synthetic resin pattern RP may be disposed to correspond to the first opening B1-OP. The first opening B1-OP may not overlap the first contact hole CH1, however, it should not be limited thereto or thereby. According to an embodiment, the first opening B1-OP may overlap a portion of the first contact hole CH1. The metal pattern MP may be disposed in every first pad electrode PD1, and the synthetic resin pattern RP may be commonly disposed in the first pad electrodes PD1 like the first opening B1-OP described above.

As shown in FIG. 10D, the second contact hole CH2 may include the first area CH2-1 penetrating a first group of insulating layers 10br and 10bf among the insulating layers 10br to 50 and the second area CH2-2 penetrating a second group of insulating layers 10 to 50 disposed on the first group of the insulating layers 10br and 10bf. In the present embodiment, the first group of the insulating layers 10br and 10bf may include inorganic layers, and the second group of the insulating layers 10 to 50 may include inorganic layers.

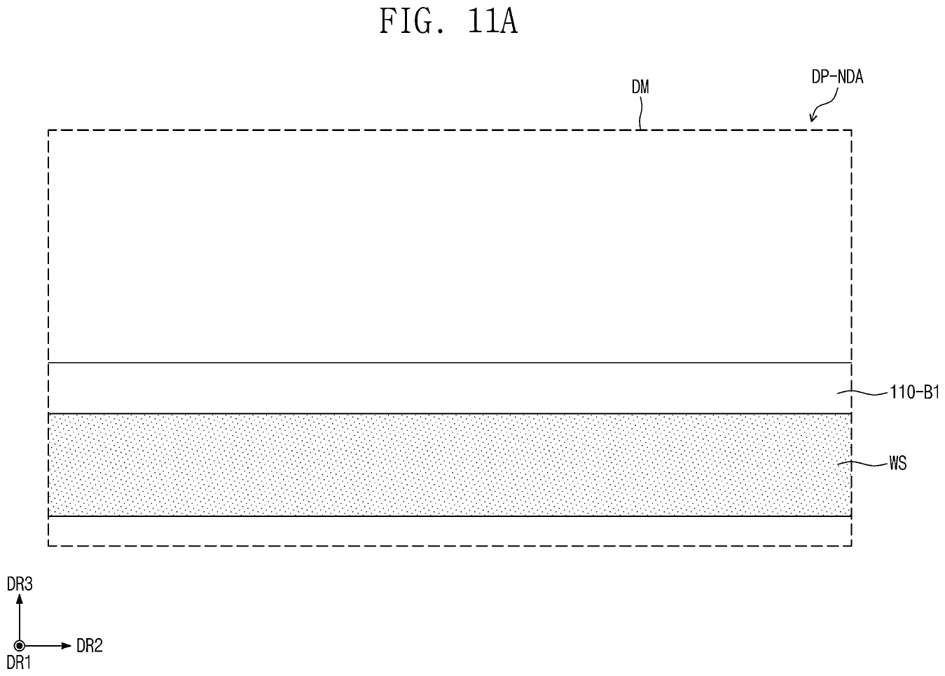

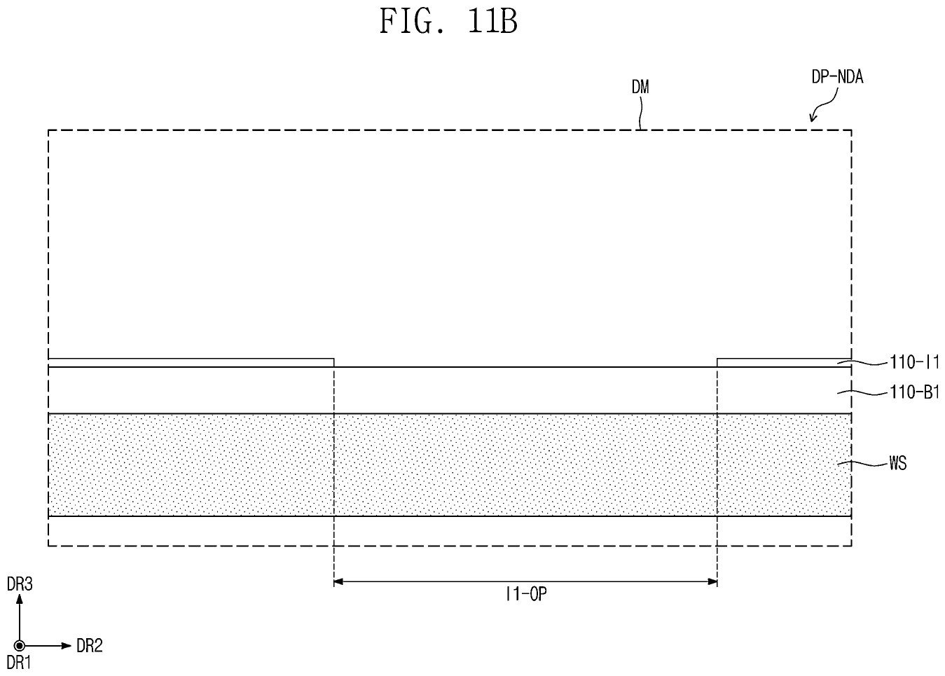

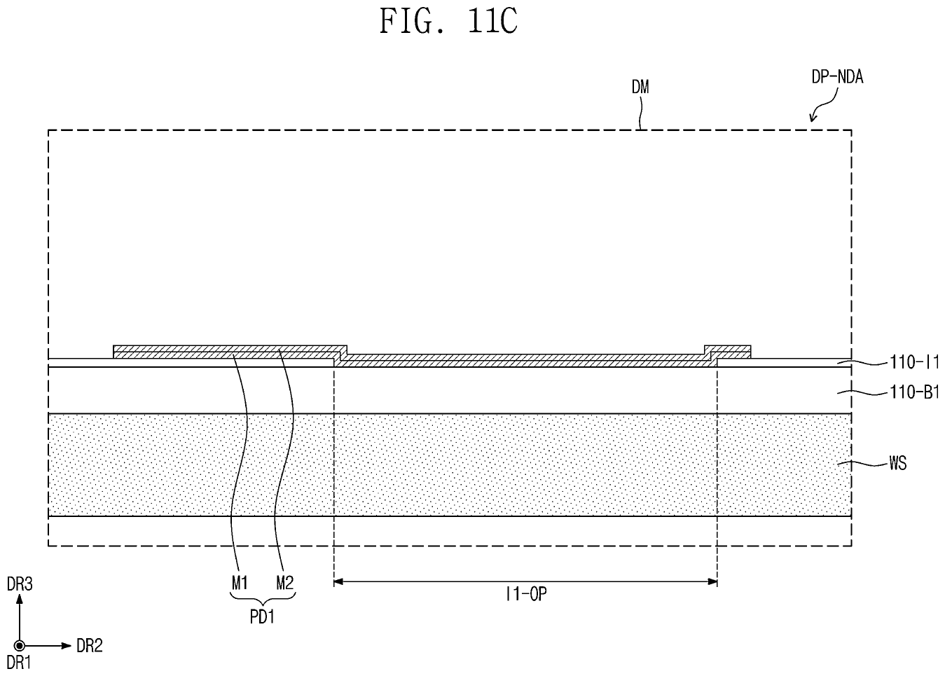

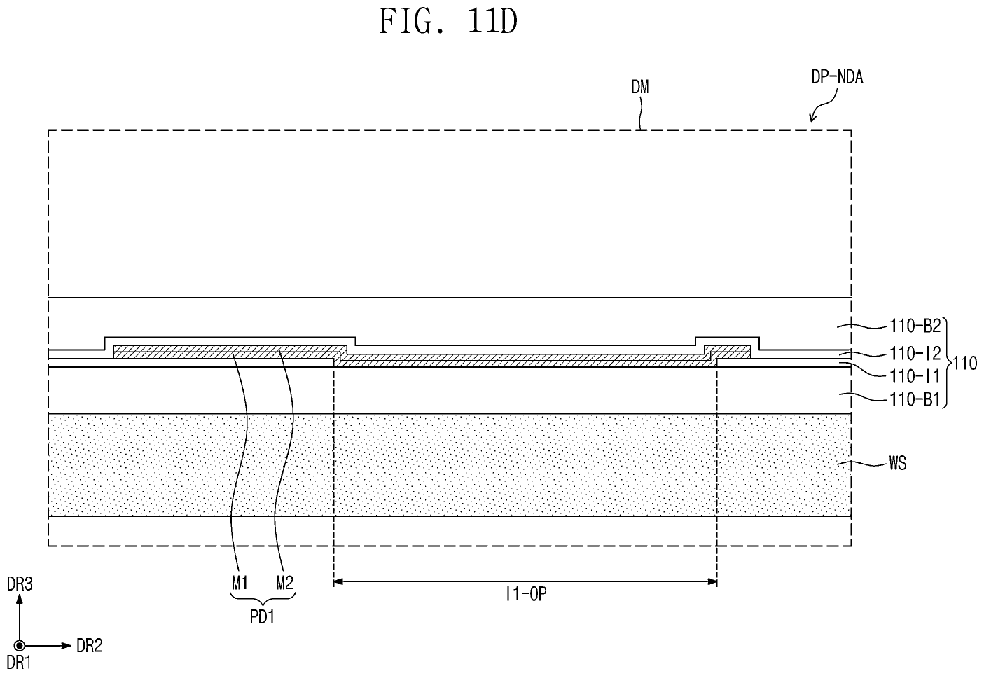

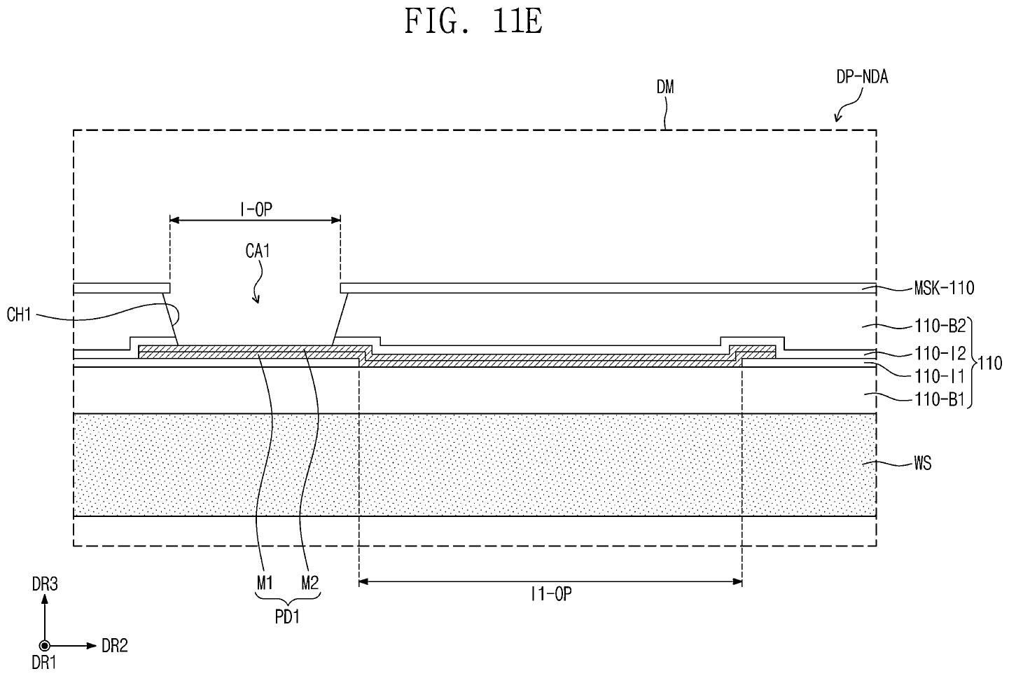

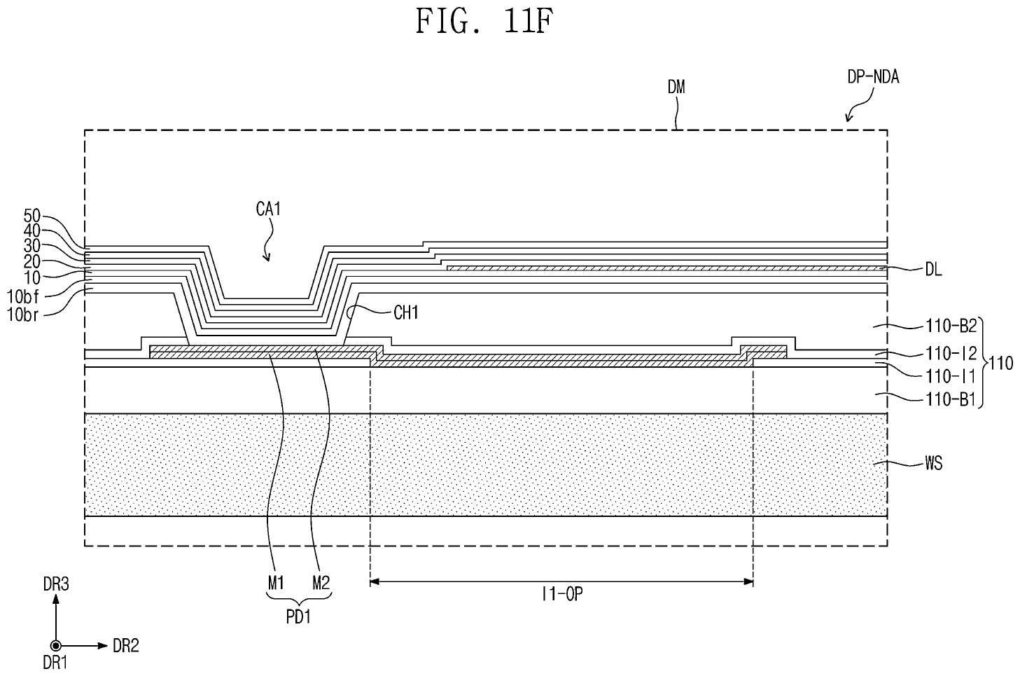

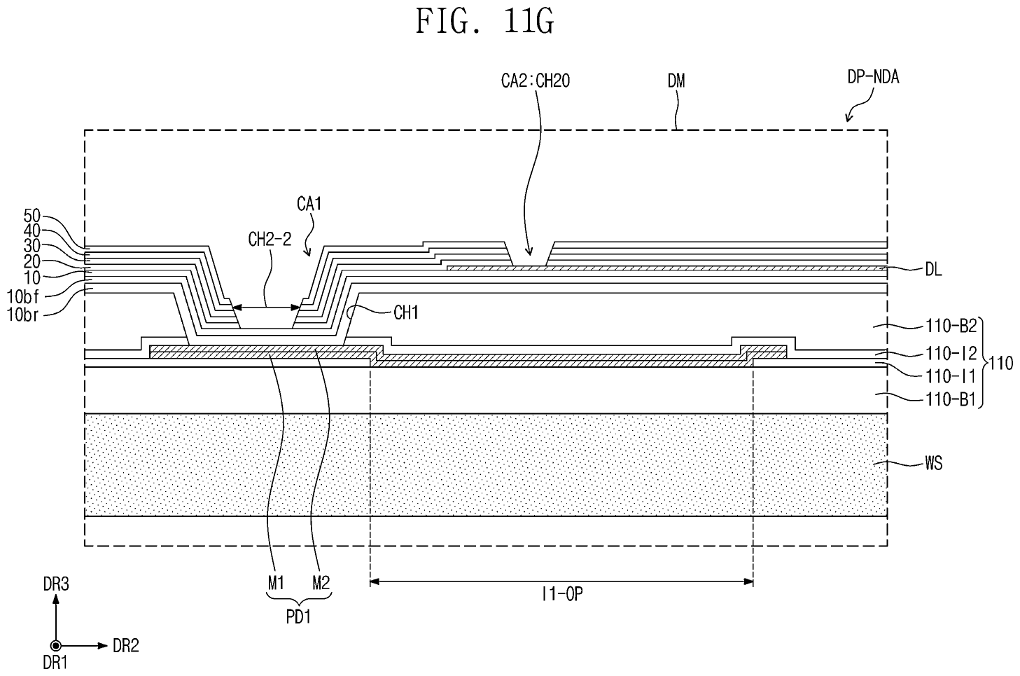

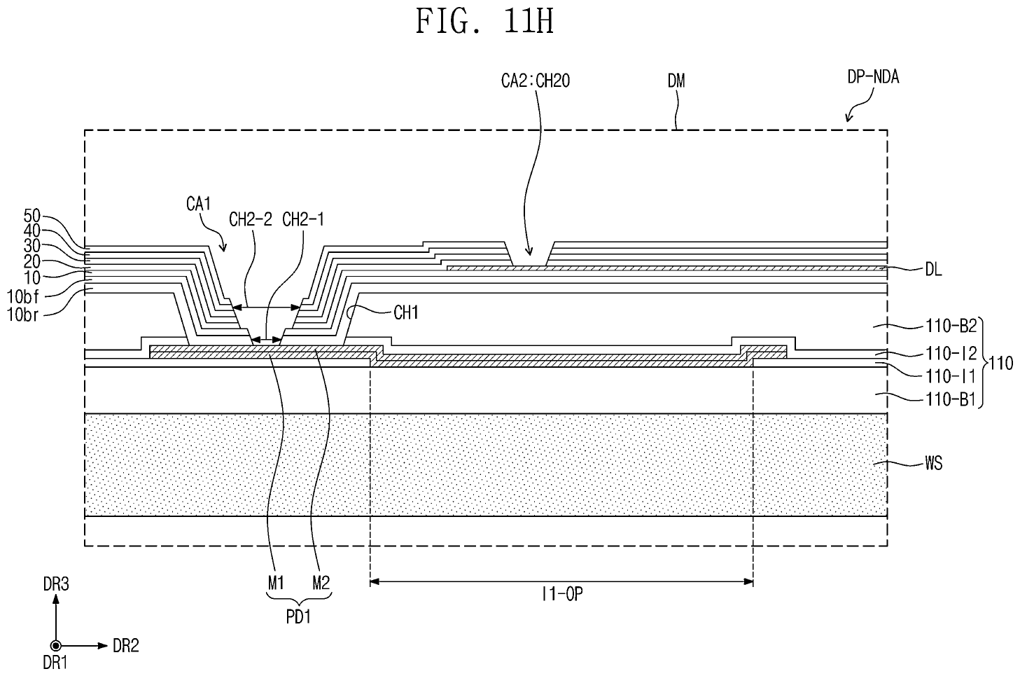

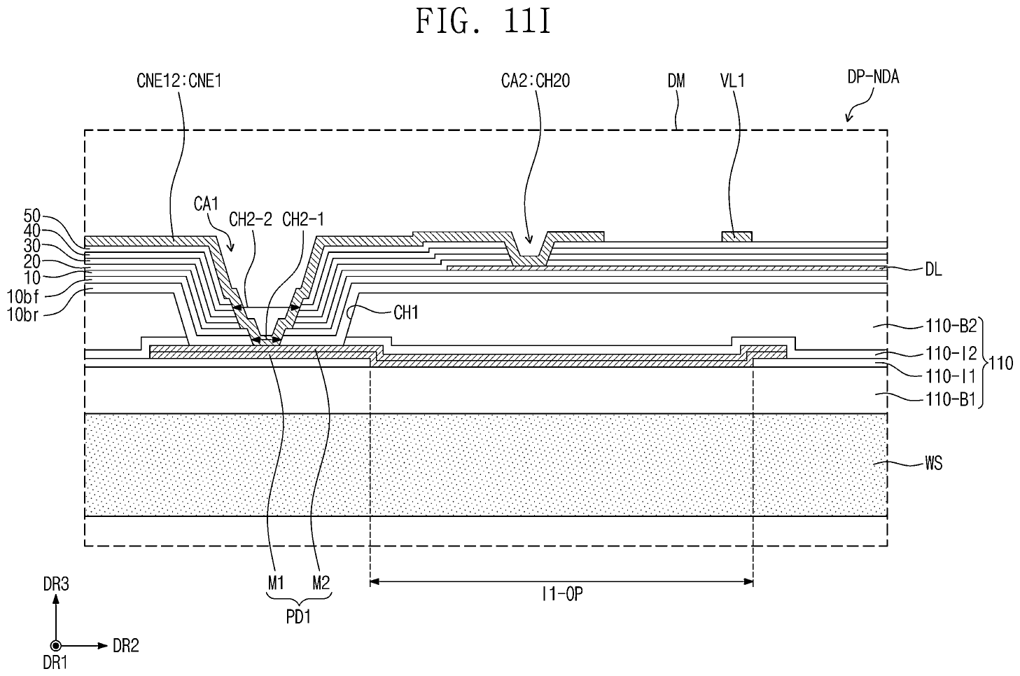

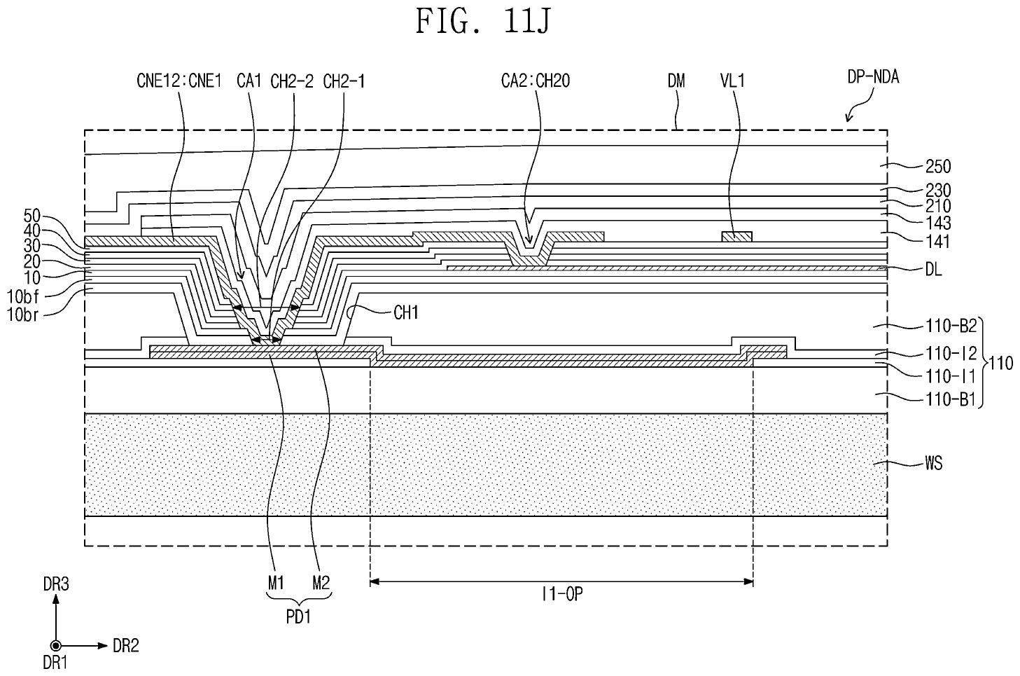

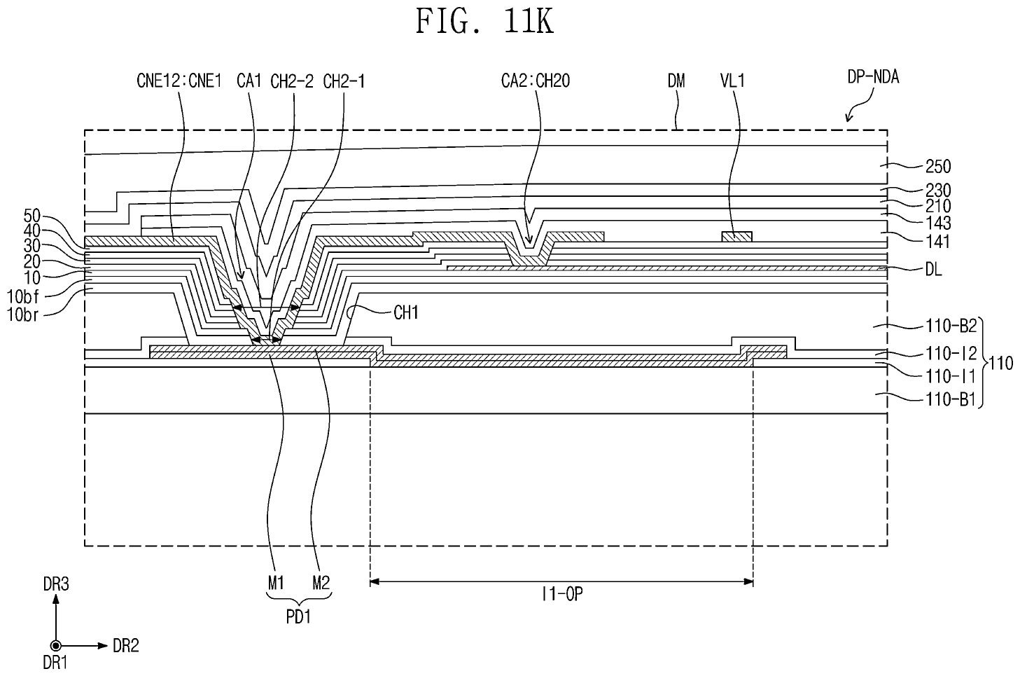

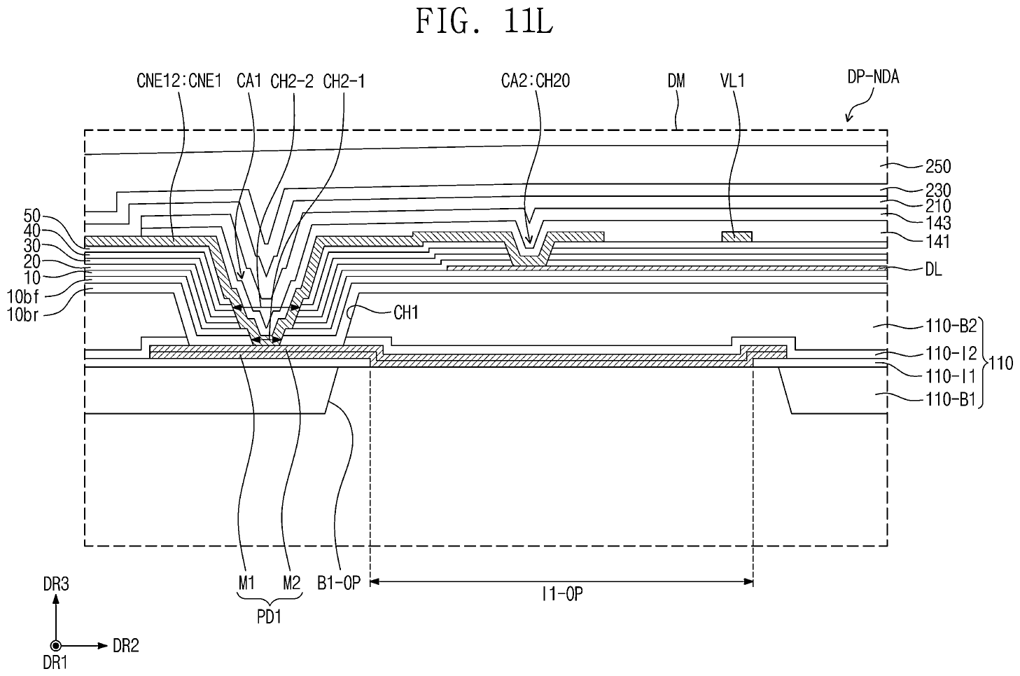

The second area CH2-2 may have a width greater than a width of the first area CH2-1. The second area CH2-2 and the first area CH2-1 are discontinuous, and the second area CH2-2 may expose a portion of an upper surface of the buffer layer 10bf. The first area CH2-1 and the second area CH2-2 may be formed through different photolithography processes from each other. This will be described in detail with reference to FIGS. 11A to 11L.

Referring to FIG. 10E, the second contact hole CH2 may be continuous without being divided into the first area CH2-1 (refer to FIG. 10D) and the second area CH2-2 (refer to FIG. 10D). The second contact hole CH2 of FIG. 10E may be formed through a single photolithography process.

First, second, and third images (1), (2), and (3) of FIG. 10F show the first-first connection electrode CNE11 and the first-second connection electrode CNE12 of FIG. 10A. Circular contact holes are shown in the first contact area CA1 of the first-first connection electrode CNE11, and quadrangular contact holes are shown in the first contact area CA1 of the first-second connection electrode CNE12. Referring to the first contact area CA1 of the first-first connection electrode CNE11 of the first to third images (1) to (3), three concentric circles may be observed. The outermost circle corresponds to the first contact hole CH1. The innermost circle corresponds to the first area CH2-1 of the second contact hole CH2. The middle circle corresponds to the second area CH2-2 of the second contact hole CH2.

In the first image (1), the first contact hole CH1 may have about 5% larger width than the second contact hole CH2. In the second image (2), the first contact hole CH1 may have about 20% larger width than the second contact hole CH2. In the third image (3), the first contact hole CH1 may have about 40% larger width than the second contact hole CH2. In the first image (1), dark spots are found around the first contact hole CH1, and these dark spots are caused by cracks in the insulating layers 10br to 50 (refer to FIG. 10D) around the first contact hole CH1. In the second image (2), most of the dark spots are removed when compared with the first image (1), and no dark spots are found in the third image (3). As shown in the first, second, and third images (1), (2), and (3) of FIG. 10F, when the width of the first contact hole CH1 is about 20% larger than the width of the second contact hole CH2, the cracks may be prevented from occurring in the insulating layers 10br to 50.

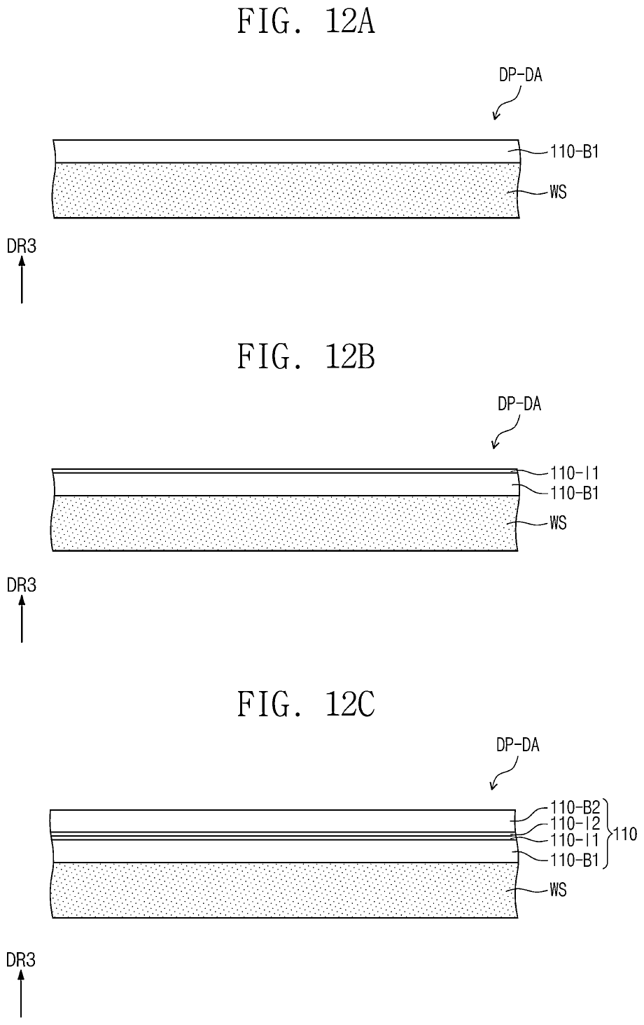

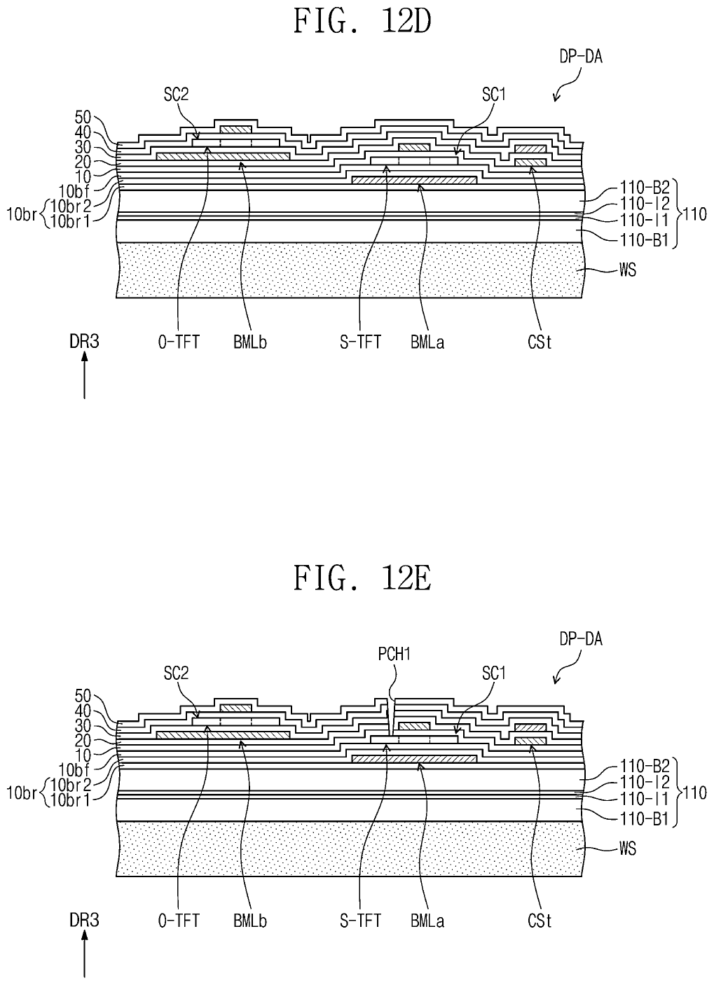

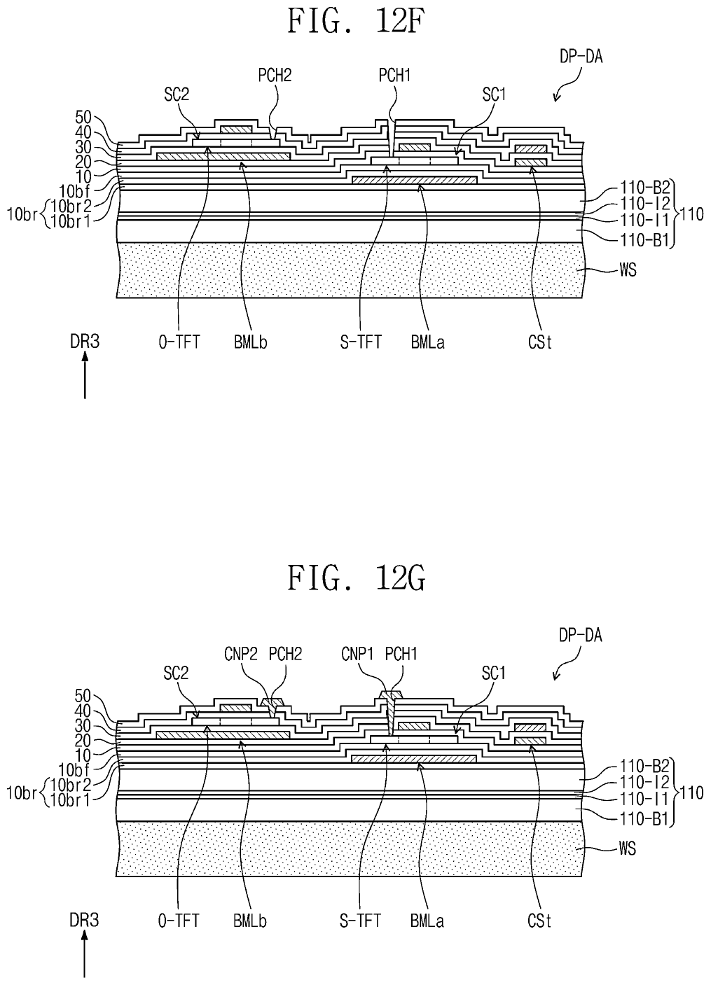

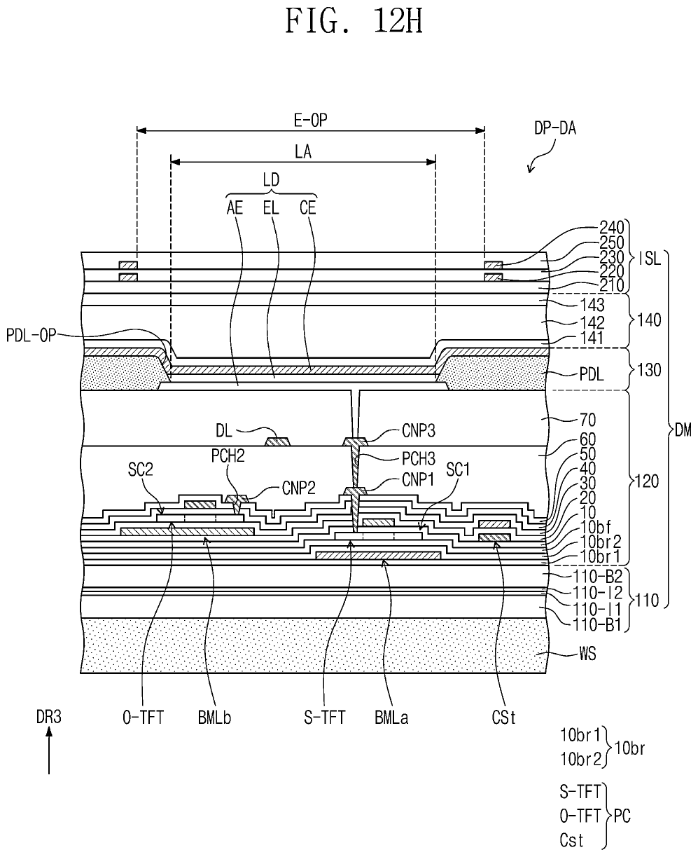

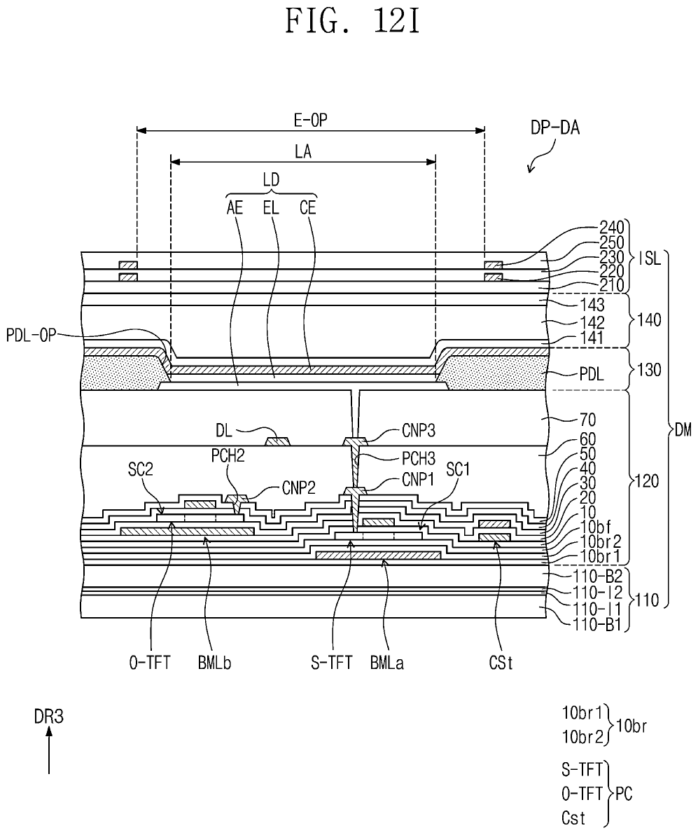

FIGS. 11A to 11L are cross-sectional views of a method of manufacturing the display module DM according to an embodiment of the present disclosure. FIGS. 12A to 12I are cross-sectional views of a method of manufacturing the display module DM according to an embodiment of the present disclosure.

FIGS. 11A to 11L correspond to FIG. 10D and show a manufacturing method of the non-display area DP-NDA of the display module DM, and FIGS. 12A to 12I correspond to FIG. 6 and show a manufacturing method of the display area DP-DA of the display module DM. The manufacturing method of the display module DM will be described with reference to FIGS. 11A to 11L and 12A to 12I. The manufacturing method of the display module DM will be described with reference to one drawing of FIGS. 11A to 11L and one or more drawings of FIGS. 12A to 12I, which corresponds to the one drawing of FIGS. 11A to 11L, to illustrate the same process performed in the non-display area DP-NDA and the display area DP-DA. However, the scales of the components shown in FIGS. 11A to 11L and the scales of the components shown in FIGS. 12A to 12I, which are identical to those shown in FIGS. 11A to 11L, are illustrated differently.

Referring to FIGS. 11A and 12A, the first synthetic resin layer 110-B1 may be formed on the work substrate WS. The synthetic resin may be coated on an upper surface of the work substrate WS by a coating or inkjet method. The synthetic resin may be commonly coated in the non-display area DP-NDA and the display area DP-DA and may be cured.

Referring to FIGS. 11B and 12B, the first base insulating layer 110-I1 may be formed on the work substrate WS. The inorganic material may be deposited on the upper surface of the first synthetic resin layer 110-B1 by a chemical vapor deposition (“CVD”) method. The first base insulating layer 110-I1 may be commonly formed in the non-display area DP-NDA and the display area DP-DA.

As shown in FIG. 11B, the opening 11-OP may be formed to overlap the non-display area DP-NDA. The opening I1-OP may correspond to the second opening 11-OP of FIGS. 10B and 10D. The second opening 11-OP may be formed only in the non-display area DP-NDA through a photolithography process.

Referring to FIG. 11C, the first pad electrode PD1 may be formed to overlap the non-display area DP-NDA. A metal layer may be formed on the first synthetic resin layer 110-B1 and the first base insulating layer 110-I1 exposed through the opening I1-OP, and then, the first pad electrode PD1 that overlaps the opening 11-OP and a portion of the first synthetic resin layer 110-B1 may be formed through a photolithography process.

The metal layer of the first pad electrode PD1 may have a two-layer structure. A first metal layer M1 may be formed through a physical vapor deposition (“PVD”) method, and then, a second metal layer M2 may be formed through another physical vapor deposition (PVD) method. The first metal layer M1 and the second metal layer M2 may be substantially simultaneously etched. The first metal layer M1 may include a metal material with a high corrosion resistance compared with the second metal layer M2. The first metal layer M1 may be exposed to the outside after the display module is completed as shown in FIG. 10D, and thus, a metal material that is not easily corroded by external moisture may be used as the first metal layer M1. The first metal layer M1 may include titanium.

The second metal layer M2 may include a metal material with high conductivity, and at least the second metal layer M2 may have the conductivity higher than that of the first metal layer M1. A metal material that reduces the contact resistance between the first pad electrode PD1 and the flexible circuit board FCB (refer to FIG. 10D) may be used as the second metal layer M2. In addition, the second metal layer M2 may include a metal material with high heat resistance. This is to prevent the first pad electrode PD1 from being damaged since a high-temperature process is performed after forming the first pad electrode PD1. The second metal layer M2 may include molybdenum or copper. The alignment mark AM shown in FIG. 8 may be formed through the same

process as the first pad electrode PD1. When the alignment mark AM is damaged in the high-temperature process, it is not possible to accurately identify the alignment mark AM, and as a result, a misalignment may occur between the work substrate and the mask in the deposition process. Accordingly, the alignment mark AM may have the two-layer structure like the first pad electrode PD1 described above.

Referring to FIGS. 11D and 12C, the second base insulating layer 110-I2 and the second synthetic resin layer 110-B2 may be sequentially formed on the first base insulating layer 110-I1. The second base insulating layer 110-I2 may include an inorganic material, and the second base insulating layer 110-I2 may be formed by a chemical vapor deposition (CVD) method. The second synthetic resin layer 110-B2 may include a synthetic resin material and may be formed by a coating method.

Referring to FIG. 11E, the contact hole CH1 may be formed through the second base insulating layer 110-I2 and the second synthetic resin layer 110-B2 and may overlap the non-display area DP-NDA. The contact hole CH1 of FIG. 11E may correspond to the first contact hole CH1 of FIG. 10D, and an area in which the first contact hole CH1 is formed may correspond to the first contact area CA1.

The first contact hole CH1 may be formed using an IZO mask MSK-110. After an IZO layer is formed on the second synthetic resin layer 110-B2, an opening I-OP may be formed through the IZO layer through a photolithography process. The first contact hole CH1 may be formed through the second base insulating layer 110-I2 and the second synthetic resin layer 110-B2 through a process of etching the insulating layer. A mask containing a transparent conductive oxide of a material other than the IZO may also be used.

Referring to FIGS. 11F and 12D, the insulating layers 10br to 50 may be formed on the second synthetic resin layer 110-B2. The insulating layers 10br to 50 may be commonly formed in the non-display area DP-NDA and the display area DP-DA. The inorganic material may be deposited on the upper surface of the second synthetic resin layer 110-B2 by a chemical vapor deposition (CVD) method. The lower barrier layer 10br1 and the upper barrier layer 10br2 of FIG. 12D is shown as a single layer of the barrier layer 10br in FIG. 11F.

During the processes of forming the insulating layers 10br to 50, the conductive pattern or the semiconductor pattern may be formed. A photolithography process may be performed in every process of forming the conductive pattern and the semiconductor pattern. Multiple photolithography processes may be performed to form the silicon transistor S-TFT, the oxide transistor O-TFT, and the capacitor Cst of FIG. 12D. The portion of the data line DL shown in FIG. 11F may be formed through the same process as the gate of the silicon transistor S-TFT.

Referring to FIGS. 11G and 12E, the contact holes CH2-2 and PCH1 may be formed through corresponding insulating layers among the insulating layers 10br to 50 through a photolithography process. The contact holes CH2-2 and PCH1 may commonly penetrate the first to fifth insulating layers 10 to 50. The contact hole CH2-2 formed in the non-display area DP-NDA may correspond to the second area CH2-2 of the second contact hole CH2 shown in FIG. 10D, and the contact hole PCH1 formed in the display area DP-DA may correspond to the first pixel contact hole PCH1 shown in FIG. 6.

In this process, the third contact hole CH20 may be further formed in the non-display area DP-NDA. The third contact hole CH20 may penetrate from the second insulating layer 20 to the fifth insulating layer 50 and may expose the data line DL. According to an embodiment of the present disclosure, the third contact hole CH20 may be formed in a process of forming the first area CH2-1 of the second contact hole CH2 shown in FIG. 11H.

Referring to FIGS. 11H and 12F, the contact holes CH2-1 and PCH2 may be formed through corresponding insulating layers among the insulating layers 10br to 50 through a photolithography process. The contact hole CH2-1 formed in the non-display area DP-NDA may correspond to the first area CH2-1 of the second contact hole CH2 shown in FIG. 10D, and the contact hole PCH2 formed in the display area DP-DA may correspond to the second pixel contact hole PCH2 shown in FIG. 6.

The contact hole CH2-1 formed in the non-display area DP-NDA may penetrate the barrier layer 10br and the buffer layer 10bf, and the contact hole PCH2 formed in the display area DP-DA may penetrate the fourth insulating layer 40 and the fifth insulating layer 50. The contact hole CH2-1 formed in the non-display area DP-NDA and the contact hole PCH2 formed in the display area DP-DA do not penetrate the same insulating layers, however, the thickness of the inorganic layers through which the contact hole CH2-1 penetrate may be the same as the thickness of the inorganic layers through which the contact hole PCH2 penetrate.

The reason why the second pixel contact hole PCH2 is formed through the process different from that of the first pixel contact hole PCH1 is that the contact holes PCH1 and PCH2 have different depths. In a case where the second pixel contact hole PCH2 is formed in the process of forming the first pixel contact hole PCH1, a metal oxide semiconductor pattern of the oxide transistor O-TFT may be damaged. In a case where the first pixel contact hole PCH1 is formed in the process of forming the second pixel contact hole PCH2, the contact hole may not be formed through the silicon semiconductor pattern of the silicon transistor S-TFT.

Referring to FIGS. 11I and 12G, the conductive patterns CNE1, CNP1, and CNP2 may be formed through a photolithography process. A conductive layer may be formed on the fifth insulating layer 50 to overlap the display area DP-DA and the non-display area DP-NDA. The conductive layer having the multi-layer structure may be formed through multiple deposition processes. Then, the conductive layer may be etched, and the first connection electrode CNE1, the first connection pattern CNP1, and the second connection pattern CNP2 may be formed.

The first connection electrode CNE1 may be connected to the first pad electrode PD1 via the second contact hole CH2, and the first connection pattern CNP1 may be connected to the drain area or the source area of the silicon transistor S-TFT via the first pixel contact hole PCH1. The second connection pattern CNP2 may be connected to the drain area or the source area of the oxide transistor O-TFT via the second pixel contact hole PCH2.

Referring to FIGS. 11J and 12H, subsequent processes may be performed to complete the driving element layer 120, and the light emitting element layer 130, the encapsulation layer 140, and the input sensor ISL may be formed. Multiple deposition processes and multiple photolithography processes may be additionally performed.

Referring to FIGS. 11K and 12I, the display module DM may be separated from the work substrate WS. As described with reference to FIGS. 9B and 9C, the display module DM may be separated from the work substrate WS in the state where the work substrate WS is divided for each unit cell UC.

Referring to FIG. 11L, the opening B1-OP may be formed through the first synthetic resin layer 110-B1. The opening B1-OP may be formed by irradiating a laser beam to the lower surface of the first synthetic resin layer 110-B1. The opening B1-OP may correspond to the first opening B1-OP FIG. 10D. Although not shown in figures, the rear surface bonding process of the flexible circuit board FCB may be additionally performed.

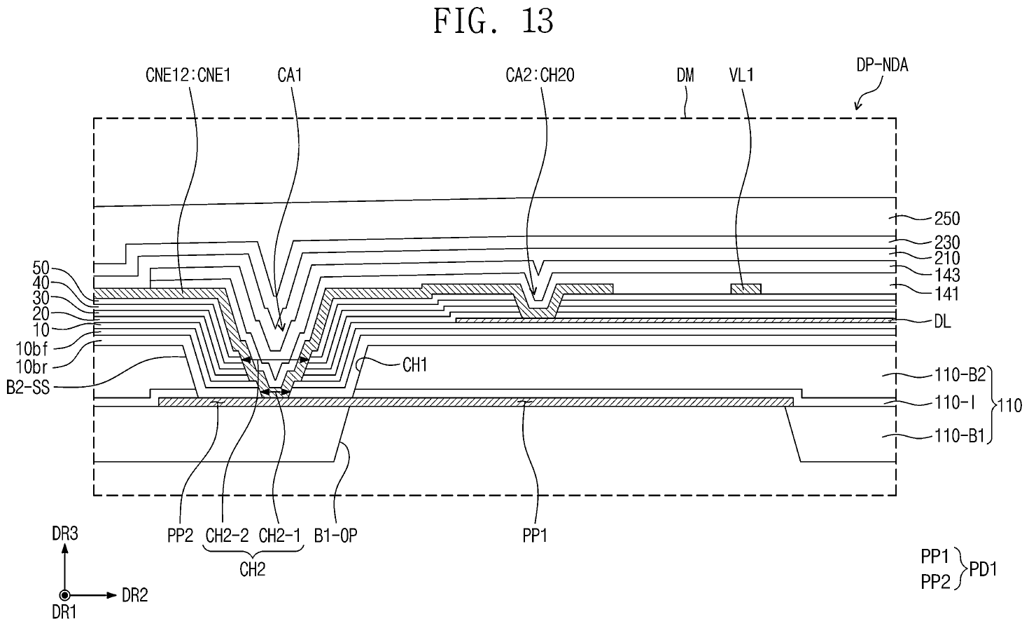

FIGS. 13 to 17 are enlarged cross-sectional views of a portion of a display module DM according to embodiments of the present disclosure. In FIGS. 13 to 17, detailed descriptions of the same elements as those described with reference to FIGS. 8 to 12I will not be repeated.

FIGS. 13 to 17 substantially correspond to FIG. 10D. However, the flexible circuit board FCB of FIG. 10D is not illustrated in FIGS. 13 to 17.

Referring to FIG. 13, one base insulating layer 110-I may be disposed between a first synthetic resin layer 110-B1 and a second synthetic resin layer 110-B2. When compared with FIG. 10D, the first base insulating layer 110-I1 of FIG. 10D is omitted, and the second base insulating layer 110-I2 of FIG. 10D may correspond to the base insulating layer 110-I of FIG. 13. A lower surface of a first pad electrode PD1 may be coplanar with a lower surface of the base insulating layer 110-I disposed in an area that does not overlap the first pad electrode PD1.

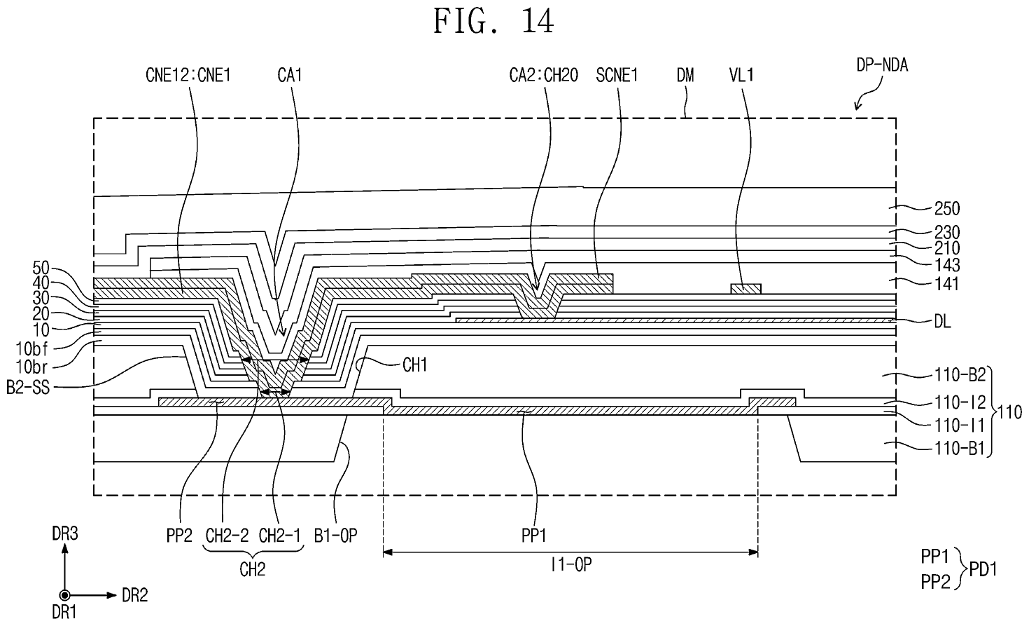

Referring to FIG. 14, a sub-connection electrode SCNE1 may be further disposed in a non-display area DP-NDA. The sub-connection electrode SCNE1 may be disposed on a first connection electrode CNE1 and may reduce a resistance of the connection electrode.

The sub-connection electrode SCNE1 may be formed through the same process as the third connection pattern CNP3 of FIG. 6. The sixth insulating layer 60 shown in FIG. 6 may not be disposed in the non-display area DP-NDA, and an insulating pattern spaced apart from the sixth insulating layer 60 may not be disposed on the first connection electrode CNE1 in the process of forming the sixth insulating layer 60. The conductive layer formed when the third connection pattern CNP3 is formed may be disposed on the first connection electrode CNE1. The sub-connection electrode SCNE1 may be further formed by patterning the conductive layer disposed thereabove in the same shape as the first connection electrode CNE1.

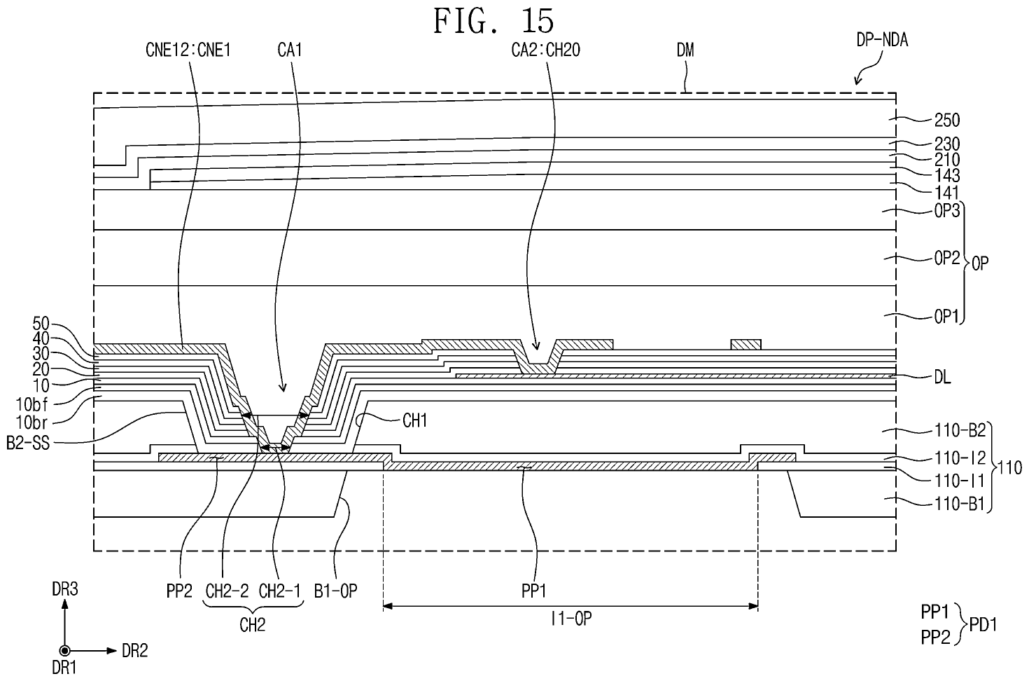

Referring to FIG. 15, an organic pattern OP may be further disposed on the first connection electrode CNE1. The organic pattern OP may include a first layer OP1 that is the same layer as the sixth insulating layer 60 of FIG. 6, a second layer OP2 that is the same layer as the seventh insulating layer 70 of FIG. 6, and a third layer OP3 that is the same layer as the pixel definition layer PDL of FIG. 6. The organic pattern OP may be disposed under a first encapsulation inorganic layer 141. The organic pattern OP may be the second insulating pattern DMP2 of FIG. 9A, may be a portion further extending to the edge 110-EG (refer to FIG. 9A) of the base layer 110 (refer to FIG. 9A) of the second insulating pattern DMP2, or may be a separate insulating pattern spaced apart from the second insulating pattern DMP2. The expression “The organic pattern OP is the second insulating pattern DMP2 of FIG. 9A.”means that a first contact area CA1 is disposed in the second outer area A22 of FIG. 9A.

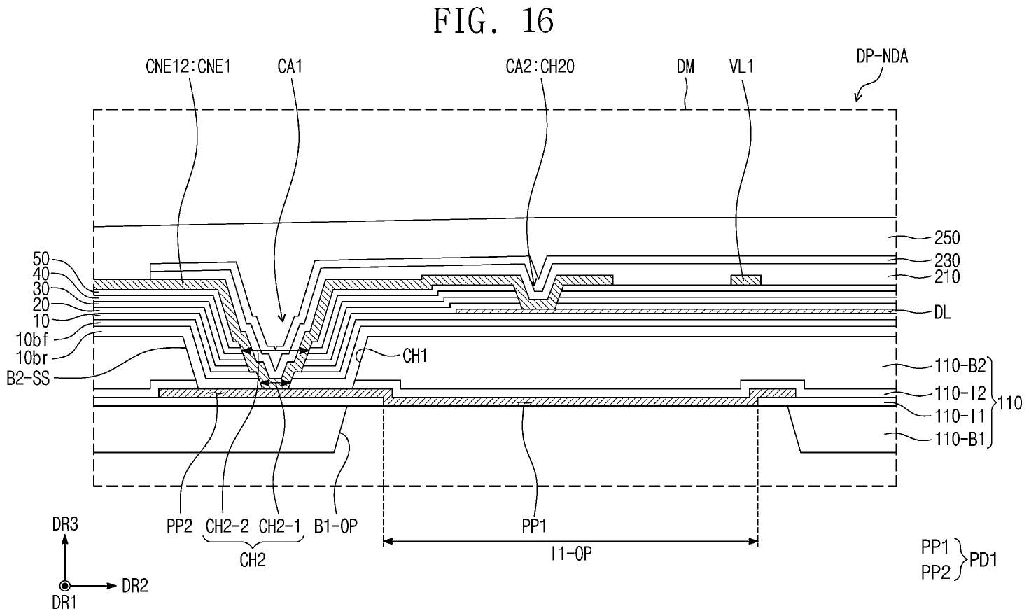

Referring to FIG. 16, a first insulating layer 210 of an input sensor ISL may be disposed on a first connection electrode CNE1. A first encapsulation inorganic layer 141 and a second encapsulation inorganic layer 143 may not be disposed on the first connection electrode CNE1. FIG. 16 shows a structure in which a first contact area CA1 is disposed in the auxiliary area B1 of FIG. 9A.

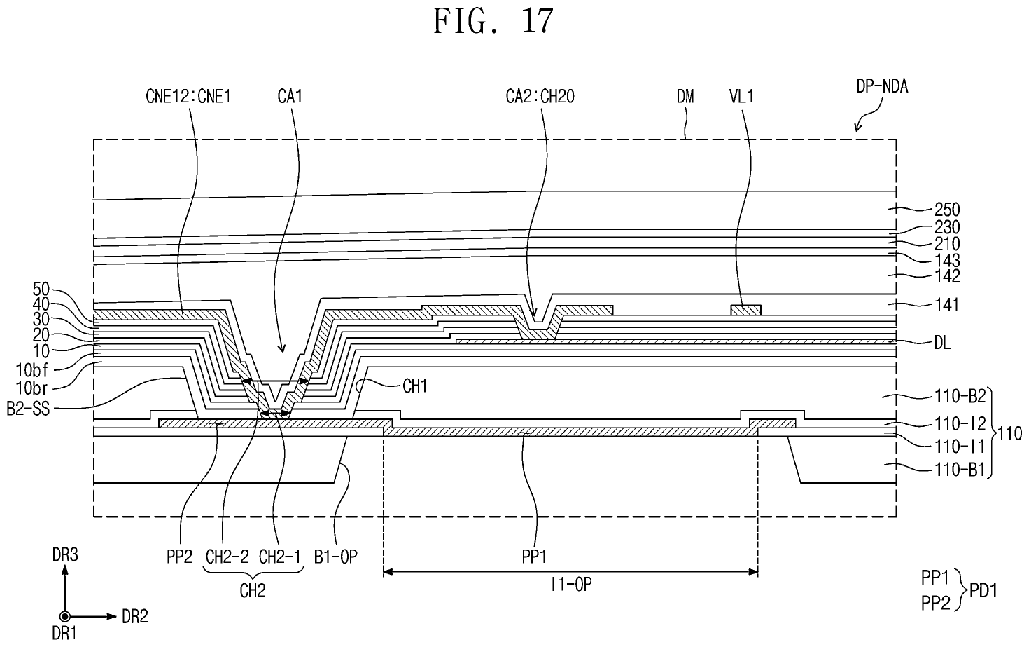

Referring to FIG. 17, an encapsulation organic layer 142 may be further disposed on a first connection electrode CNE1. The encapsulation organic layer 142 may be disposed between a first encapsulation inorganic layer 141 and a second encapsulation inorganic layer 143. FIG. 17 shows a structure in which a first contact area CA1 is disposed in the inner area A1 of FIG. 9A.

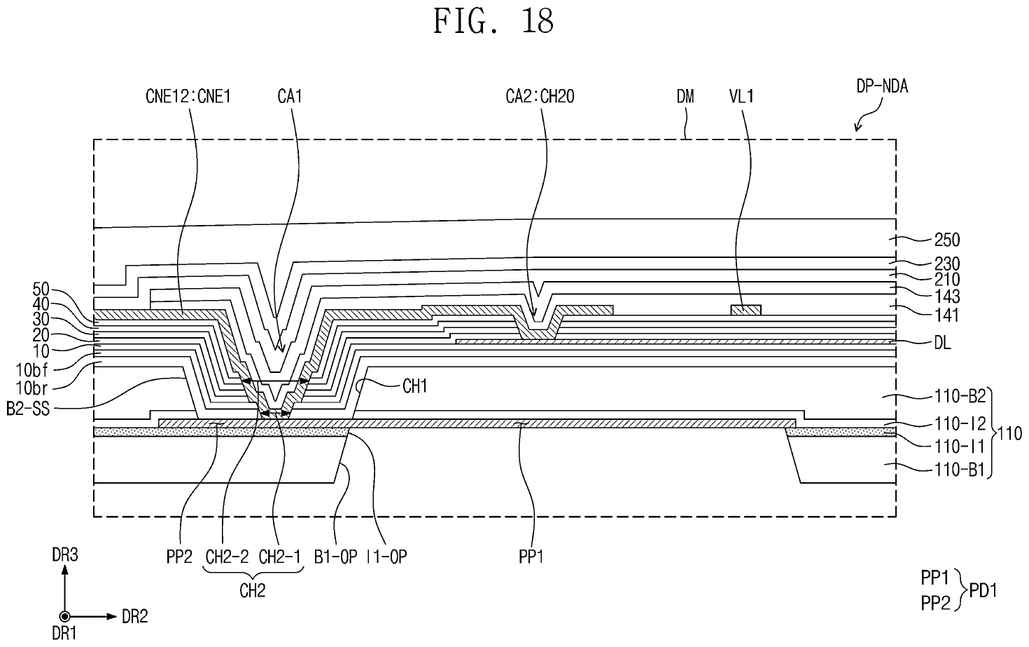

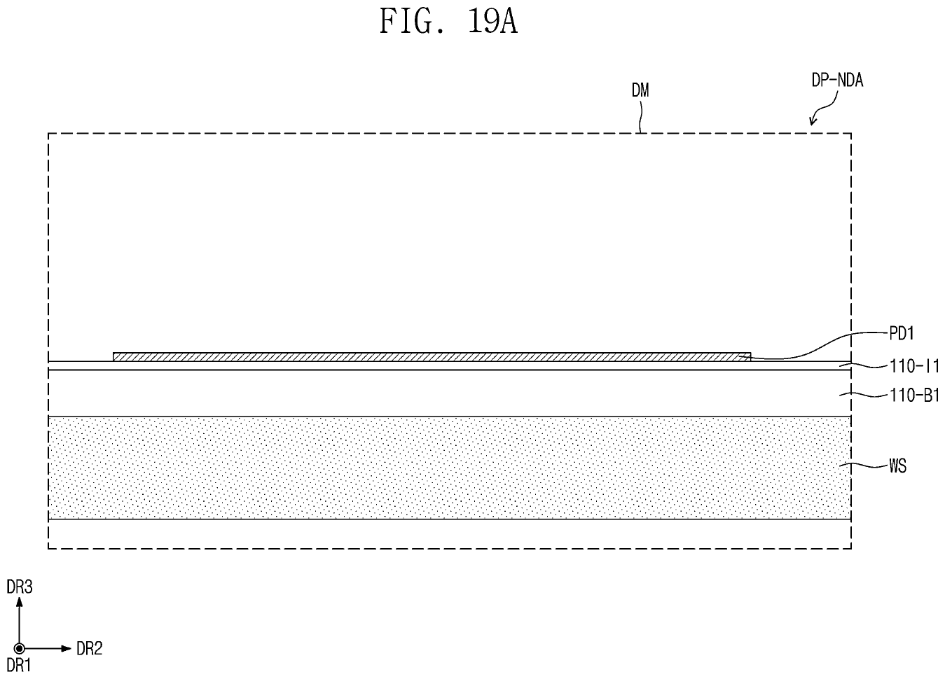

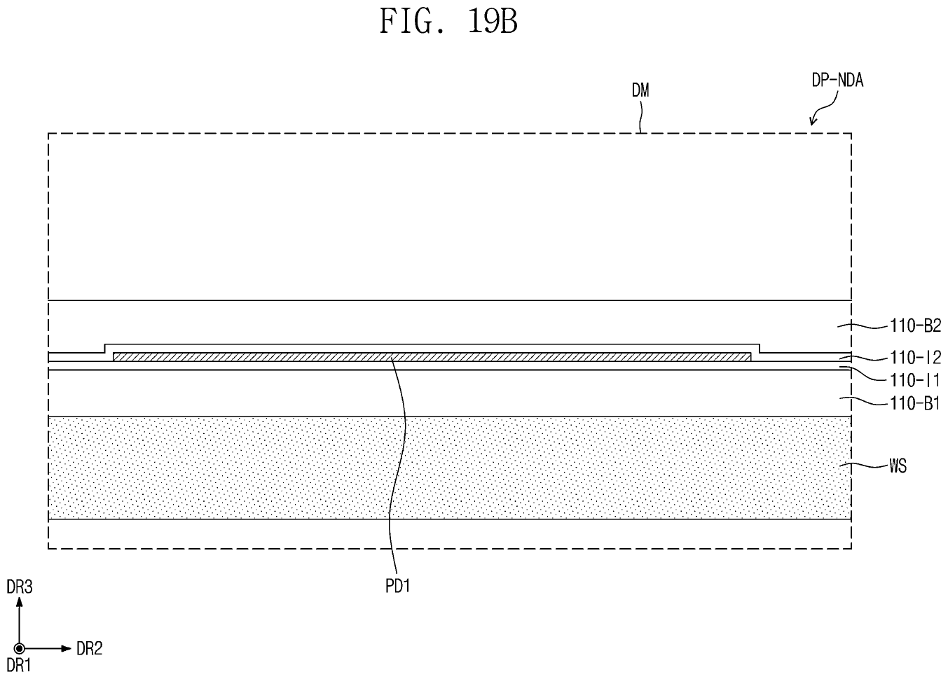

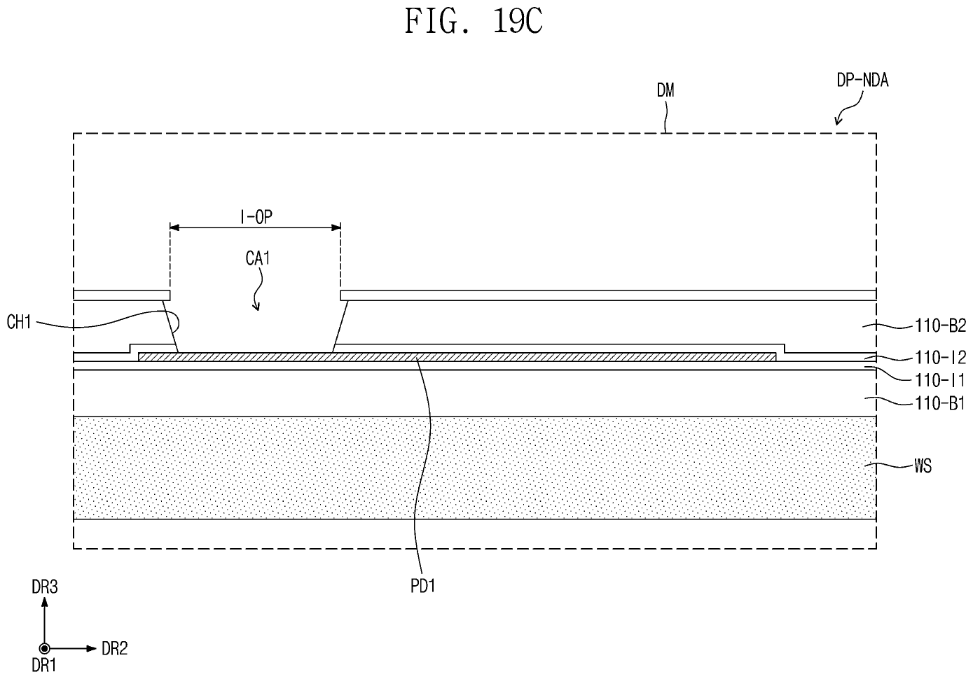

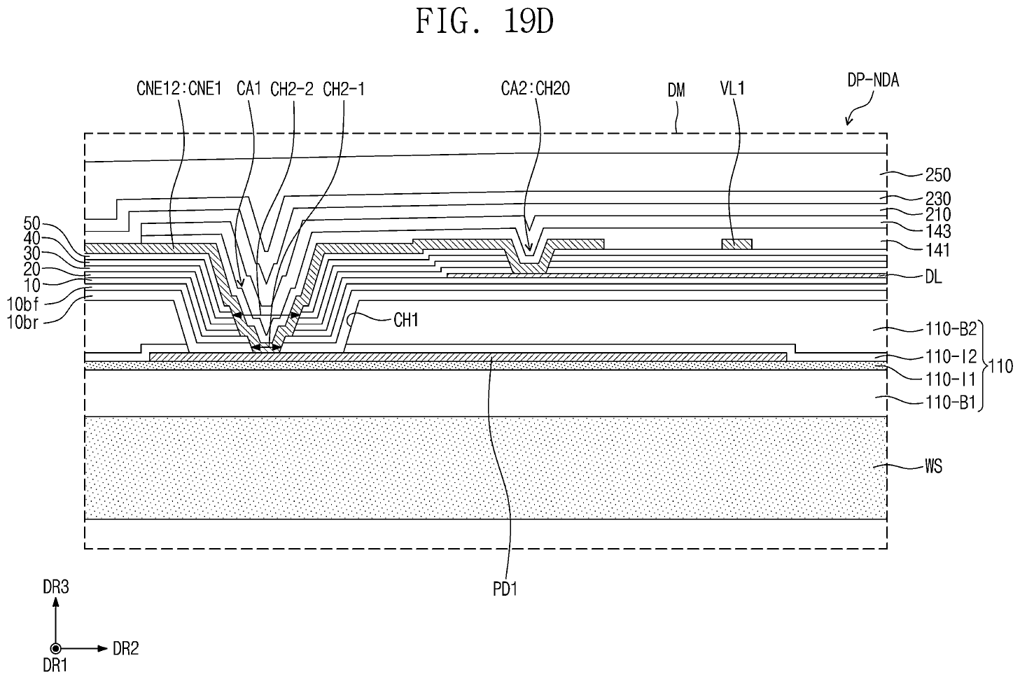

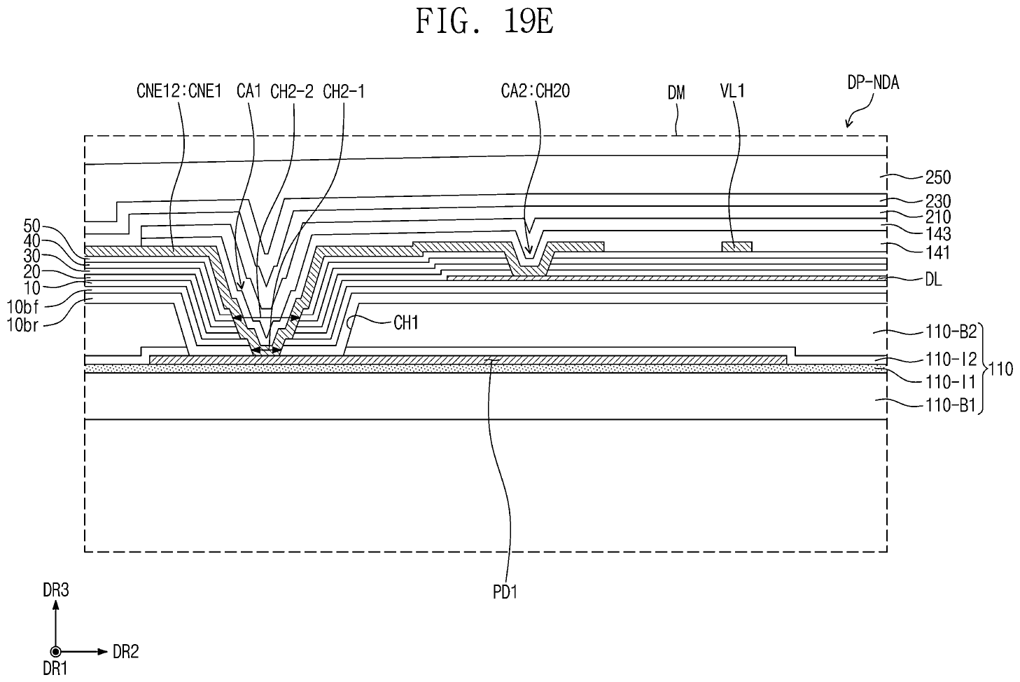

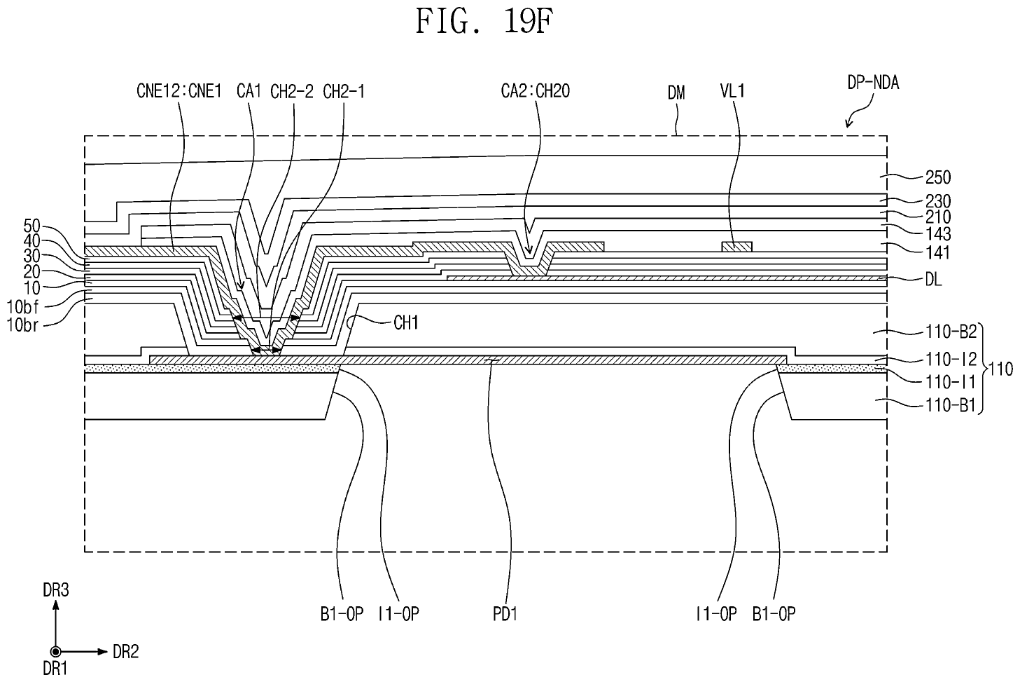

FIG. 18 is a cross-sectional view of a display module DM according to an embodiment of the present disclosure. FIGS. 19A to 19F are cross-sectional views of a method of manufacturing the display module DM according to an embodiment of the present disclosure.

FIG. 18 corresponds to FIG. 10D. FIGS. 19A to 19F correspond to FIGS. 11A to 11L. In FIGS. 18 and 19A to 19F, detailed descriptions of the same elements as those described with reference to FIGS. 8 to 12I will not be repeated.

Referring to FIG. 18, a first base insulating layer 110-I1 may be disposed on an upper surface of a first synthetic resin layer 110-B1. A first pad electrode PD1 may be disposed on the first base insulating layer 110-I1.

The first base insulating layer 110-I1 may have a greater coupling force to the first pad electrode PD1 than the first synthetic resin layer 110-B1 has. The first base insulating layer 110-I1 may include a material with a greater coupling force to the first pad electrode PD1 than the first synthetic resin layer 110-B1 has.

When the first synthetic resin layer 110-B1 includes polyimide and the first pad electrode PD1 is directly formed on the first synthetic resin layer 110-B1, the first pad electrode PD1 may be corroded or oxidized. As described with reference to FIG. 11C, when the first pad electrode PD1 includes the first metal layer M1 of titanium, a titanium oxide may be formed between an interface of the first synthetic resin layer 110-B1 and the first metal layer M1. The titanium oxide may reduce the coupling force between the first synthetic resin layer 110-B1 and the first metal layer M1.

When the first base insulating layer 110-I1 includes an inorganic material such as silicon oxide, silicon nitride, or silicon oxynitride, the oxidation of the first metal layer M1 may be prevented. In addition, the first base insulating layer 110-I1 may include an organic material or synthetic resin material with a relatively low oxygen content or may be a plasma-treated organic layer or a plasma-treated synthetic resin layer.

A second opening 11-OP formed through the first base insulating layer 110-I1 may have a shape that is continuous from a first opening B1-OP formed through the first synthetic resin layer 110-B1. This is because the first opening B1-OP and the second opening I1-OP are formed through the same process as described later.

According to an embodiment of the present disclosure, a shape of a first contact area CA1 of FIG. 18 may be changed as the first contact area CA1 shown in FIGS. 13 to 17.

Referring to FIGS. 19A and 19B, the first base insulating layer 110-I1 may be formed on the first synthetic resin layer 110-B1, the first pad electrode PD1 may be formed on the first base insulating layer 110-I1, and a second base insulating layer 110-I2 and a second synthetic resin layer 110-B2 may be formed on the first base insulating layer 110-I1 to cover the first pad electrode PD1.

Then, processes shown in FIGS. 19C to 19E are substantially the same as those shown in FIGS. 11E to 11K. Referring to FIG. 19F, the first pad electrode PD1 may be exposed without being covered by the first synthetic resin layer 110-B1. The first opening B1-OP and the second opening 11-OP may be formed by irradiating a laser beam onto a lower surface of the first synthetic resin layer 110-B1.

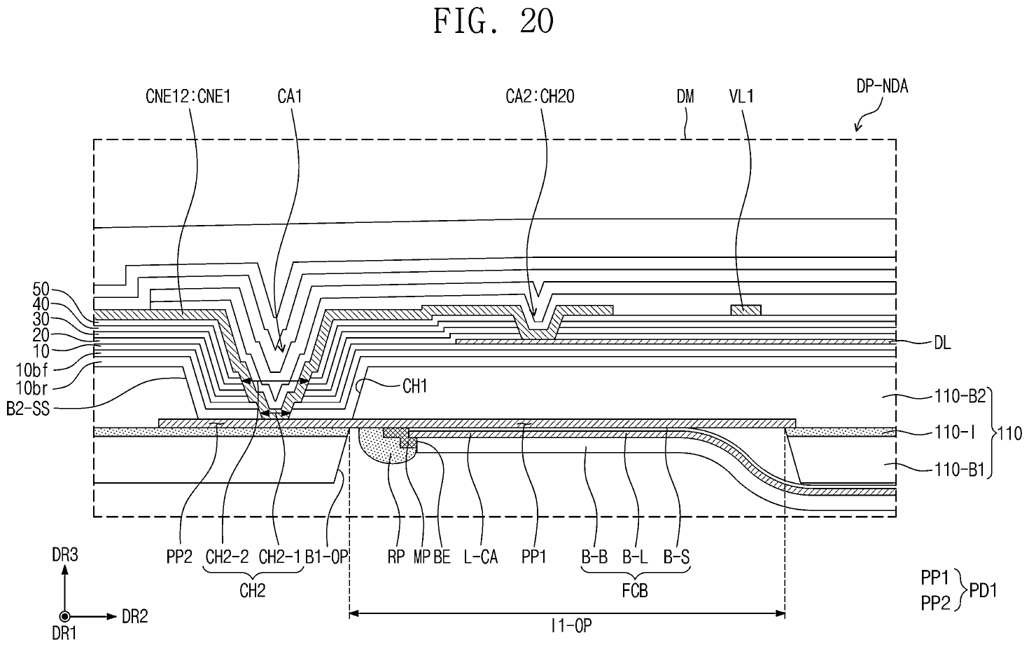

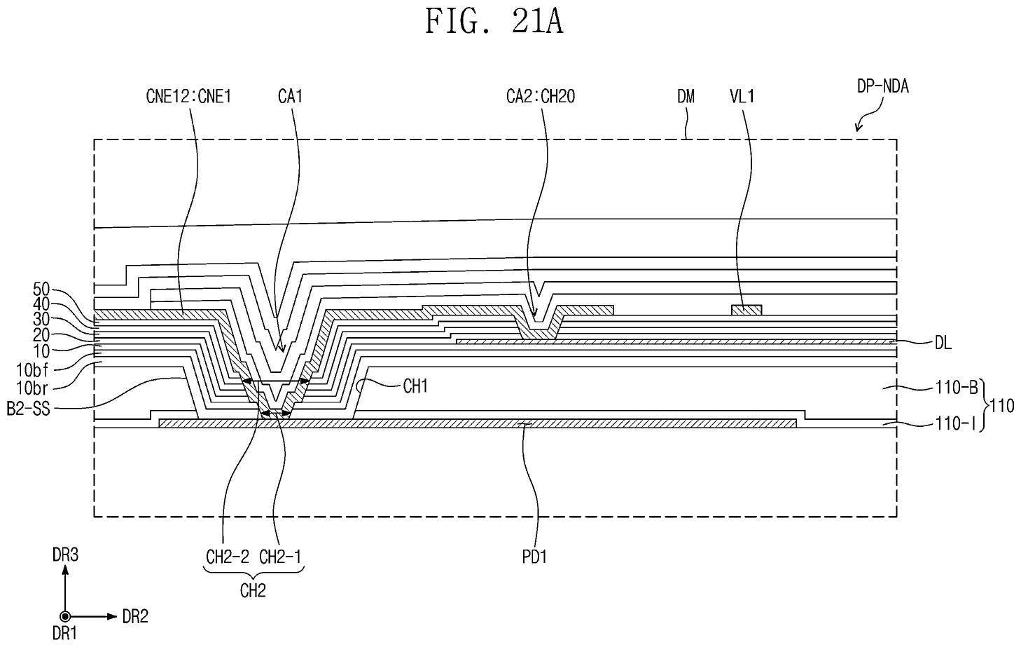

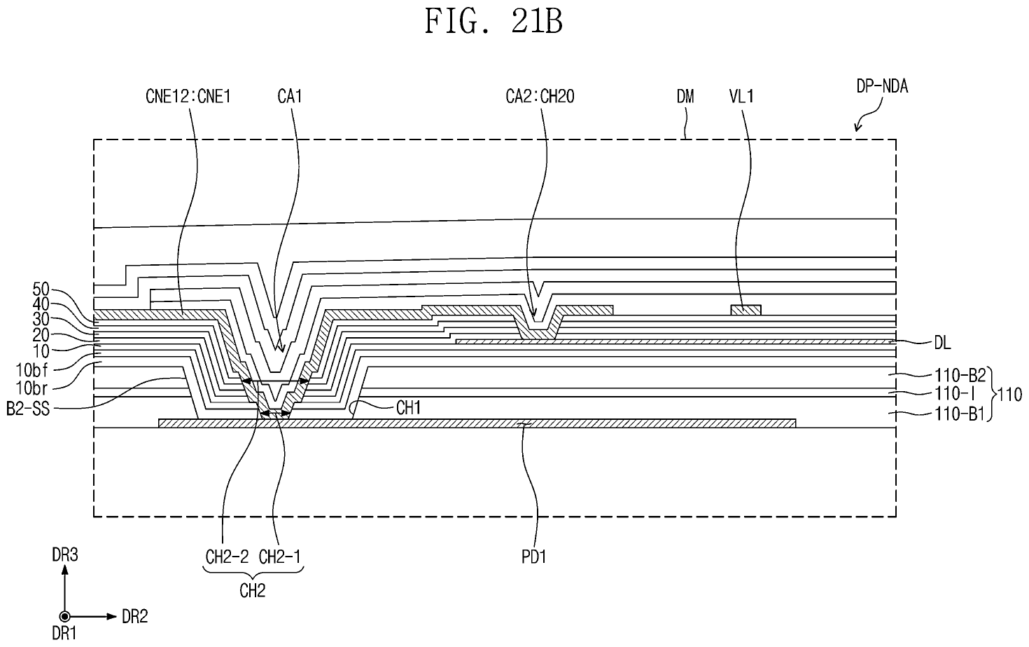

FIGS. 20, 21A, and 21B are cross-sectional views of a display module DM according to embodiments of the present disclosure.

FIGS. 20, 21A, and 21B substantially correspond to FIG. 18. In FIGS. 20, 21A, and 21B, detailed descriptions of the same elements as those described with reference to FIGS. 8 to 19F will not be repeated.

Referring to FIG. 20, the second base insulating layer 110-I2 of FIG. 18 may be omitted. A portion of a second synthetic resin layer 110-B2 may be in contact with a first pad electrode PD1. A barrier layer 10br may be in contact with the first pad electrode PD1 in a first contact hole CH1. The first pad electrode PD1 may be disposed on the base insulating layer 110-I.

As shown in FIG. 21A, the first synthetic resin layer 110-B1 and the first base insulating layer 110-I1 of FIG. 18 may be omitted. A base layer 110 may include a base insulating layer 110-I and a synthetic resin layer 110-B disposed on the base insulating layer 110-I. Different from the case of forming the first pad electrode PD1 on the first base insulating layer 110-I1 in FIG. 19A, when the first pad electrode PD1 is directly formed on the working substrate WS of FIG. 19A, a structure of FIG. 21A may be formed. Subsequent processes may be the same as those of FIGS. 19B to 19E. According to the present embodiment, the process of irradiating the laser beam of FIG. 19F may be omitted.

As shown in FIG. 21B, a first pad electrode PD1 may be disposed on a lower surface of a first synthetic resin layer 110-B1. Different from FIG. 19A, the first pad electrode PD1 may be directly formed on the work substrate WS. Then, the first synthetic resin layer 110-B1, a base insulating layer 110-I, and a second synthetic resin layer 110-B2 may be formed on the work substrate WS. Then, a first contact hole CH1 may be formed through the process as shown in FIG. 19C, however, the first contact hole CH1 according to the present embodiment may penetrate the first synthetic resin layer 110-B1, the base insulating layer 110-I, and the second synthetic resin layer 110-B2. Subsequent processes may be the same as those of FIGS. 19D and 19E. According to the present embodiment, the process of irradiating the laser beam of FIG. 19F may be omitted. According to an embodiment of the present disclosure, a base insulating layer 110-I may be further formed before the first synthetic resin layer 110-B1 is formed. In this case, the first pad electrode PD1 may be formed under the base insulating layer 110-I.

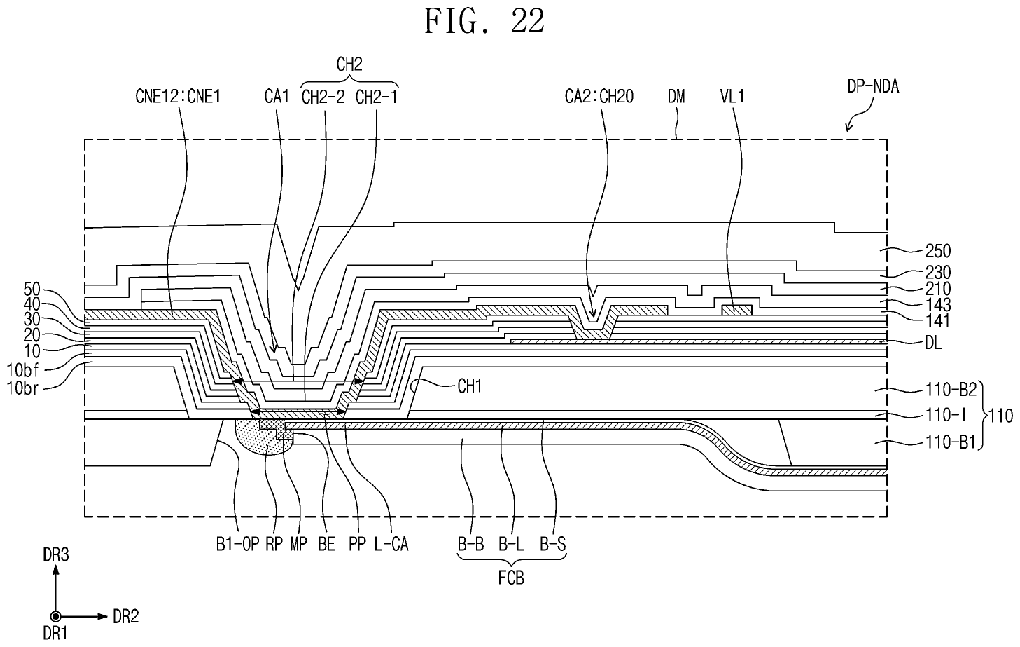

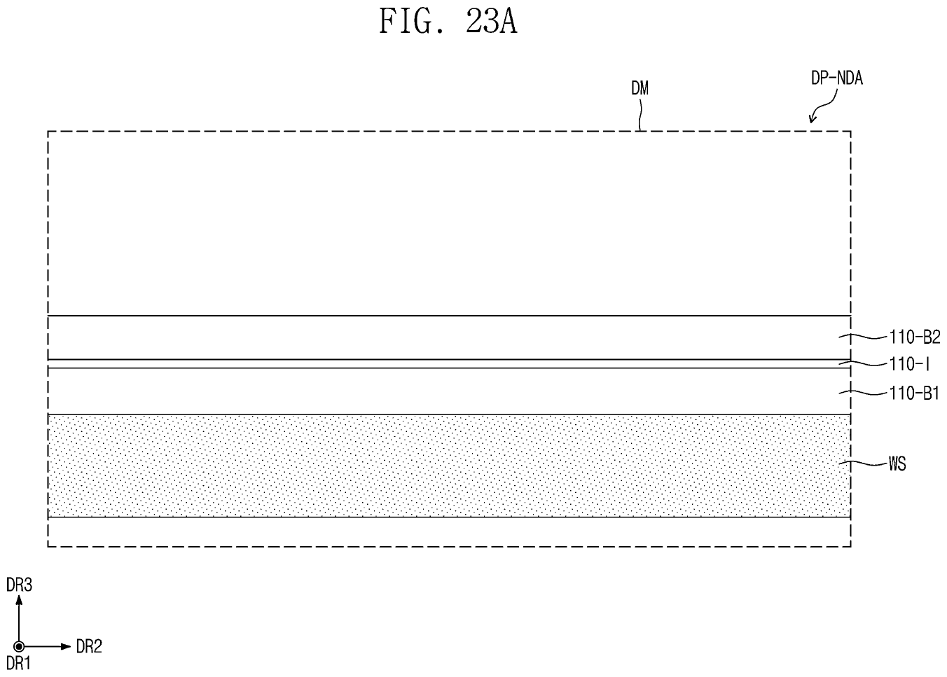

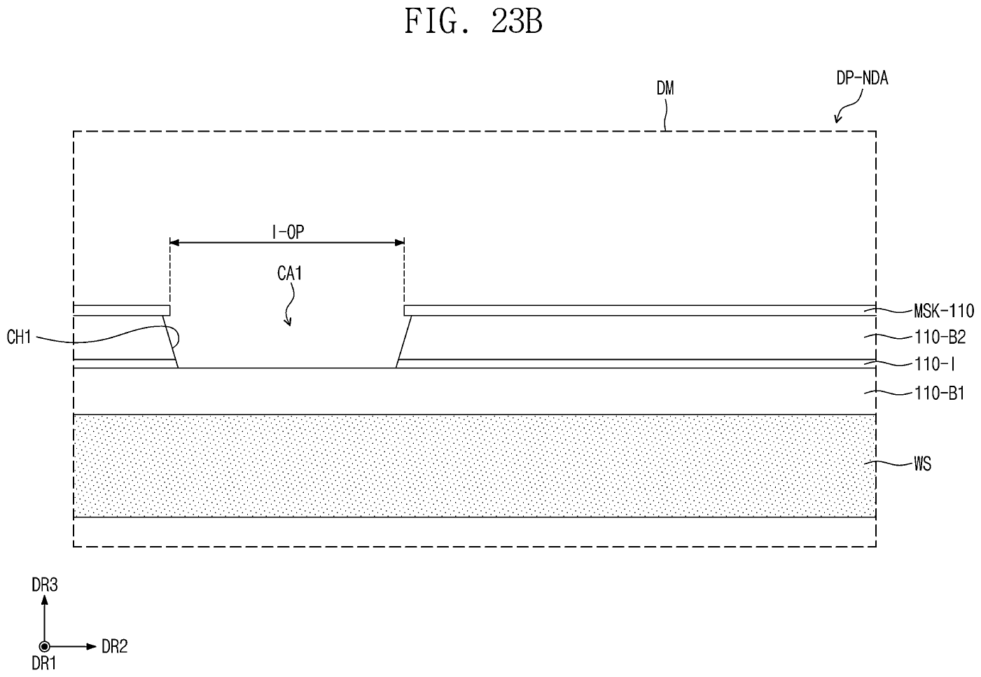

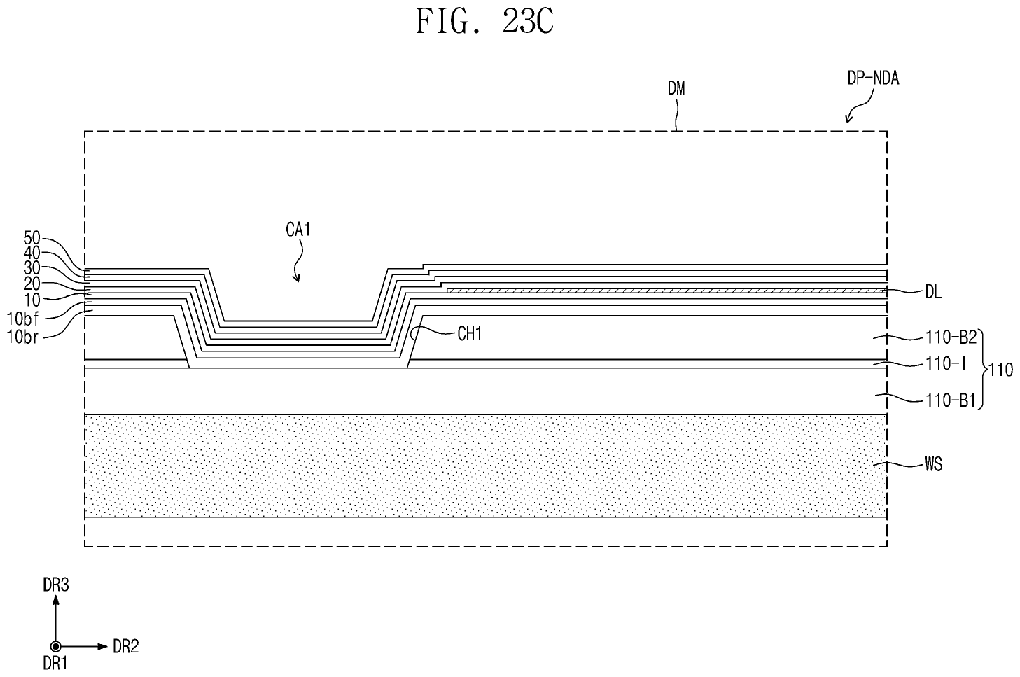

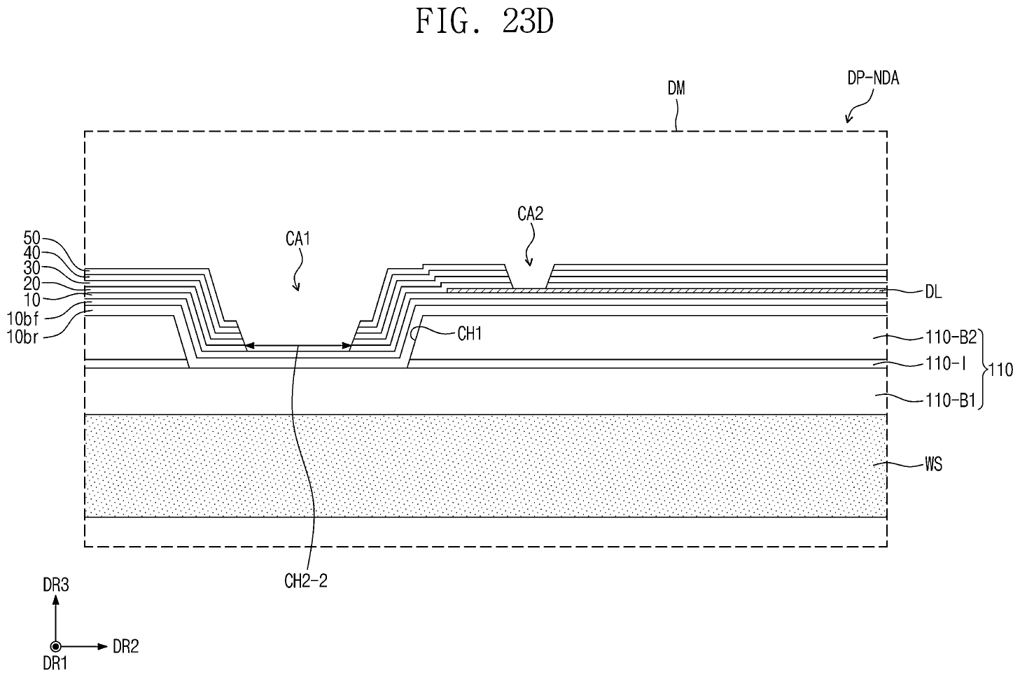

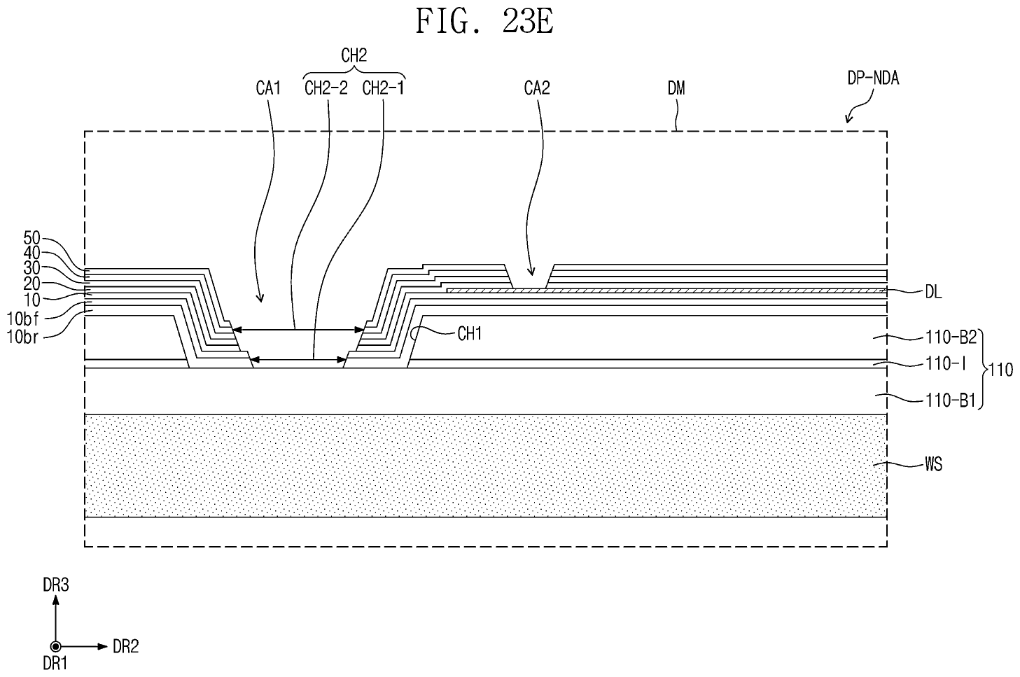

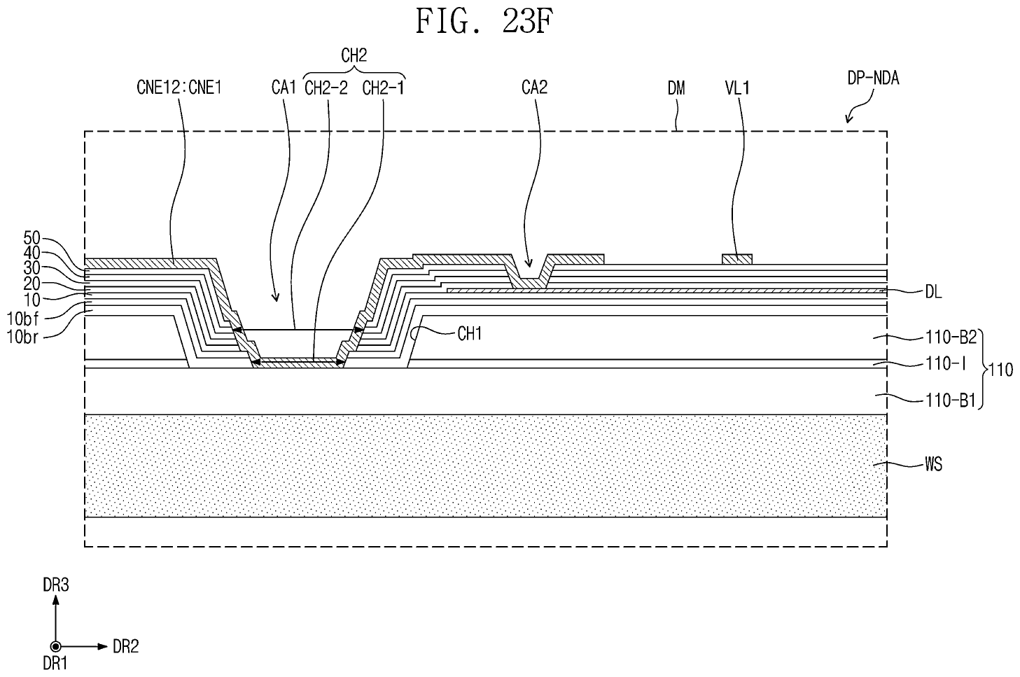

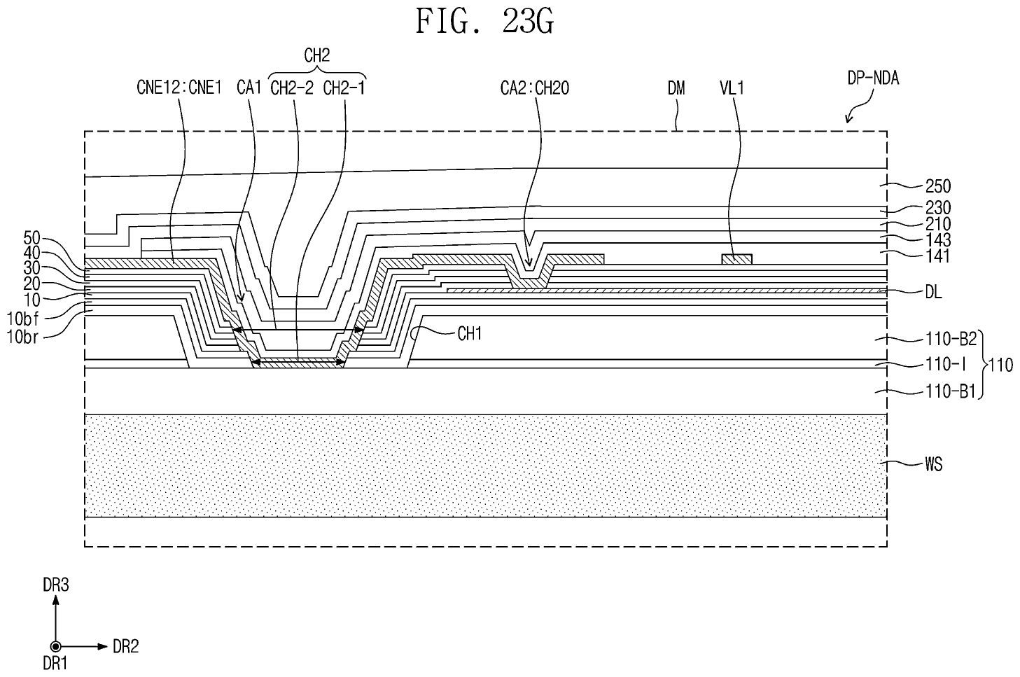

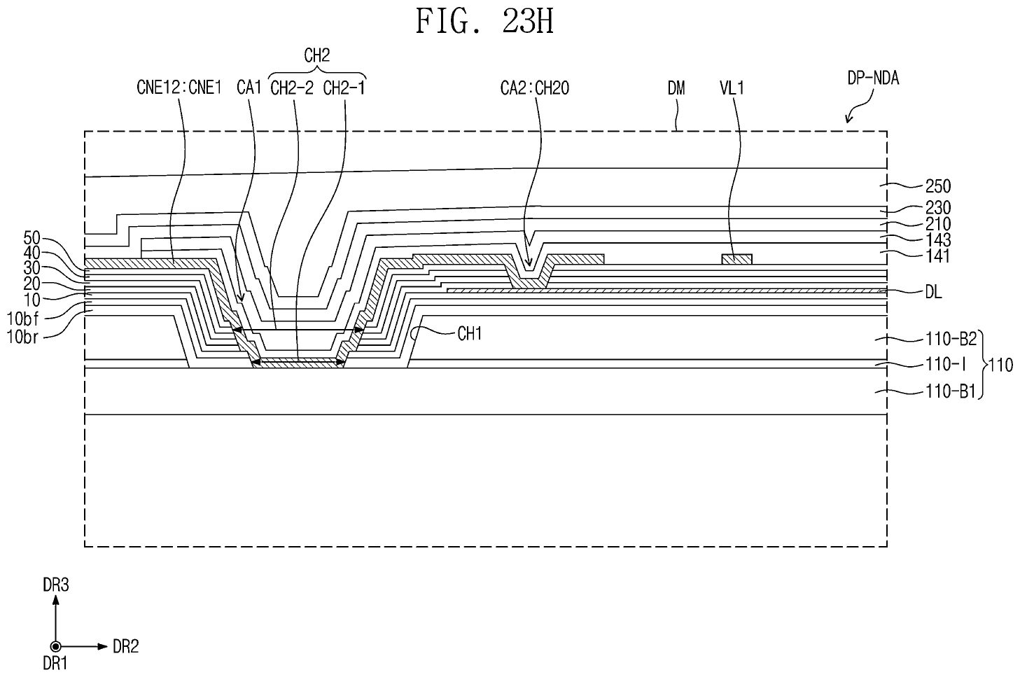

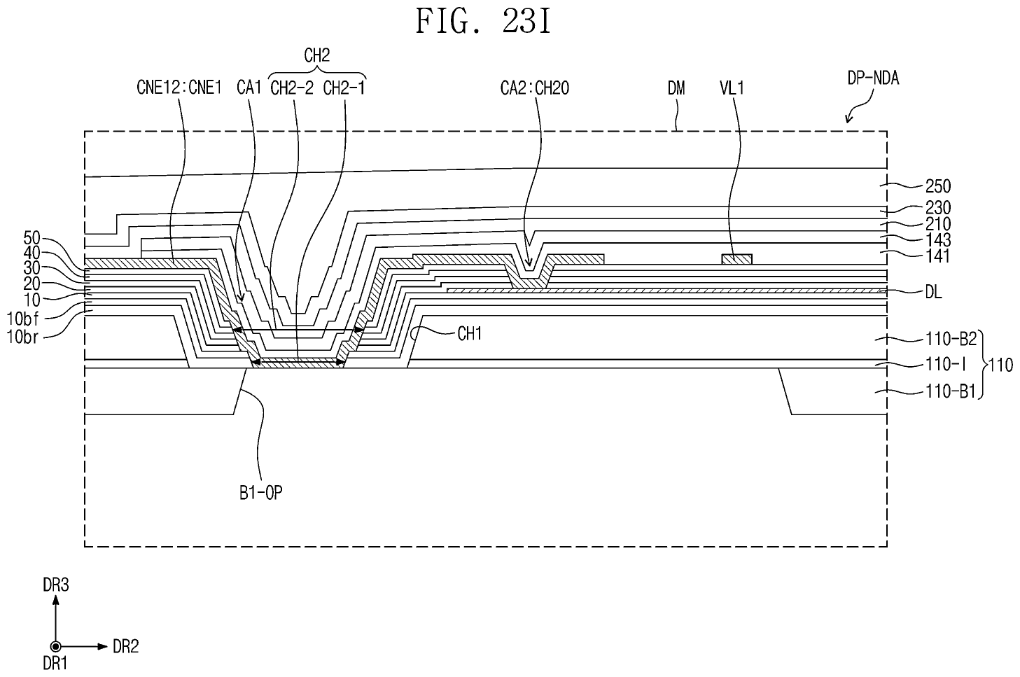

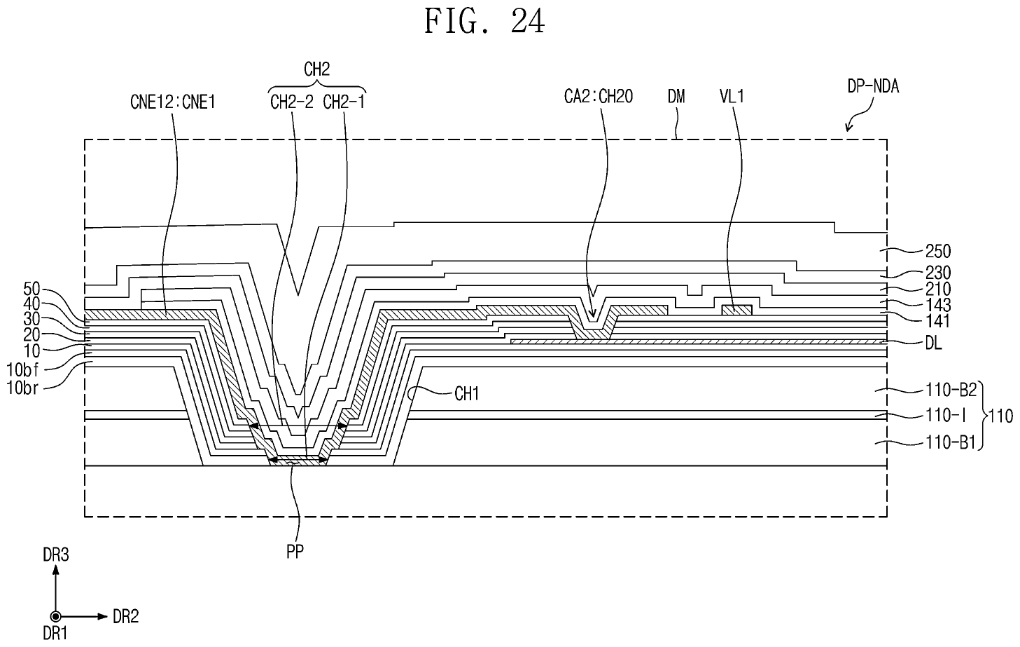

FIG. 22 is a cross-sectional view of a display module DM according to an embodiment of the present disclosure. FIGS. 23A to 23I are cross-sectional views of a method of manufacturing the display module DM according to an embodiment of the present disclosure. FIG. 24 is a cross-sectional view of a display module DM according to an embodiment of the present disclosure.

FIG. 22 substantially corresponds to FIG. 10D. FIGS. 23A to 23I correspond to FIGS. 11A to 11L. In FIGS. 22 and 23A to 23I, detailed descriptions of the same elements as those described with reference to FIGS. 8 to 12I will not be repeated.

Referring to FIG. 22, when compared with the display module DM of FIG. 10D, the first pad electrode PD1 (refer to FIG. 10D) may be omitted. In addition, the first base insulating layer 110-I1 (refer to FIG. 10D) may be omitted. A base insulating layer 110-I disposed between a first synthetic resin layer 110-B1 and a second synthetic resin layer 110-B2 shown in FIG. 22 may correspond to the second base insulating layer 110-I2 shown in FIG. 10D.

A portion of a first connection electrode CNE1 may be exposed to the outside through a second contact hole CH2 and a first opening B1-OP. The portion of the first connection electrode CNE1 exposed to the outside may be defined as a pad portion PP of the first connection electrode CNE1. The pad portion PP may be in contact with a metal pattern MP. A lower surface of the pad portion PP may be coplanar with a lower surface of the base insulating layer 110-I or an upper surface of the first synthetic resin layer 110-B1.

The pad portion PP may have a size greater than the portion of the first connection electrode CNE1 exposed through the second contact hole CH2 shown in FIG. 10D. As the pad portion PP has the relatively large size, a contact area with the metal pattern MP1 may be secured.

As shown in FIG. 23A, the first synthetic resin layer 110-B1, the base insulating layer 110-I, and the second synthetic resin layer 110-B2 may be formed on a work substrate WS. Then, as shown in FIG. 23B, a first contact hole CH1 may be formed through the base insulating layer 110-I and the second synthetic resin layer 110-B2. The first contact hole CH1 may be formed using an IZO mask MSK-110. Processes of FIGS. 23C to 23H may be substantially the same as the processes of FIGS. 11F to 11K.

Then, as shown in FIG. 231, the first opening B1-OP may be formed. The first opening B1-OP may be formed by irradiating a laser beam onto a lower surface of the first synthetic resin layer 110-B1. The pad portion PP may be exposed to the outside through the first opening B1-OP. A portion of a lower surface of a barrier layer 10br and a portion of the lower surface of the base insulating layer 110-I may be further exposed to the outside through the first opening B1-OP. Then, a bonding process between a flexible circuit board FCB (refer to FIG. 22) and the pad portion PP may be further performed.

Referring to FIG. 24, a first contact hole CH1 may penetrate a base layer 110. A first contact hole CH1 may completely penetrate a first synthetic resin layer 110-B1 in the process of forming the first contact hole CH1 described with reference to FIG. 23B. In this case, as described with reference to FIGS. 23H or 11K, when the display module DM is separated from a work substrate WS, the display module DM of FIG. 24 may be manufactured.

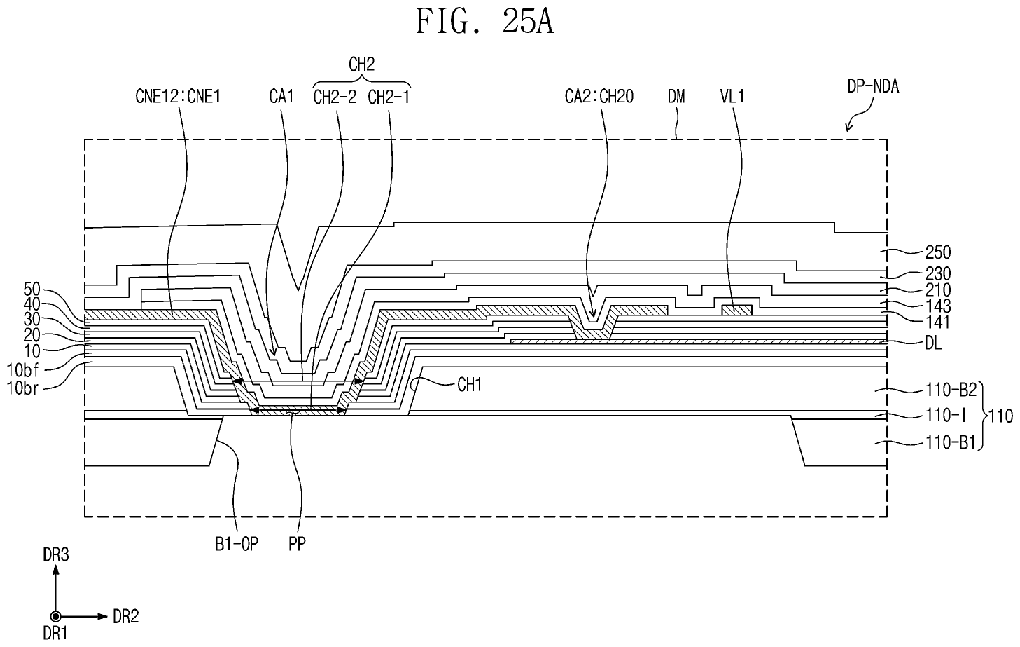

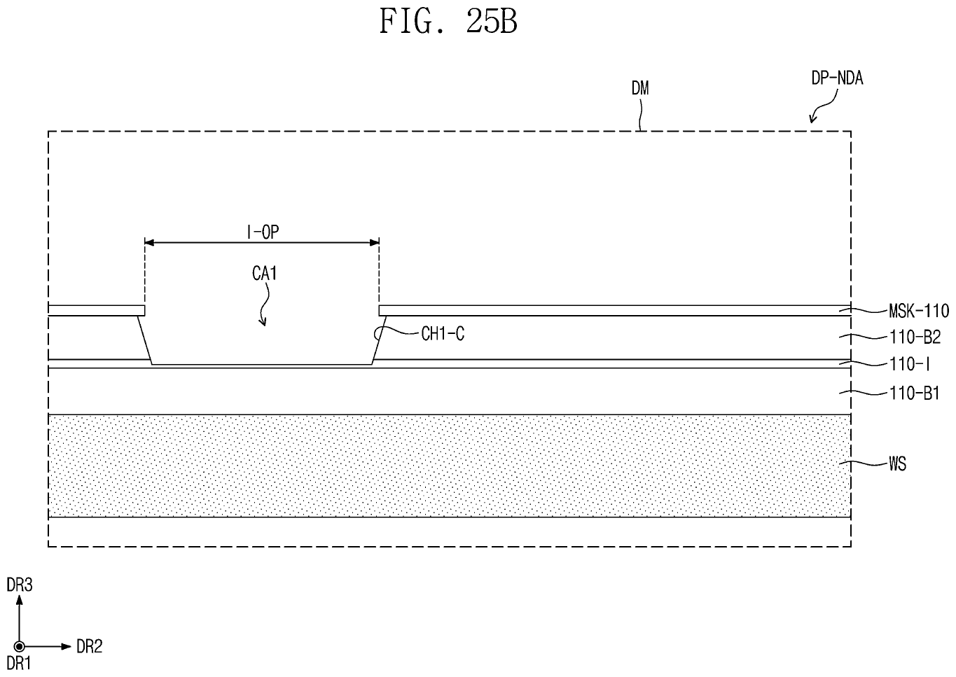

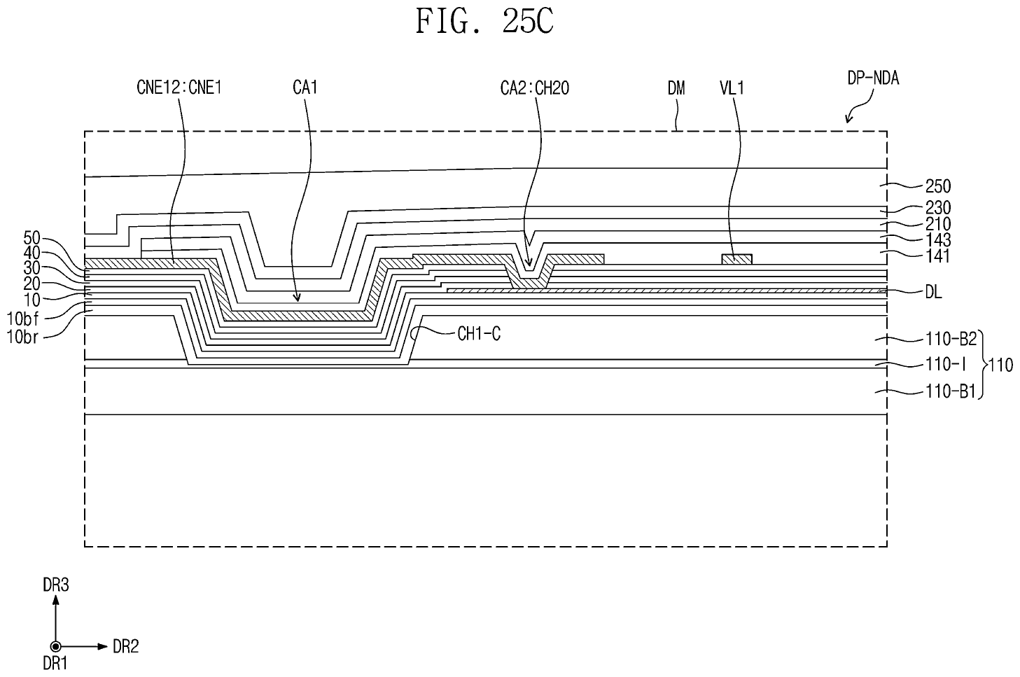

FIG. 25A is a cross-sectional view of a display module DM according to an embodiment of the present disclosure. FIGS. 25B and 25C are cross-sectional views of a method of manufacturing the display module DM according to an embodiment of the present disclosure. In FIGS. 25A to 25C, detailed descriptions of the same elements as those described with reference to FIGS. 22 and 23A to 23I will not be repeated.

Referring to FIG. 25A, a first opening B1-OP may overlap a first contact hole CH1. A portion of a base insulating layer 110-I may be exposed to the outside through the first opening B1-OP. The exposed portion of the base insulating layer 110-I may be etched when the first opening B1-OP is formed, and thus, a thickness of the exposed portion of the base insulating layer 110-I may be reduced. A portion of the base insulating layer 110-I, which is not exposed through the first opening B1-OP, may have a thickness greater than the thickness of the exposed portion of the base insulating layer 110-I exposed through the first opening B1-OP.

The first contact hole CH1 may penetrate a second synthetic resin layer 110-B2 but may not completely penetrate the base insulating layer 110-I in a partial area of a non-display area DP-NDA, and thus, a step difference may be formed in the base insulating layer 110-I. A portion of the base insulating layer 110-I, which overlaps the first contact hole CH1, may have a thickness smaller than a thickness of a portion of the base insulating layer 110-I, which does not overlap the first contact hole CH1.

FIG. 25B corresponds to FIG. 23B or FIG. 11E. The first contact hole CH1 may not completely penetrate the base insulating layer 110-I in the process of forming the first contact hole CH1, and as a result, a cavity CH1-C may be formed in the base insulating layer 110-I. The cavity CH1-C may be intentionally formed in the base insulating layer 110-I, however, the portion of the base insulating layer 110-I having the smaller thickness may be a result of a process error in which the etching is not completely performed.

FIG. 25C corresponds to FIG. 23H or FIG. 11K. Plural insulating layers 10br to 50 may be disposed in the cavity CH1-C, and a second contact hole CH2 may be defined in the cavity CH1-C. A portion of a first connection electrode CNE1 may be in contact with the base insulating layer 110-I in the second contact hole CH2.

As described with reference to FIG. 231 or FIG. 11L, the first opening B1-OP may be formed through a first synthetic resin layer 110-B1. In this case, a laser beam may be irradiated to the base insulating layer 110-I to allow the portion of the first connection electrode CNE1 to be exposed to the outside. Accordingly, as shown in FIG. 25A, the step difference may be formed in the base insulating layer 110-I to correspond to the first opening B1-OP. The base insulating layer 110-I may be removed in an area where the first opening B1-OP overlaps the cavity CH1-C. Accordingly, the first contact hole CH1 of FIG. 25A may be formed from the cavity CH1-C.

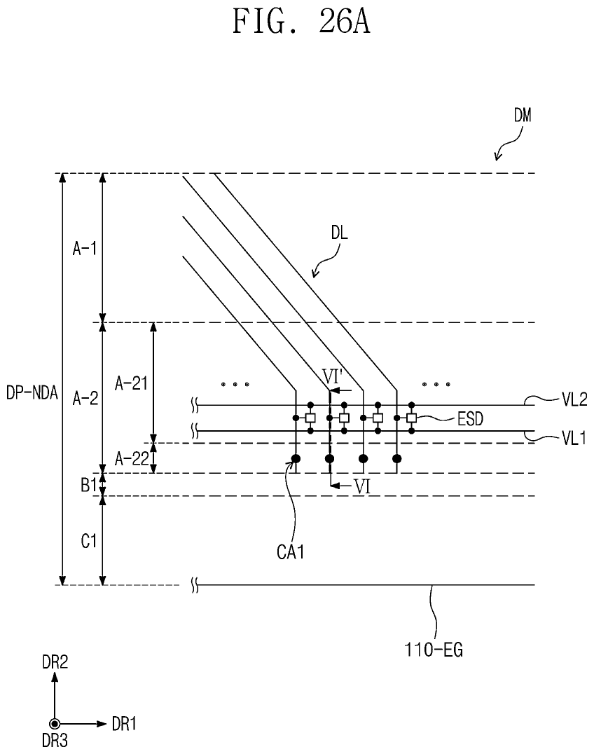

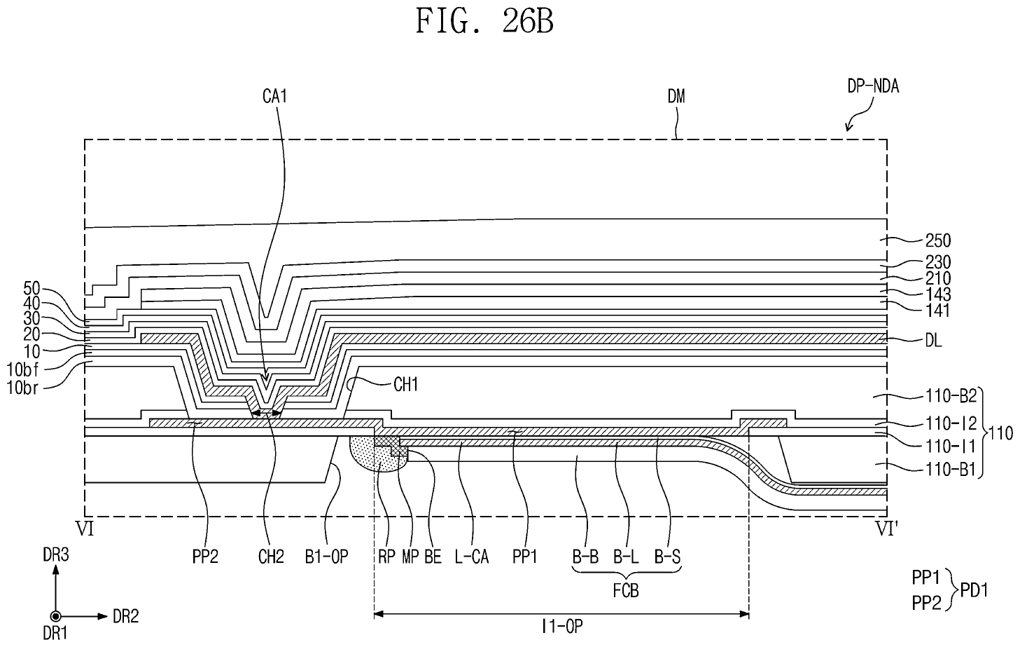

FIG. 26A is an enlarged plan view of a non-display area DP-NDA of a display module DM according to an embodiment of the present disclosure. FIG. 26B is a cross-sectional view of the display module DM taken along line VI-VI' of FIG. 26A. In FIGS. 26A and 26B, detailed descriptions of the same elements as those described with reference to FIGS. 8 and 12I will not be repeated.

According to the present embodiment, the first connection electrode CNE1 described with reference to FIG. 10A may be omitted. FIG. 26A shows first contact areas CA1 defined in a second outer area A22 as a representative example.

The first contact areas CA1 may be arranged in the first direction DR1, however, the first contact areas CA1 may be arranged in a zigzag shape. FIG. 26A shows a reduced auxiliary area B1, however, the auxiliary area B1 may be omitted.

Referring to FIG. 26B, a base layer 110 and a flexible circuit board FCB may have substantially the same structure as those shown in FIG. 10D. Some insulating layers 10br, 10bf, and 10 among insulating layers 10br to 50 may be disposed inside a first contact hole CH1.

A second contact hole CH2 may be defined inside the first contact hole CH1 to penetrate a barrier layer 10br, a buffer layer 10bf, and a first insulating layer 10. A photolithography process may be additionally required to form the second contact hole CH2. A data line DL may be connected to a first pad electrode PD1 via the second contact hole CH2. The second contact area CA2 of FIG. 10D may be omitted.

An insulating layer through which the second contact hole CH2 is defined may be changed according to a position of the data line DL. For instance, when the data line DL is disposed on a second insulating layer 20 in the non-display area DP-NDA, the second contact hole CH2 may further penetrate the second insulating layer 20.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present invention shall be determined according to the attached claims.

What is claimed is:

1. A display device comprising:
a display panel comprising a display area and a non-display area, the display panel comprising:
a first synthetic resin layer overlapping the display area and the non-display area;
a second synthetic resin layer disposed on the first synthetic resin layer;
a pad electrode disposed between the first synthetic resin layer and the second synthetic resin layer, overlapping the non-display area, and exposed to an outside via an opening defined through the first synthetic resin layer;
a plurality of insulating layers disposed on an upper surface of the second synthetic resin layer;
a pixel disposed on the upper surface of the second synthetic resin layer and comprising a light emitting element overlapping the display area and a transistor electrically connected to the light emitting element;
a signal line disposed on the upper surface of the second synthetic resin layer and overlapping at least the non-display area; and
a connection electrode disposed on the insulating layers in the non-display area and configured to electrically connect the signal line to the pad electrode,
wherein the connection electrode is connected to the pad electrode via a first contact area defined in the non-display area,
a first contact hole is defined penetrating the second synthetic resin layer in the first contact area,
portions of the insulating layers are disposed in the first contact hole,
a second contact hole is defined inside the first contact hole in a plan view, penetrates the insulating layers, and exposes the pad electrode, and
the first contact hole has a width greater than a width of the second contact hole in the plan view.

2. The display device of claim 1, wherein an area of the pad electrode exposed through the first contact hole is greater than an area of the pad electrode exposed through the second contact hole in the plan view.

3. The display device of claim 1, wherein the display panel further comprises:
a first base insulating layer disposed between the first synthetic resin layer and the second synthetic resin layer and provided with an opening defined therethrough to expose the pad electrode and corresponding to the opening of the first synthetic resin layer; and
a second base insulating layer disposed between the first base insulating layer and the second synthetic resin layer and overlapping the pad electrode,
wherein the first contact hole further penetrates the second base insulating layer.

4. The display device of claim 3, wherein the pad electrode comprises a first contact portion disposed in the opening of the first base insulating layer, and a lower surface of the first contact portion of the pad electrode is coplanar with a lower surface of the first base insulating layer.

5. The display device of claim 4, wherein the pad electrode further comprises a second contact portion extending from the first contact portion of the pad electrode, and the second contact portion of the pad electrode is disposed on the first synthetic resin layer, is exposed through the second contact hole, and is in contact with the connection electrode.

6. The display device of claim 3, wherein the first base insulating layer and the second base insulating layer comprise silicon nitride, silicon oxynitride, or silicon oxide.

7. The display device of claim 3, wherein the pad electrode is disposed on the first base insulating layer.

8. The display device of claim 7, wherein the first base insulating layer has a coupling force with the pad electrode greater than a coupling force between the first synthetic resin layer and the pad electrode.

9. The display device of claim 1, wherein the display panel further comprises a base insulating layer disposed between the first synthetic resin layer and the second synthetic resin layer, the pad electrode is disposed on the first synthetic resin layer, a portion of the base insulating layer overlaps the pad electrode in the plan view, the first contact hole further penetrates the base insulating layer, and a lower surface of the pad electrode is coplanar with a lower surface of another portion of the base insulating layer, which does not overlap the pad electrode in the plan view.

10. The display device of claim 1, wherein the display panel further comprises a base insulating layer disposed between the first synthetic resin layer and the second synthetic resin layer, and the pad electrode is disposed on the base insulating layer.

11. The display device of claim 1, wherein the first contact hole is defined by an inner side surface of the second synthetic resin layer, and an angle between the inner side surface of the second synthetic resin layer and an upper surface of the first synthetic resin layer is within a range of about 45 degrees to about 80 degrees.

12. The display device of claim 1, wherein the insulating layers comprise:
a first group of inorganic layers; and
a second group of inorganic layers disposed on the first group of the inorganic layers,
wherein the second contact hole comprises a first area defined to penetrate the first group of the inorganic layers and a second area defined to penetrate the second group of the inorganic layers, and
the second area has a width greater than a width of the first area in the plan view.

13. The display device of claim 12, wherein the transistor comprises:
a first transistor comprising a silicon semiconductor pattern disposed on the first group of the inorganic layers; and
a second transistor comprising a metal oxide semiconductor pattern disposed between the second group of the inorganic layers, and
the display panel further comprises a first connection pattern connected to the silicon semiconductor pattern via a first pixel contact hole penetrating at least the second group of the inorganic layers and a second connection pattern connected to the metal oxide semiconductor pattern via a second pixel contact hole penetrating a corresponding inorganic layer among the second group of the inorganic layers.

14. The display device of claim 1, wherein the first contact hole has a width that is about 20% greater than a width of the second contact hole in the plan view.

15. The display device of claim 1, wherein the first contact hole has a width in a range of about 20 micrometers to about 24 micrometers, and the second contact hole has a width in a range of about 8 micrometers to about 14 micrometers in the plan view.

16. The display device of claim 1, wherein the pad electrode comprises:
a first metal layer; and
a second metal layer disposed on the first metal layer,
wherein the first metal layer has a corrosion resistance greater than a corrosion resistance of the second metal layer, and the second metal layer has a conductivity greater than a conductivity of the first metal layer.

17. The display device of claim 1, wherein the connection electrode is connected to the signal line via a second contact area, and a third contact hole penetrating corresponding insulating layers among the insulating layers and exposing the signal line is defined in the second contact area.

18. The display device of claim 17, wherein the signal line comprises a data line that further overlaps the display area and is electrically connected to the transistor.

19. The display device of claim 1, wherein the display panel further comprises an encapsulation layer disposed on the upper surface of the second synthetic resin layer and covering the light emitting element,
the encapsulation layer comprises:
a first encapsulation inorganic layer overlapping the display area and the non-display area;
a second encapsulation inorganic layer disposed on the first encapsulation inorganic layer; and
an encapsulation organic layer disposed between the first encapsulation inorganic layer and the second encapsulation inorganic layer, and
the encapsulation layer comprises an outer area in which the first encapsulation inorganic layer is in contact with the second encapsulation inorganic layer and an inner area overlapping the encapsulation organic layer in the plan view.

20. The display device of claim 19, wherein the first contact area overlaps the outer area or the inner area, and the first encapsulation inorganic layer is in contact with the connection electrode in the first contact area.

21. The display device of claim 19, wherein the pad electrode overlaps the inner area

22. The display device of claim 1, wherein the display panel further comprises at least one organic pattern disposed on the insulating layers, the at least one organic pattern overlaps the first contact area, and the at least one organic pattern is in contact with the connection electrode in the first contact area.

23. The display device of claim 1, wherein the display panel further comprises a sub-connection electrode that is disposed on the connection electrode and is in contact with the connection electrode.

24. The display device of claim 1, wherein the pad electrode comprises a first-first pad electrode and a first-second pad electrode, which are arranged in a first direction, the signal line comprises a first signal line and a second signal line, the connection electrode comprises a first-first connection electrode configured to electrically connect the first-first pad electrode to the first signal line and a first-second connection electrode configured to electrically connect the first-second pad electrode to the second signal line, and the first contact area corresponding to the first-first connection electrode is not aligned with the second contact area corresponding to the first-second connection electrode in the first direction.

25. The display device of claim 1, further comprising:
a flexible circuit board overlapping the opening of the first synthetic resin layer; and
a metal pattern configured to electrically connect the flexible circuit board to the pad electrode, wherein the flexible circuit board comprises:
a base film; and
a signal transmission line disposed on the base film and comprising a contact area exposed without being covered by an edge of the base film, and
the metal pattern is in contact with the pad electrode and the contact area of the signal transmission area.

26. The display device of claim 1, wherein the display panel further comprises an alignment mark disposed in the non-display area, disposed on a same layer as the pad electrode, and disposed spaced apart from the pad electrode.

27. A display device comprising:
a display panel comprising a display area and a non-display area; and
a flexible circuit board electrically connected to the display panel, the display panel comprising:
a first synthetic resin layer overlapping the display area and the non-display area;
a second synthetic resin layer disposed on the first synthetic resin layer;
a base insulating layer disposed between the first synthetic resin layer and the second synthetic resin layer;
a plurality of insulating layers disposed on an upper surface of the second synthetic resin layer;
a pixel disposed on the upper surface of the second synthetic resin layer and comprising a light emitting element overlapping the display area and a transistor electrically connected to the light emitting element;
a signal line disposed on the upper surface of the second synthetic resin layer and overlapping at least the non-display area; and
a connection electrode disposed on the insulating layers in the non-display area, configured to electrically connect the signal line to the flexible circuit board, and comprising a pad portion exposed to an outside through an opening defined through the first synthetic resin layer,
wherein the connection electrode is connected to the flexible circuit board via a contact area defined in the non-display area, a first contact hole is defined penetrating the second synthetic resin layer and the base insulating layer in the contact area, portions of the insulating layers are disposed in the first contact hole, a second contact hole is defined inside the first contact hole in a plan view and penetrates the insulating layers, and the pad portion is disposed in the second contact hole.

28. The display device of claim 27, wherein the base insulating layer comprises silicon nitride, silicon oxynitride, or silicon oxide.

29. The display device of claim 27, wherein the first contact hole is defined by an inner side surface of the second synthetic resin layer, and an angle between the inner side surface of the second synthetic resin layer and an upper surface of the first synthetic resin layer is within a range of about 45 degrees to about 80 degrees.

30. The display device of claim 27, wherein the insulating layers comprise:
a first group of inorganic layers; and
a second group of inorganic layers disposed on the first group of the inorganic layers,
wherein the second contact hole comprises a first area defined to penetrate the first group of the inorganic layers and a second area defined to penetrate the second group of the inorganic layers, and
the second area has a width greater than a width of the first area in the plan view.

31. The display device of claim 30, wherein a portion of an inorganic layer disposed at a lowermost position among the first group of the inorganic layers is exposed to the outside via the opening defined through the first synthetic resin layer.

32. The display device of claim 27, wherein the first contact hole has a width that is about 20% greater than a width of the second contact hole in the plan view.

33. The display device of claim 27, wherein the first contact hole has a width in a range of about 20 micrometers to about 24 micrometers, and the second contact hole has a width in a range of about 8 micrometers to about 14 micrometers in the plan view.

34. The display device of claim 27, wherein a portion of the base insulating layer is exposed to the outside via the opening defined through the first synthetic resin layer.

35. A display device comprising:
a display panel comprising a display area and a non-display area, the display panel comprising:
a first synthetic resin layer overlapping the display area and the non-display area;
a second synthetic resin layer disposed on the first synthetic resin layer;
a pad electrode disposed between the first synthetic resin layer and the second synthetic resin layer, overlapping the non-display area, and exposed to an outside via an opening defined through the first synthetic resin layer;
a plurality of insulating layers disposed on an upper surface of the second synthetic resin layer;
a pixel disposed on the upper surface of the second synthetic resin layer and comprising a light emitting element overlapping the display area and a transistor electrically connected to the light emitting element; and
a signal line disposed on a first group of insulating layers among the insulating layers in the non-display area and electrically connected to the pad electrode,
wherein the signal line is connected to the pad electrode via a contact area defined in the non-display area.
a first contact hole is defined penetrating the second synthetic resin layer in the contact area
portions of the first group of the insulating layers are disposed in the first contact hole,
a second contact hole is defined inside the first contact hole in a plan view, penetrates the first group of the insulating layers, and exposes the pad electrode,
the signal line is connected to the pad electrode through the second contact hole, and
the first contact hole has a width greater than a width of the second contact hole in the plan view.

36. The display device of claim 35, wherein an area of the pad electrode exposed through the first contact hole is greater than an area of the pad electrode exposed through the second contact hole in the plan view.

37. The display device of claim 35, wherein a second group of insulating layers among the insulating layers covers the signal line in the first contact hole and is disposed on the first group of the insulating layers.

38. The display device of claim 35, wherein the display panel further comprises:
a first base insulating layer disposed between the first synthetic resin layer and the second synthetic resin layer and provided with an opening defined therethrough to expose the pad electrode and corresponding to the opening of the first synthetic resin layer; and
a second base insulating layer disposed between the first base insulating layer and the second synthetic resin layer and overlapping the pad electrode,
wherein the first contact hole further penetrates the second base insulating layer.

39. The display device of claim 35, wherein the first contact hole has a width that is about 20% greater than a width of the second contact hole in the plan view.

40. The display device of claim 35, wherein the first contact hole has a width in a range of about 20 micrometers to about 24 micrometers, and the second contact hole has a width in a range of about 8 micrometers to about 14 micrometers in the plan view.
